(19) United States
(12) Patent Application Publication
(10) Pub. No.: US 2026/0173747 A1
(43) Pub. Date: Jun. 18, 2026

(54) BLUE LUMINESCENT HOST COMPOSITION, ORGANIC ELECTROLUMINESCENT DEVICE COMPRISING SAME, AND DISPLAY DEVICE

(71) Applicant: SHIJIAZHUANG CHENGZHI YONGHUA DISPLAY MATERIAL CO., LTD., Shijiazhuang (CN)

(72) Inventors: Tianyu WEI, Shijiazhuang (CN); Feng Liang, Shijiazhuang (CN); Pengjun Bu, Shijiazhuang (CN); Zelin Wu, Shijiazhuang (CN); Songyuan Liu, Shijiazhuang (CN)

(73) Assignee: SHIJIAZHUANG CHENGZHI YONGHUA DISPLAY MATERIAL CO., LTD., Shijiazhuang (CN)

(21) Appl. No.: 19/530,063

(22) Filed: Feb. 4, 2026

(30) Foreign Application Priority Data
Aug. 15, 2025 (CN) 202511148589.4

(51) Int. Cl. H10K 85/60; C09K 11/02; H10K 50/11

(52) U.S. Cl. CPC H10K 85/626; C09K 11/02; H10K 85/615; H10K 85/6574; H10K 50/11

(57) ABSTRACT

The present invention discloses a blue luminescent host composition, an organic electroluminescent device comprising the blue luminescent host composition, and a display device. The blue luminescent host composition comprises at least a first host compound, a second host compound, and a third host compound, wherein the structure of the first host compound is as represented by formula I, the structure of the second host compound is as represented by formula II, and the structure of the third host compound is as represented by formula I or II. The blue luminescent host composition provided by the present invention has a melting point lower than that of each individual compound. The blue luminescent host compounds provided by the present invention are evaporated to form a host composition thin film under continuous working conditions and at different evaporation rates. The blue luminescent host composition provided by the present invention exhibits a relatively constant mass ratio in the final evaporated thin film and a relatively small difference from an initial pre-mixing ratio, thereby avoiding the problem of device performance degradation caused by a relatively significant difference between the actual evaporated component ratio and the initially set pre-mixing ratio.

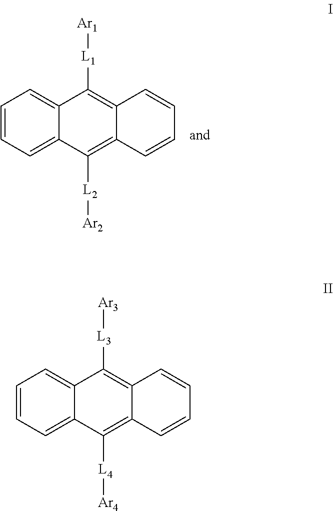

### TECHNICAL FIELD

The present invention belongs to the technical field of OLEDs and in particular comprises a blue luminescent host composition, an organic electroluminescent device comprising the blue luminescent host composition, and a display device.

### BACKGROUND ART

Organic electroluminescent devices (OLEDs), as a highly promising semiconductor luminescence technology, have achieved significant research progress in recent years in materials science, device structures, performance optimization, industrial applications, etc. How to further improve the overall performance of a blue-light organic electroluminescent device is a hot topic in current research.

Existing pre-mixed dual-host blue fluorescent light-emitting devices have significant advantages. Their dual host materials achieve good carrier balance by means of optimized energy level matching. This not only reduces the driving voltage and enhances luminescence efficiency but can also effectively suppress efficiency roll-off. At present, during the preparation of pre-mixed dual-host blue fluorescent light-emitting devices, generally, two host materials are pre-mixed at a preset mass ratio in advance before evaporation, and evaporation is then performed in an evaporation source. However, during the evaporation process, the two host components in the pre-mixed material are often not evaporated at the pre-mixing ratio, resulting in a relatively significant difference between the ratio of the two host materials in the actually obtained evaporated film layer and the initial preset ratio, which leads to a decrease in its lifetime and a need for further optimization. Moreover, it is also difficult to maintain a constant ratio between the two host materials at different evaporation rates, which may result in fluctuations in device performance as the evaporation rate varies, leading to a relatively poor stability, thereby greatly affecting the production of the device under continuous working conditions.

### SUMMARY OF THE INVENTION

In view of the above-mentioned problems in the prior art, the present invention provides a blue luminescent host composition and an organic electroluminescent device comprising the blue luminescent host composition.

In order to achieve the above objective, the technical solution used by the present invention comprises the following content:

A first aspect of the present invention provides a blue luminescent host composition, comprising at least a first host compound, a second host compound, and a third host compound, wherein the structure of the first host compound is as represented by formula I, the structure of the second host compound is as represented by formula II, and the structure of the third host compound is as represented by formula I or II; and the first host compound, the second host compound, and the third host compound are different from each other;

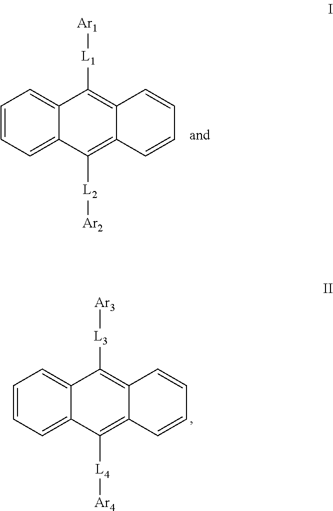

wherein Ar₁ and Ar₂ are each independently selected from any one of or a combination of any two of a deuterated or non-deuterated aryl group having a carbon atom number of 6 to 30 and a deuterated or non-deuterated fused aryl group having a carbon atom number of 10 to 30;
Ar₃ is selected from any one of or a combination of any two of a deuterated or non-deuterated aryl group having a carbon atom number of 6 to 30 and a deuterated or non-deuterated fused aryl group having a carbon atom number of 10 to 30;
Ar₄ is selected from any one of or a combination of any two of a deuterated or non-deuterated oxygen-atom-containing heterocyclyl group having a carbon atom number of 5 to 30 and a deuterated or non-deuterated oxygen-atom-containing fused heterocyclyl group having a carbon atom number of 5 to 30;
L₁, L₂, L₃, and L₄ are each independently selected from any one of a single bond and a deuterated or non-deuterated aryl group having a carbon atom number of 6 to 30; and
the mass proportion of any one of the host compounds in the blue luminescent host composition is between 10 wt % and 80 wt %.

Furthermore, Ar₁ and Ar₂ are each independently selected from any one of or a combination of any two of a deuterated or non-deuterated aryl group having a carbon atom number of 6 to 20 and a deuterated or non-deuterated fused aryl group having a carbon atom number of 10 to 20.

Furthermore, Ar₃ is selected from any one of or a combination of any two of a deuterated or non-deuterated aryl group having a carbon atom number of 6 to 20 and a deuterated or non-deuterated fused aryl group having a carbon atom number of 10 to 20.

Furthermore, Ar₄ is selected from any one of or a combination of any two of a deuterated or non-deuterated oxygen-atom-containing heterocyclyl group having a carbon atom number of 5 to 20 and a deuterated or non-deuterated oxygen-atom-containing fused heterocyclyl group having a carbon atom number of 5 to 20.

Furthermore, L₁, L₂, L₃, and L₄ are each independently selected from any one of a single bond and a deuterated or non-deuterated aryl group having a carbon atom number of 6 to 20.

Furthermore, the mass proportion of any one of the compounds in the blue luminescent host composition is between 10 wt % and 75 wt %.

Furthermore, the mass proportion of any one of the compounds in the blue luminescent host composition is between 10 wt % and 70 wt %.

Furthermore, the mass proportion of any one of the compounds in the blue luminescent host composition is between 10 wt % and 65 wt %.

Furthermore, the mass proportion of any one of the compounds in the blue luminescent host composition is between 10 wt % and 60 wt %.

Furthermore, the proportion of the total mass of compounds selected from Formula I in the blue luminescent host composition relative to the mass of the blue luminescent host composition is not less than 10 wt %.

Furthermore, the proportion of the total mass of compounds selected from Formula I in the blue luminescent host composition relative to the mass of the blue luminescent host composition is not less than 20 wt %.

Furthermore, the proportion of the total mass of compounds selected from Formula I in the blue luminescent host composition relative to the mass of the blue luminescent host composition is not less than 30 wt %.

Furthermore, the proportion of the total mass of compounds selected from Formula I in the blue luminescent host composition relative to the mass of the blue luminescent host composition is not less than 40 wt %.

Furthermore, the proportion of the total mass of compounds selected from Formula II in the blue luminescent host composition relative to the mass of the blue luminescent host composition is not less than 10 wt %.

Furthermore, the proportion of the total mass of compounds selected from Formula II in the blue luminescent host composition relative to the mass of the blue luminescent host composition is not less than 20 wt %.

Furthermore, the proportion of the total mass of compounds selected from Formula II in the blue luminescent host composition relative to the mass of the blue luminescent host composition is not less than 30 wt %.

Furthermore, the proportion of the total mass of compounds selected from Formula II in the blue luminescent host composition relative to the mass of the blue luminescent host composition is not less than 40 wt %.

In conjunction with the first aspect, the ratio of the total mass of compounds selected from Formula I to the total mass of compounds selected from Formula II in the blue luminescent host composition is 1:9 to 9:1.

Furthermore, the ratio of the total mass of compounds selected from Formula I to the total mass of compounds selected from Formula II in the blue luminescent host composition is 2:8 to 8:2.

Furthermore, the ratio of the total mass of compounds selected from Formula I to the total mass of compounds selected from Formula II in the blue luminescent host composition is 3:7 to 7:3.

Furthermore, the ratio of the total mass of compounds selected from Formula I to the total mass of compounds selected from Formula II in the blue luminescent host composition is 4:6 to 6:4.

Furthermore, the above-mentioned oxygen-atom-containing heterocyclyl group preferably includes furanyl, etc.;
and the above-mentioned oxygen-atom-containing fused heterocyclyl preferably includes dibenzofuranyl, naphthobenzofuranyl, benzo[4,5-BCD]furanyl, etc.

In conjunction with the first aspect, Ar₁ and Ar₂ are each independently selected from any one of or a combination of any two of a deuterated or non-deuterated phenyl group, a deuterated or non-deuterated biphenyl group, a deuterated or non-deuterated naphthyl group, and a deuterated or non-deuterated phenanthryl group;
Ar₃ is selected from any one of or a combination of any two of a deuterated or non-deuterated phenyl group, a deuterated or non-deuterated biphenyl group, and a deuterated or non-deuterated naphthyl group;
Ar₄ is selected from any one of

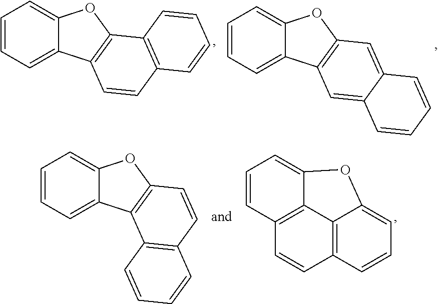

and any hydrogen in Ar₄ can be replaced by deuterium;
L₁, L₂, L₃, and L₄ are each independently selected from any one of a single bond, a deuterated or non-deuterated phenyl group, and a deuterated or non-deuterated biphenyl group;
when the third host compound is selected from structures as represented by formula I, the mass ratio of the first host compound to the second host compound to the third host compound in the blue luminescent host composition is 0.1-6:0.5-7:1; and
when the third host compound is selected from structures as represented by formula II, the mass ratio of the first host compound to the second host compound to the third host compound in the blue luminescent host composition is 0.5-7:0.1-6:1.

In conjunction with the first aspect, the difference in molecular weight between any two compounds of the above-mentioned first host compound, second host compound, and third host compound is within 100, that is, the difference in molecular weight between the first host compound and the second host compound is within 100, the difference in molecular weight between the first host compound and the third host compound is within 100, and the difference in molecular weight between the second host compound and the third host compound is within 100.

In conjunction with the first aspect, when the first host compound, the second host compound, and the third host compound are deuterated compounds, the degree of deuteration at each deuteration site in the structures of the compounds is greater than 5%.

Furthermore, Formula I is selected from one of the following structures:

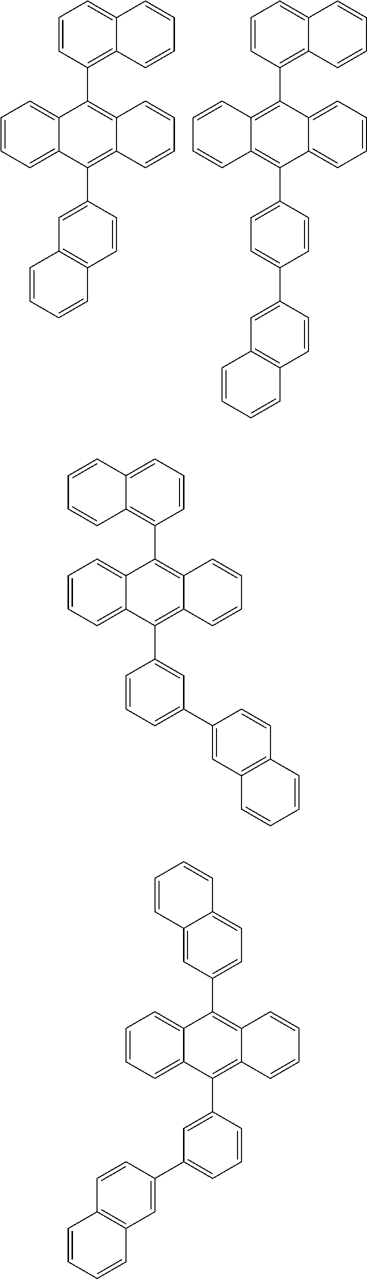

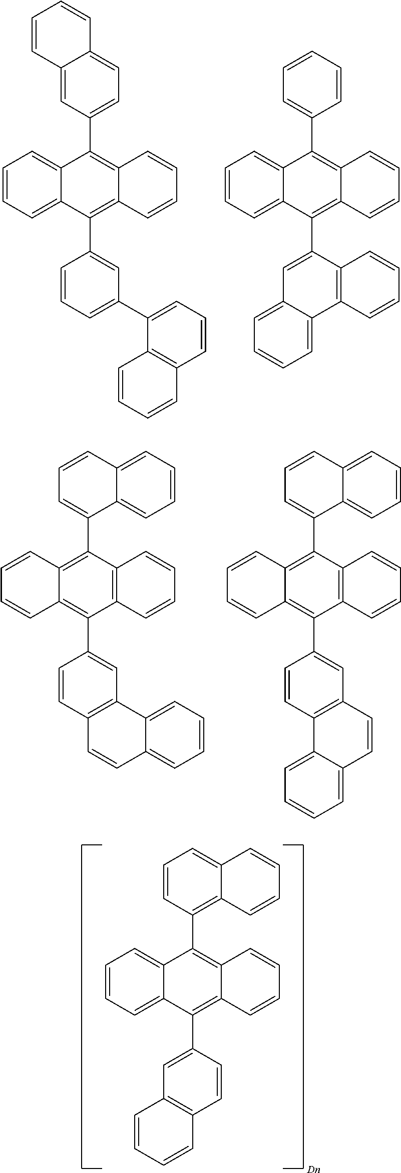

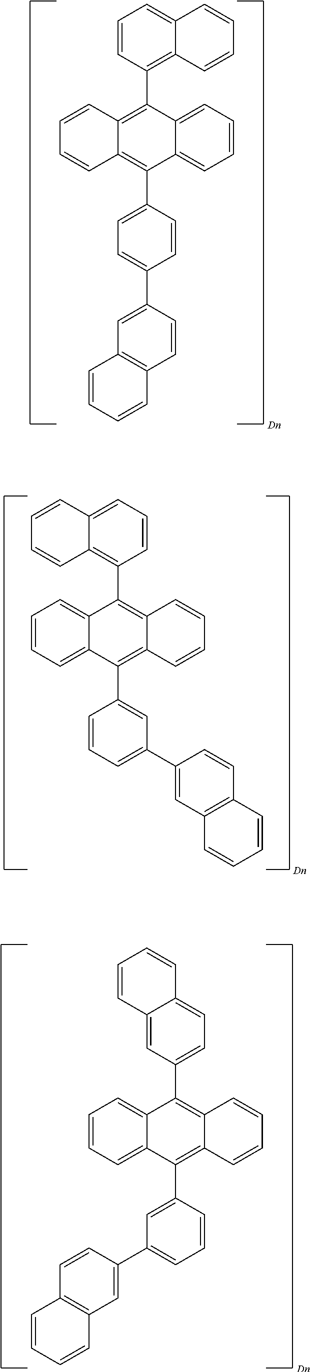

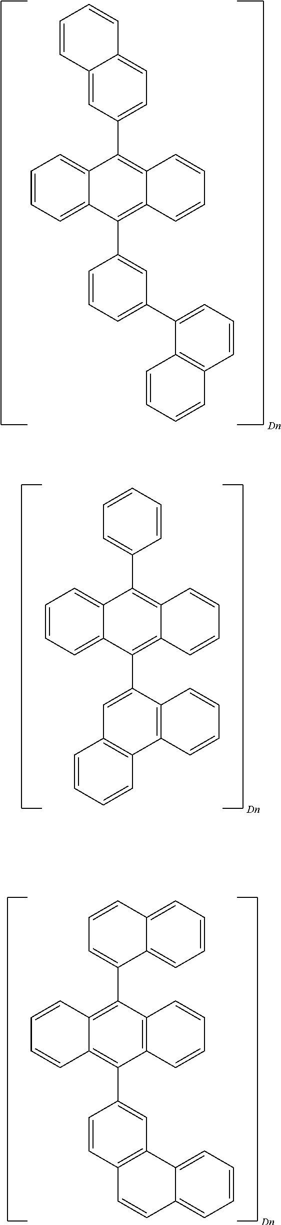

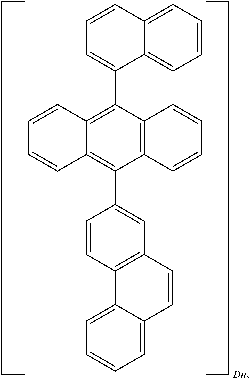

wherein Dn represents n hydrogen atoms being replaced by deuterium, n is a positive integer, and the value of n is from 1 to the maximum number of deuteration.

Using

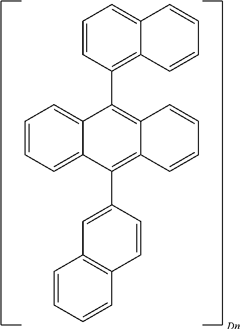

for illustration, it can represent the case where any hydrogen on

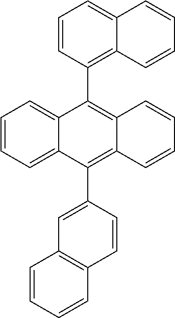 [SMILES: c1ccc2cc(-c3c4ccccc4c(-c4cccc5ccccc45)c4ccccc34)ccc2c1]

is replaced by deuterium, and examples are

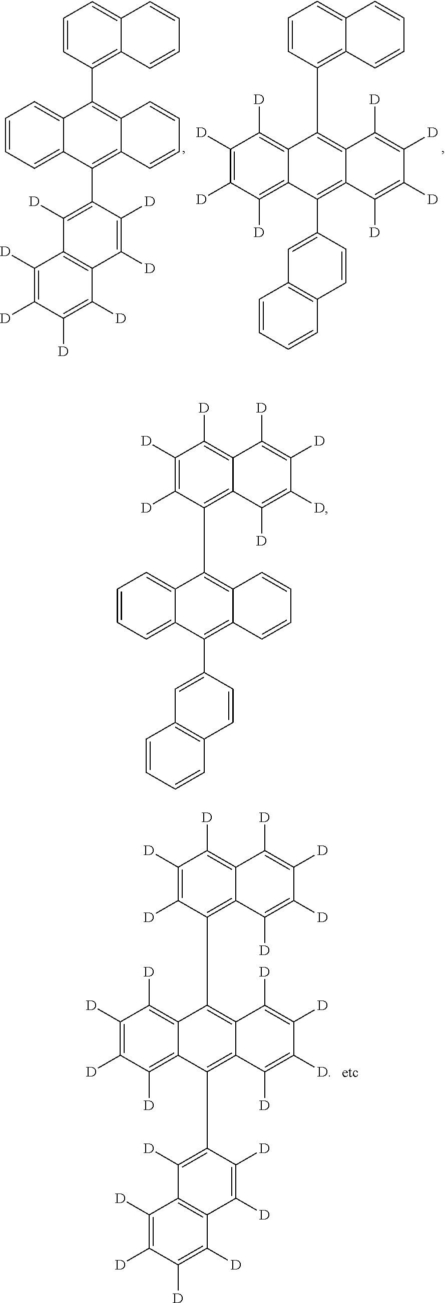

In conjunction with the first aspect, Formula II is selected from one of the following structures:

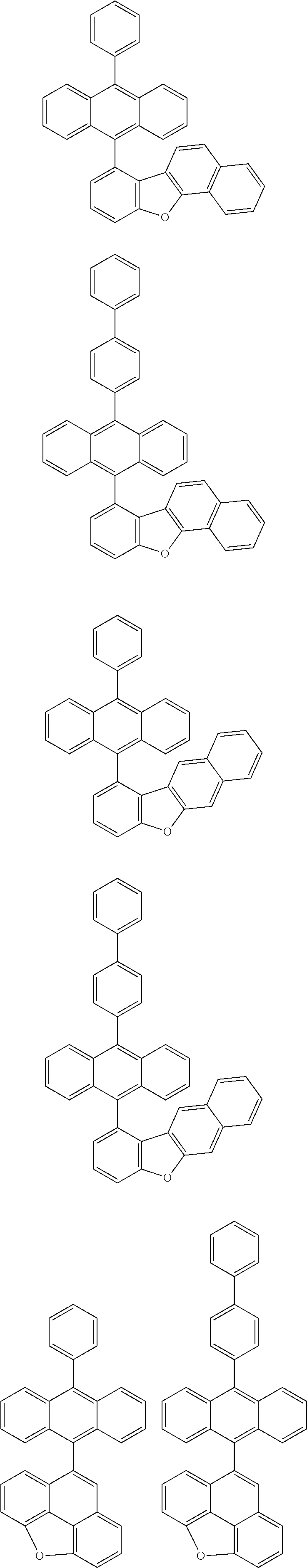

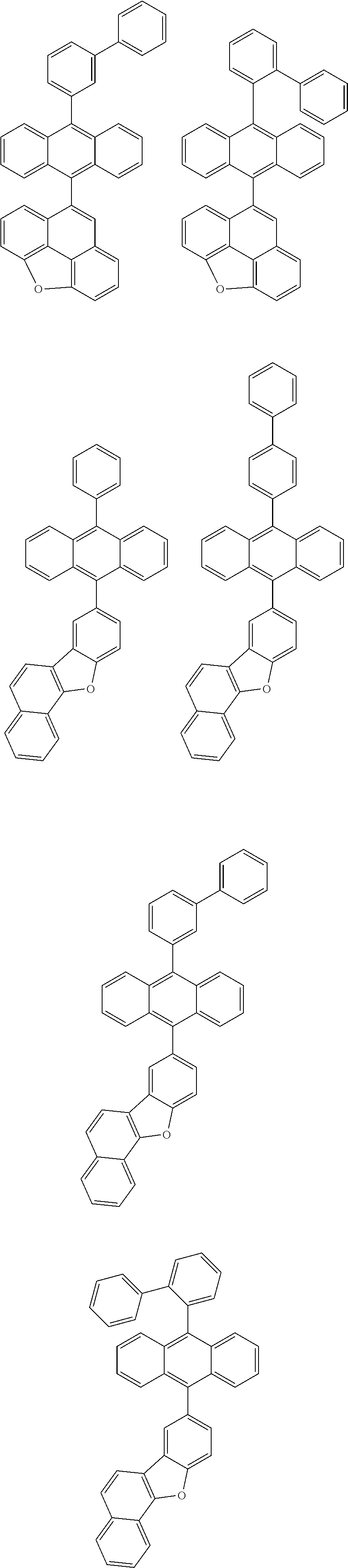

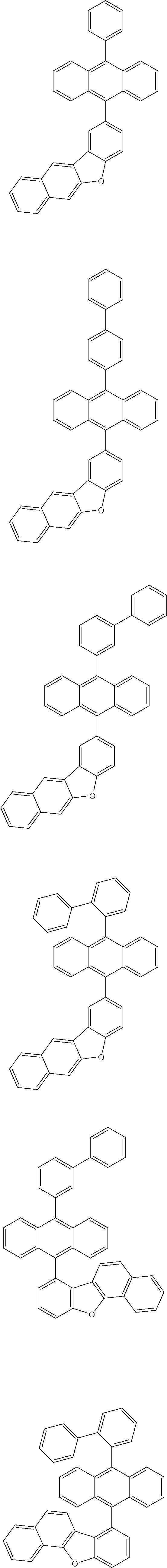

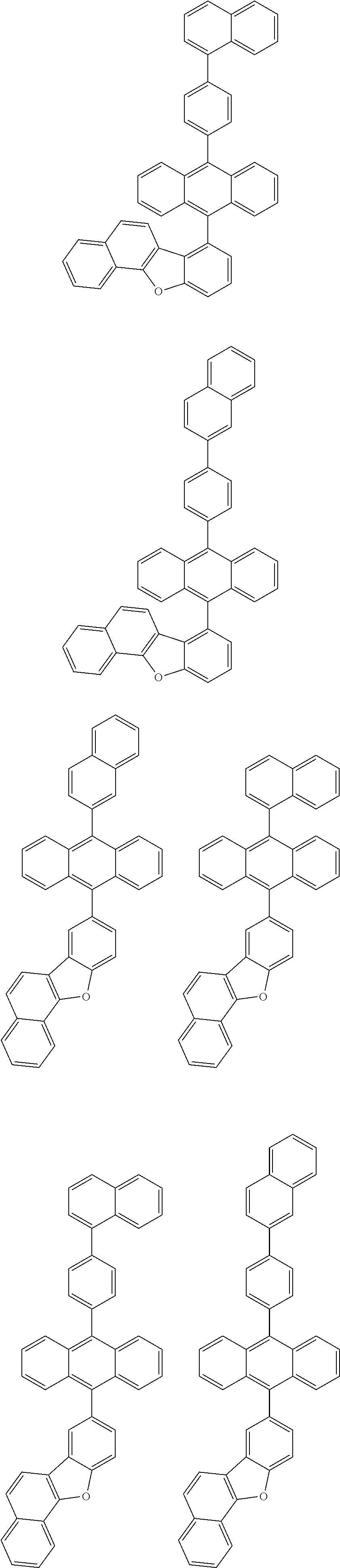

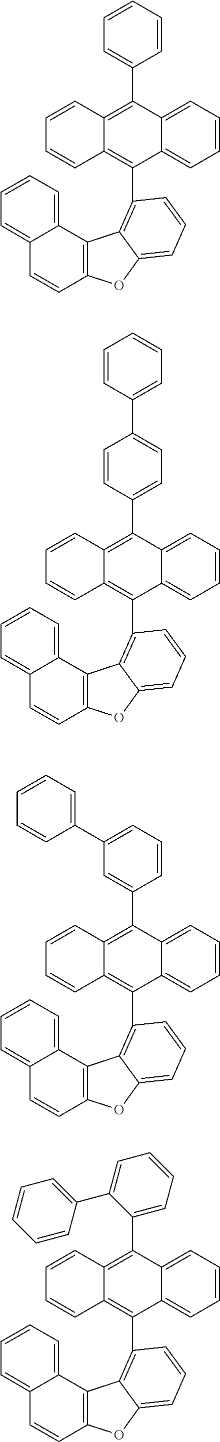

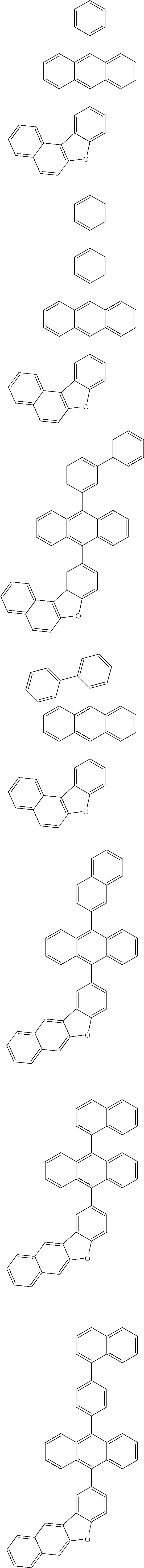

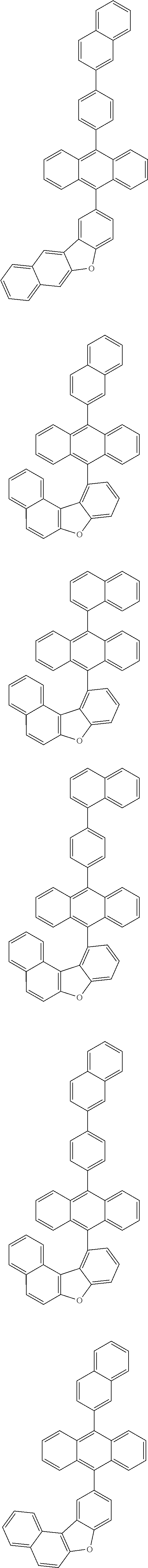

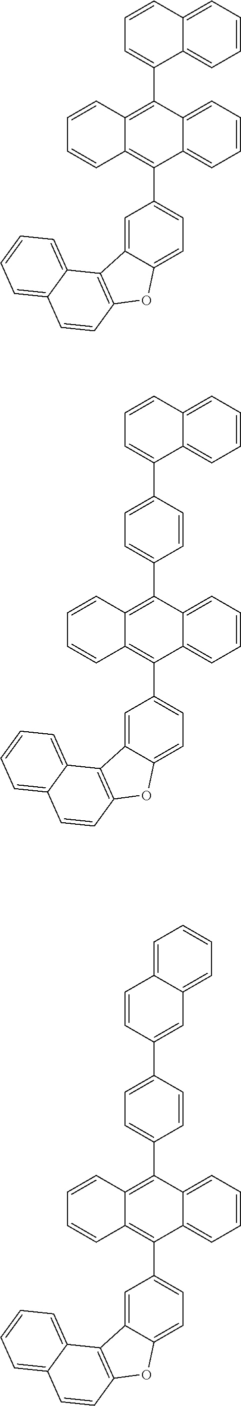

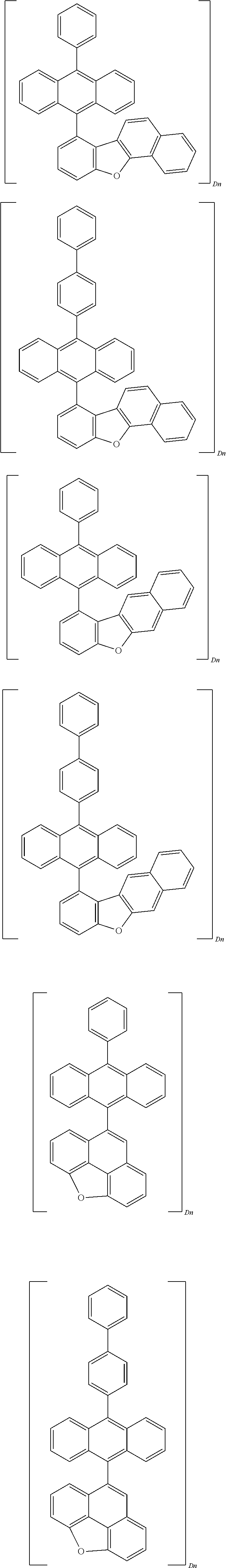

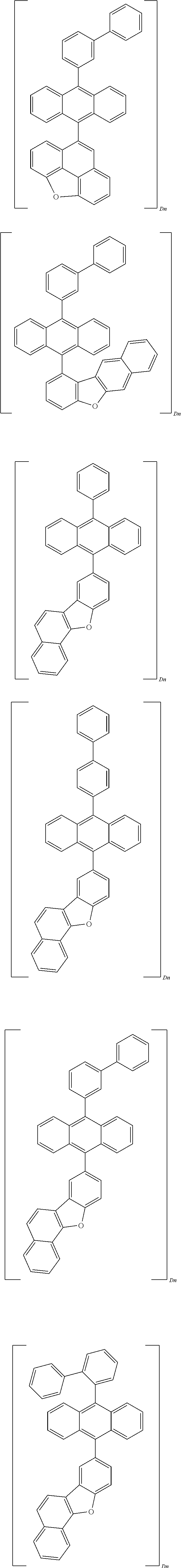

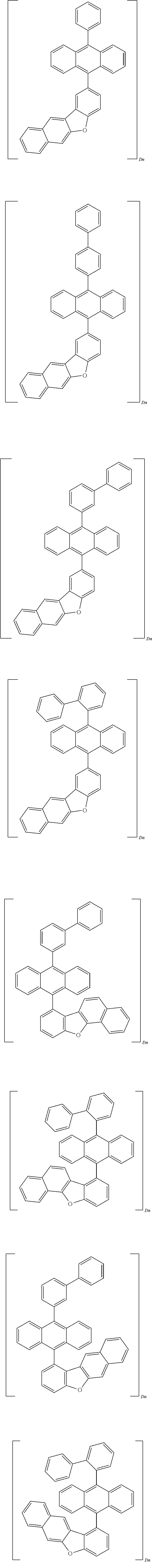

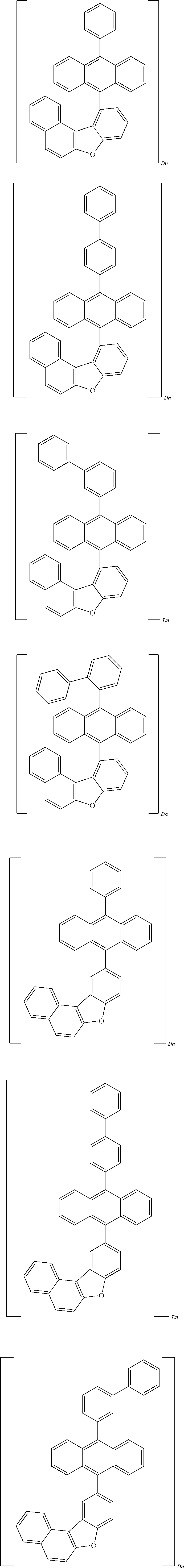

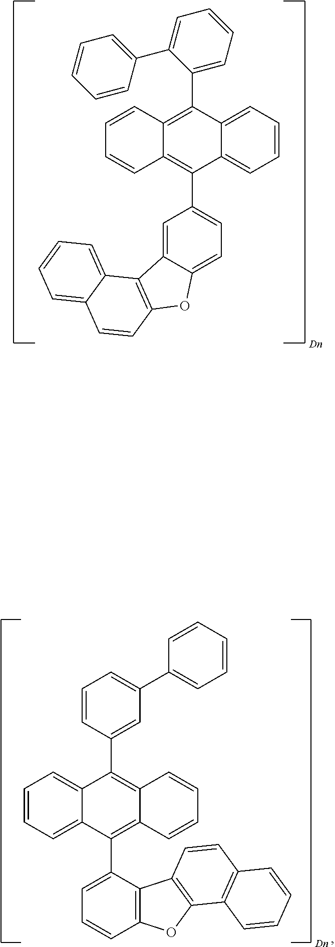

wherein Dn represents n hydrogen atoms being replaced by deuterium, n is a positive integer, and the value of n is from 1 to the maximum number of deuteration.

Furthermore, the blue luminescent host composition is selected from any one of:

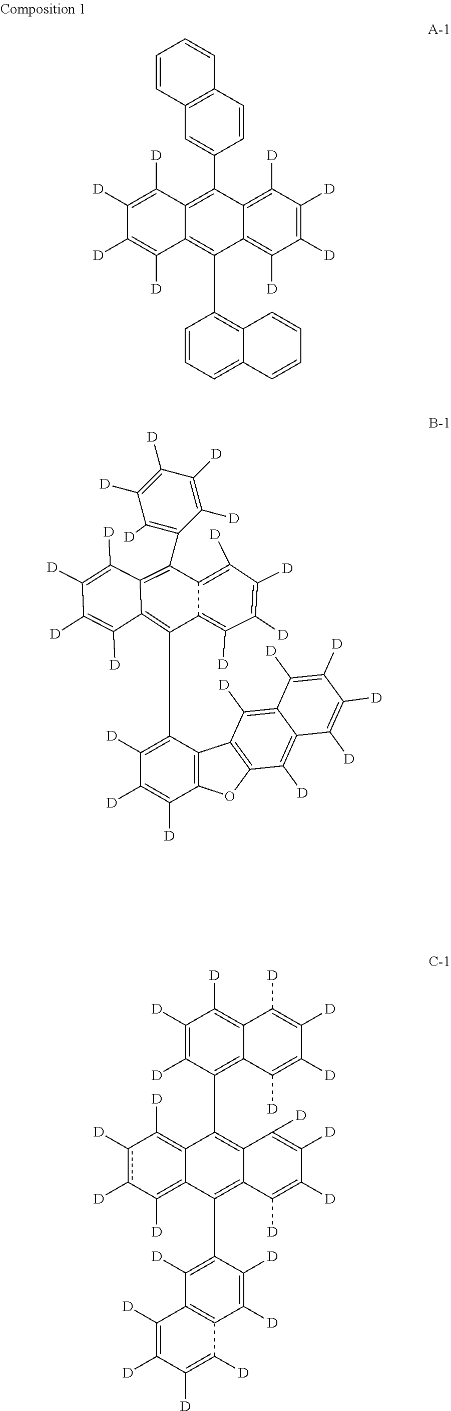

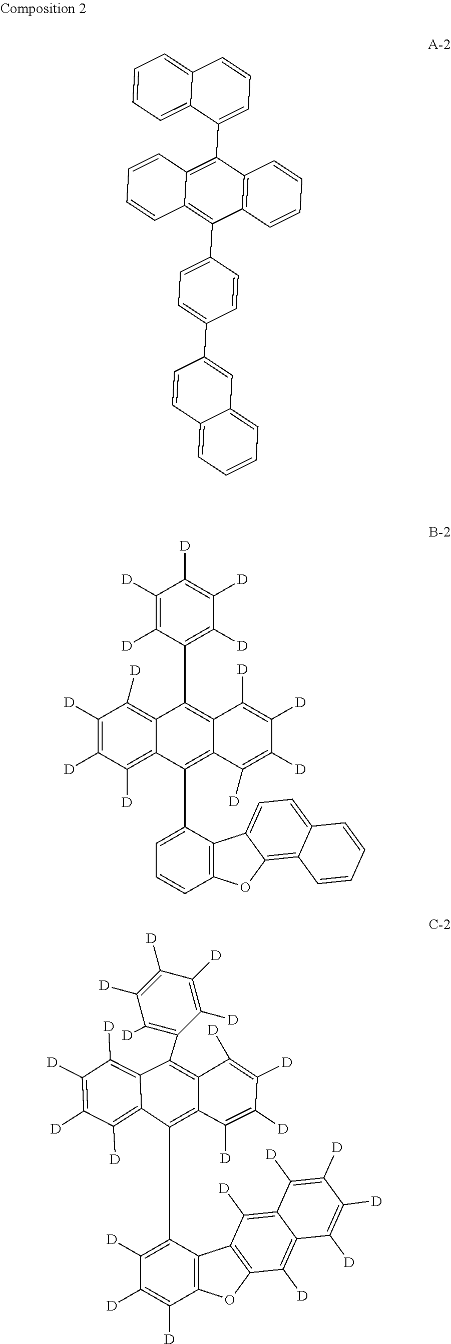

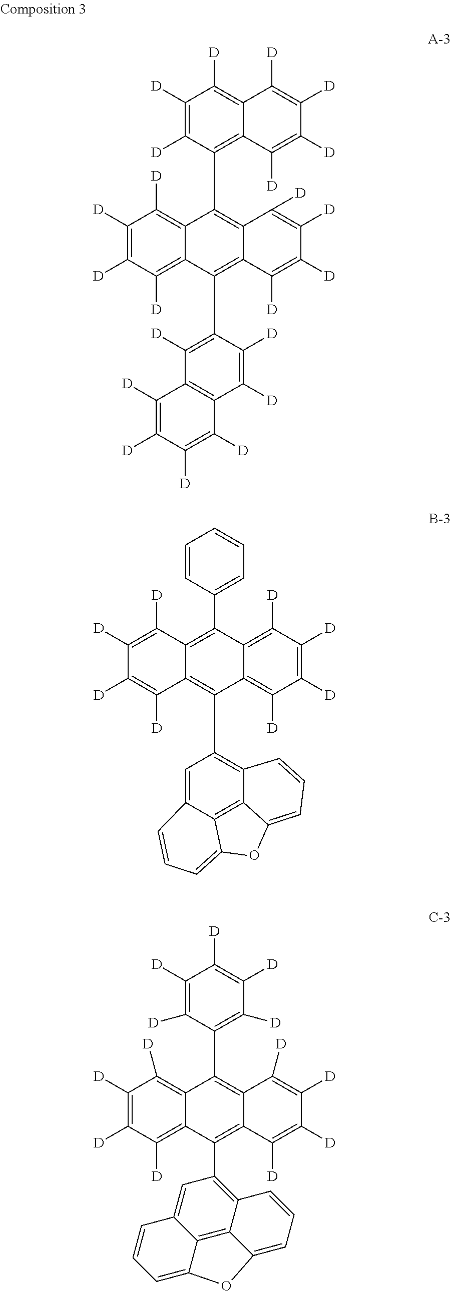 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c2c(-c3cc4cccc5oc6cccc3c6c45)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3cc4cccc5oc6cccc3c6c45)c3c([2H])c([2H])c([2H])c([2H])c23)c([2H])c1[2H]]

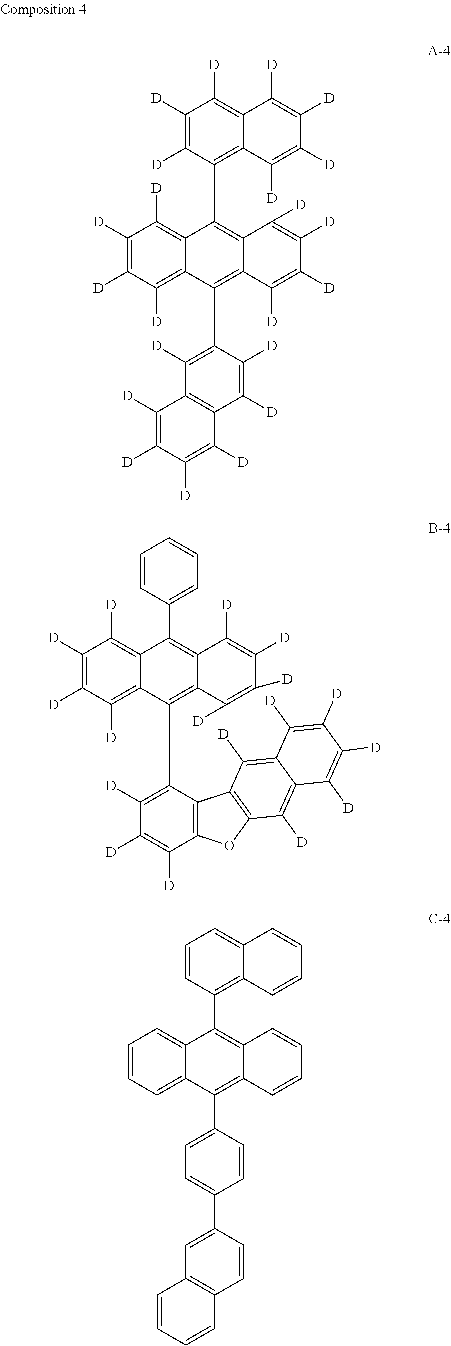

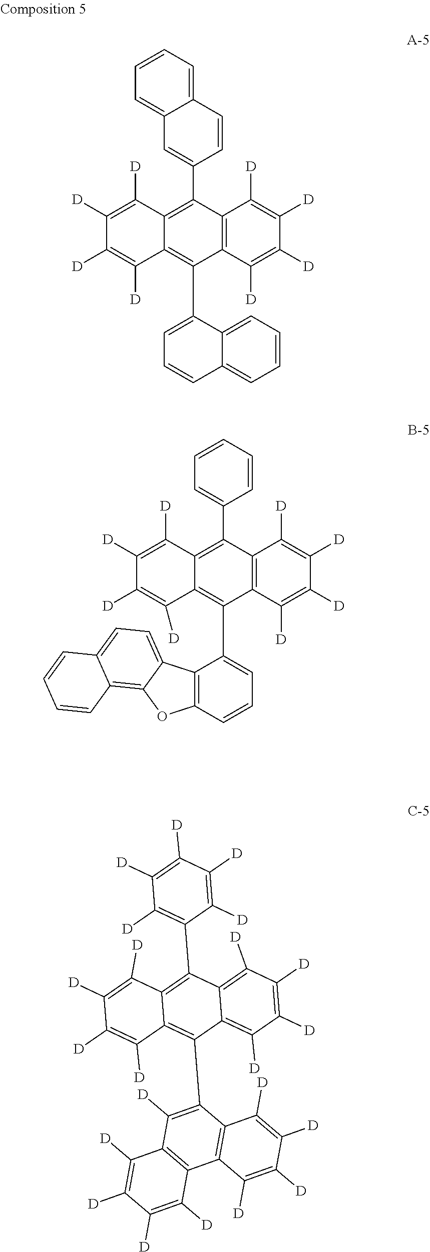 [SMILES: [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3c([2H])c4c([2H])c([2H])c([2H])c([2H])c4c4c([2H])c([2H])c([2H])c([2H])c34)c3c([2H])c([2H])c([2H])c([2H])c23)c([2H])c1[2H]]

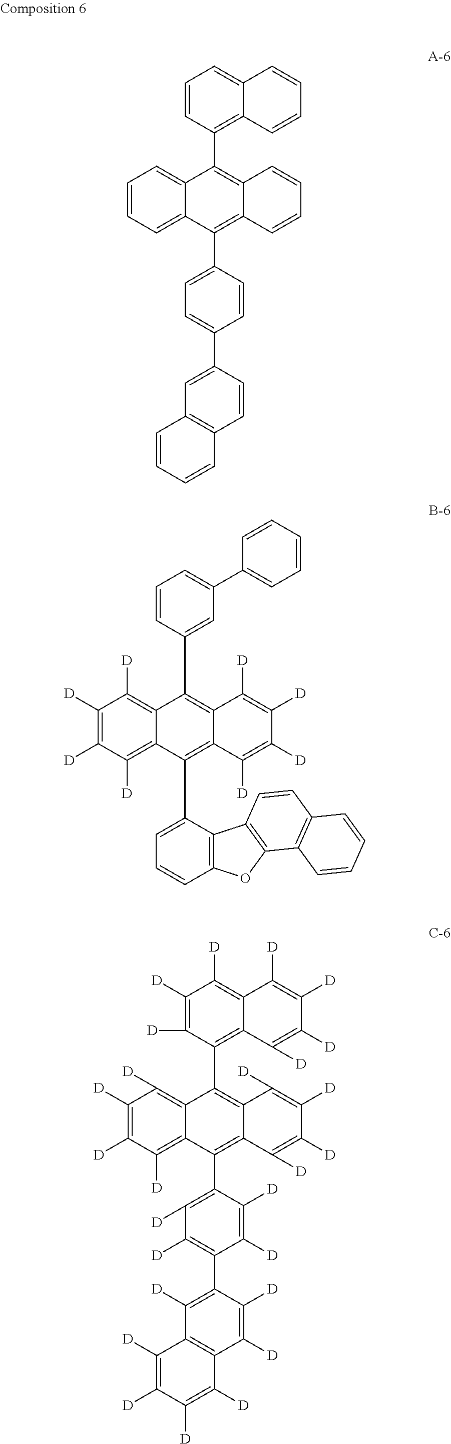

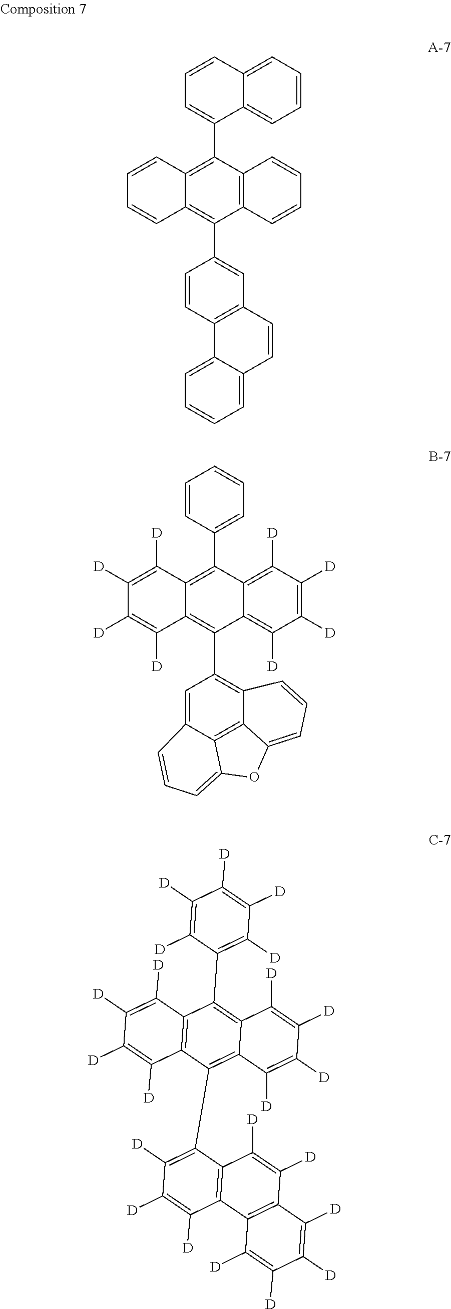

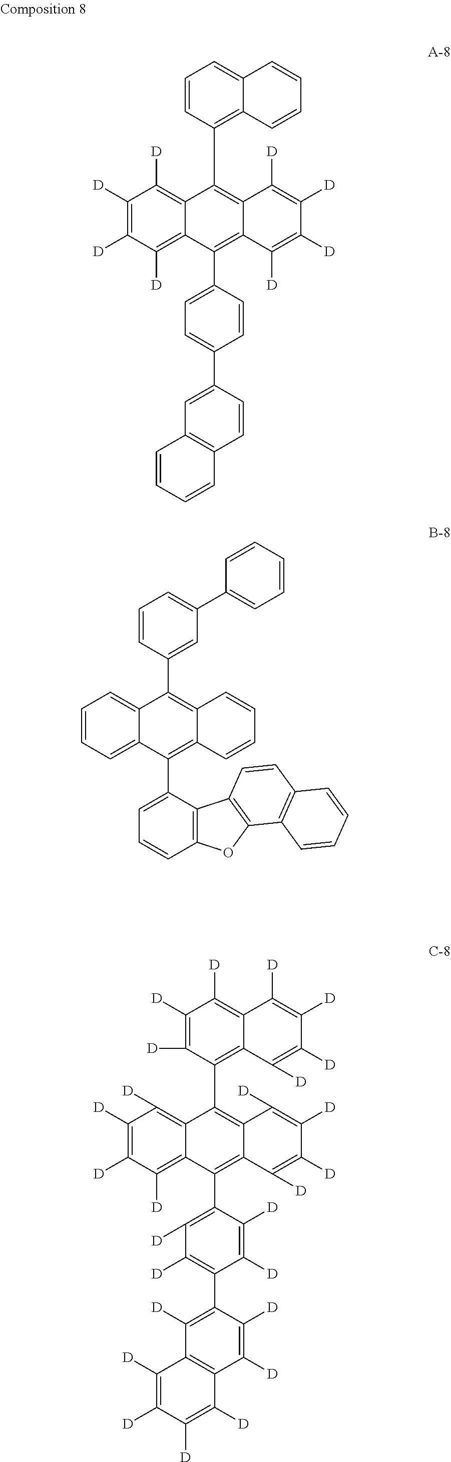 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; c1ccc(-c2cccc(-c3c4ccccc4c(-c4cccc5oc6c7ccccc7ccc6c45)c4ccccc34)c2)cc1 ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H]]

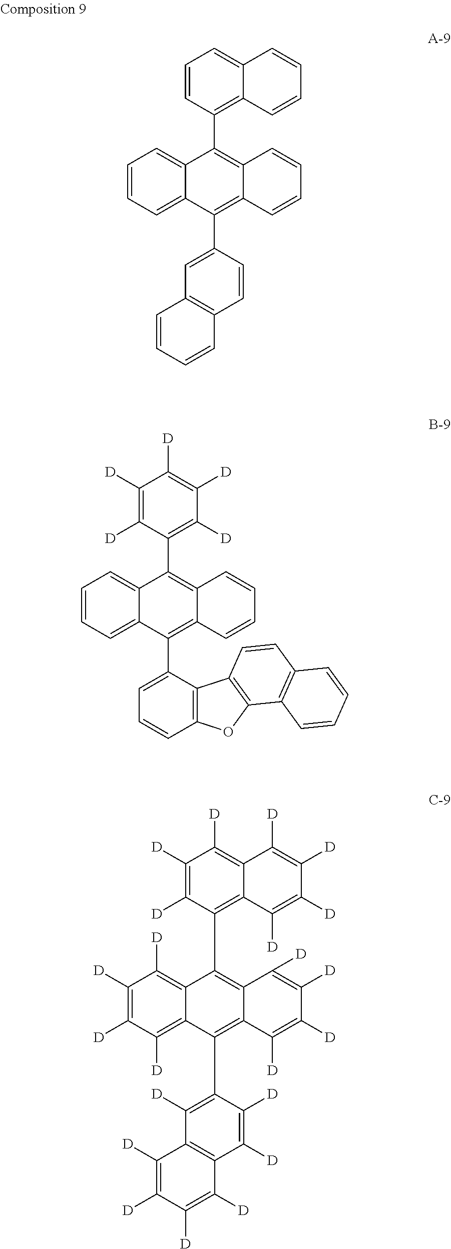

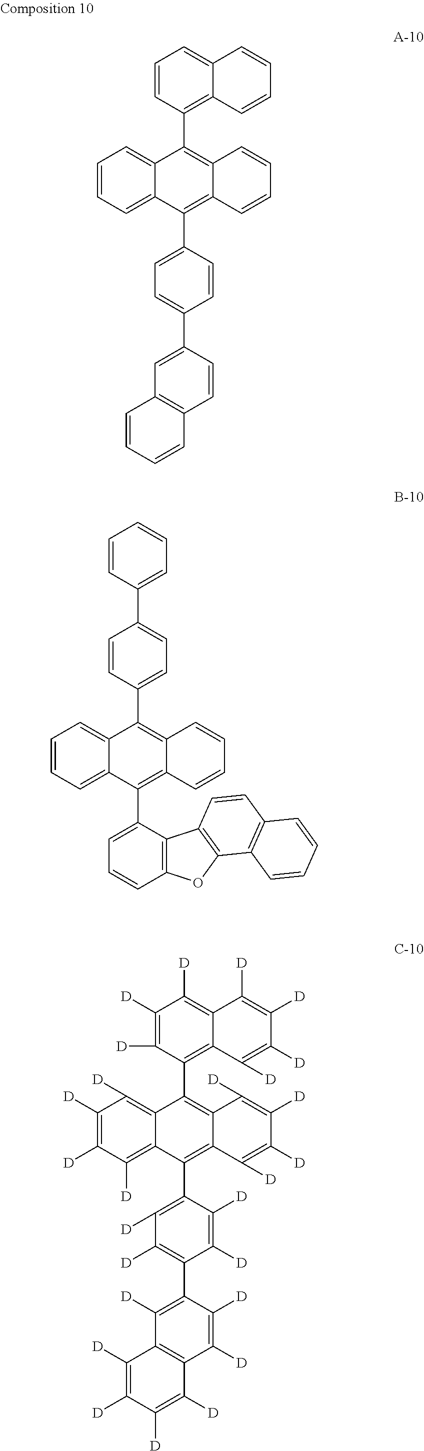

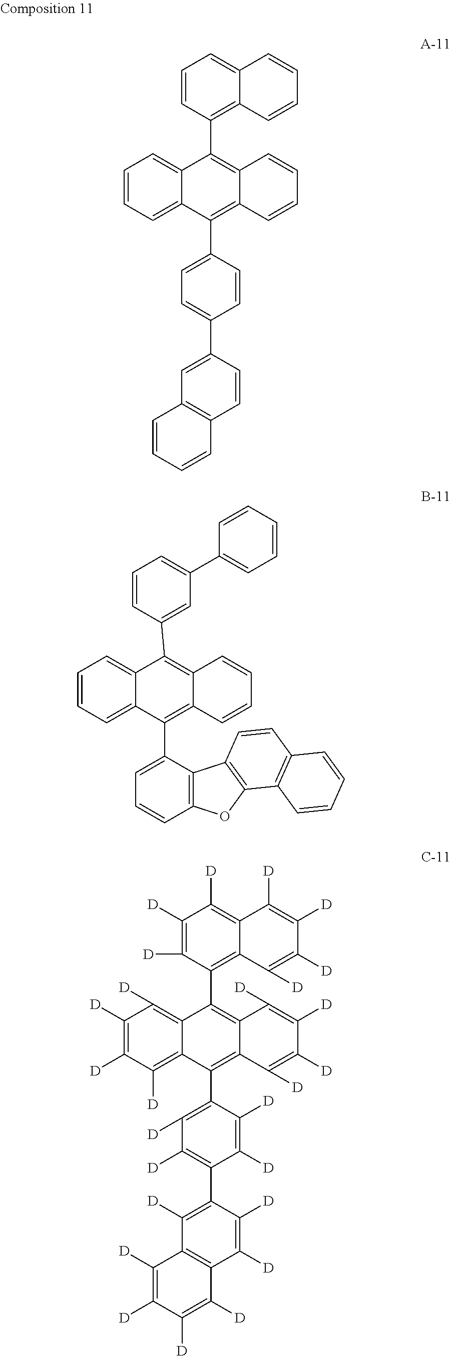

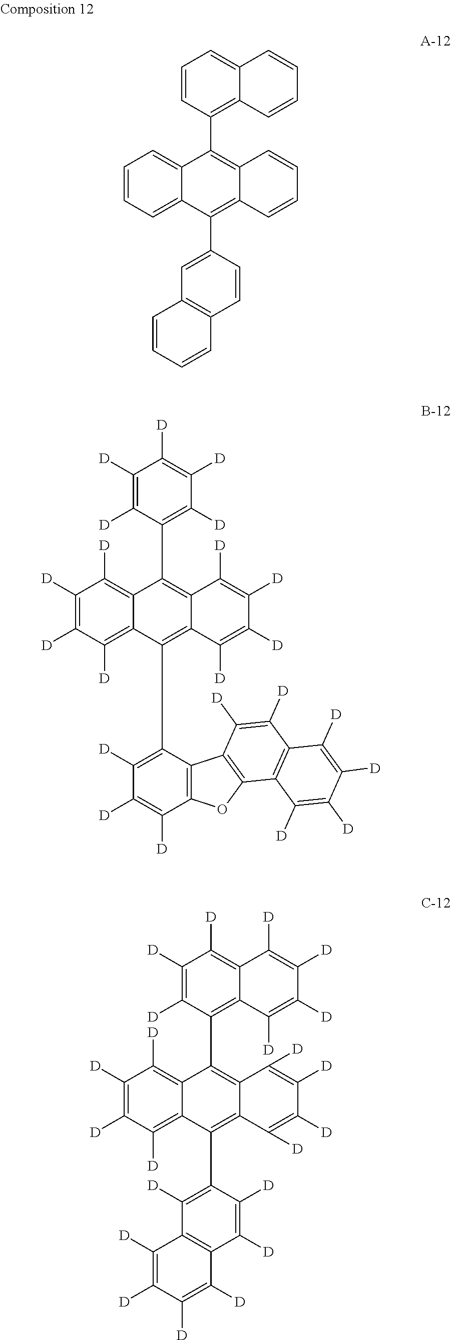

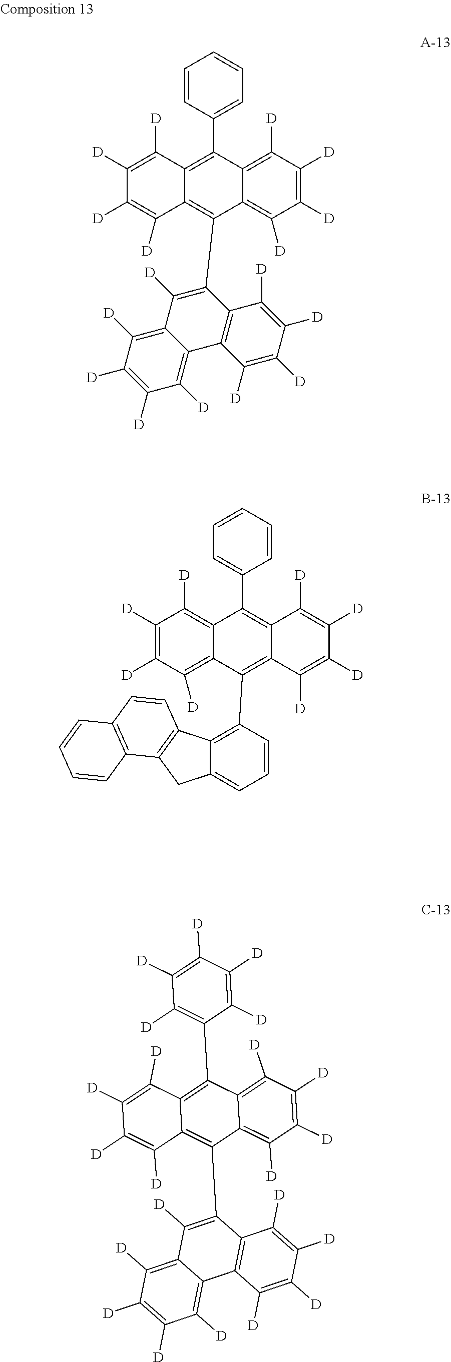 [SMILES: [2H]c1c([2H])c([2H])c2c(-c3c([2H])c4c([2H])c([2H])c([2H])c([2H])c4c4c([2H])c([2H])c([2H])c([2H])c34)c3c([2H])c([2H])c([2H])c([2H])c3c(-c3ccccc3)c2c1[2H] ; [2H]c1c([2H])c([2H])c2c(-c3cccc4c3-c3ccc5ccccc5c3C4)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3c([2H])c4c([2H])c([2H])c([2H])c([2H])c4c4c([2H])c([2H])c([2H])c([2H])c34)c3c([2H])c([2H])c([2H])c([2H])c23)c([2H])c1[2H]]

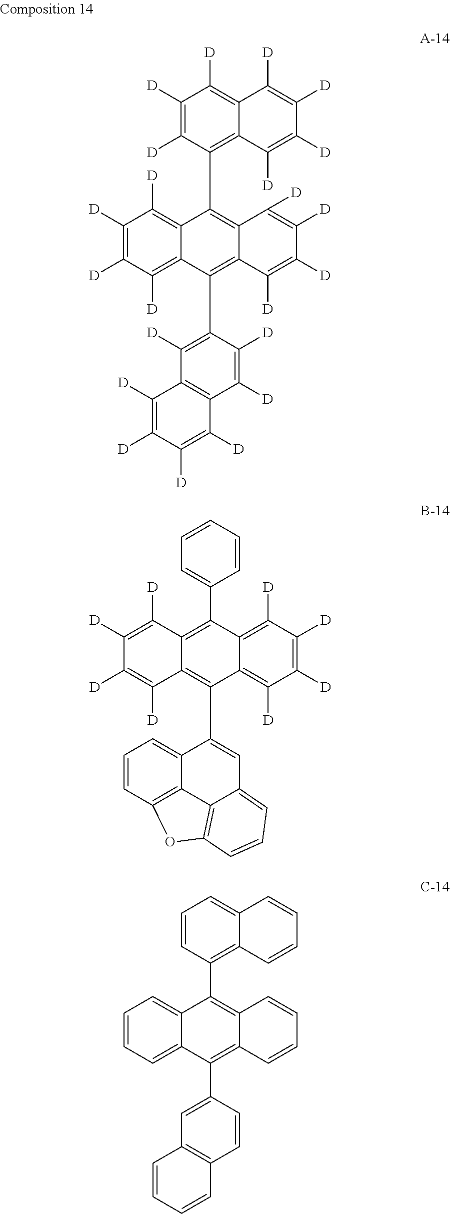

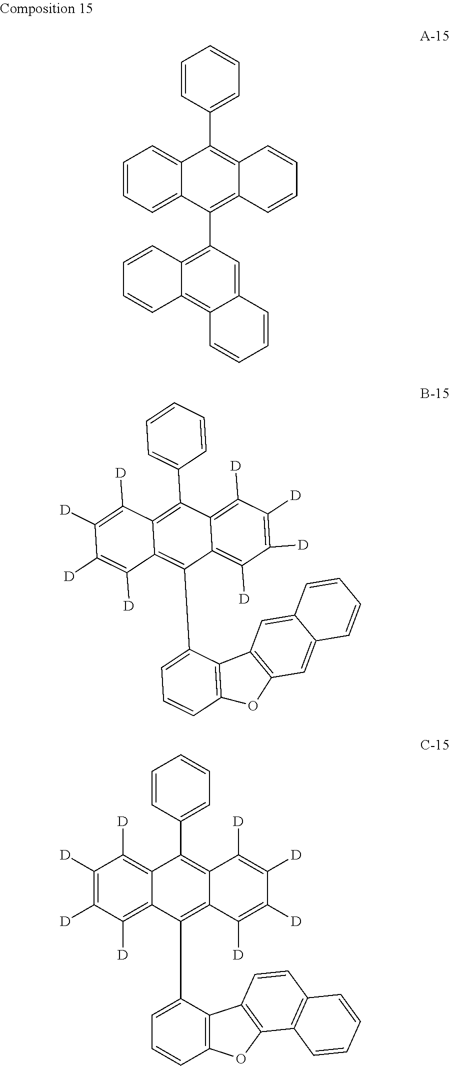

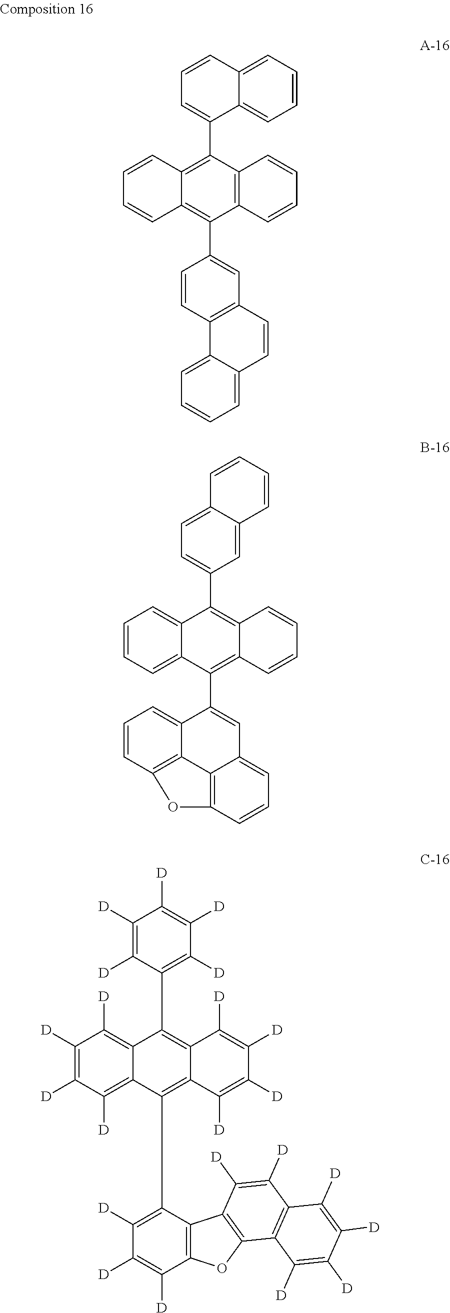

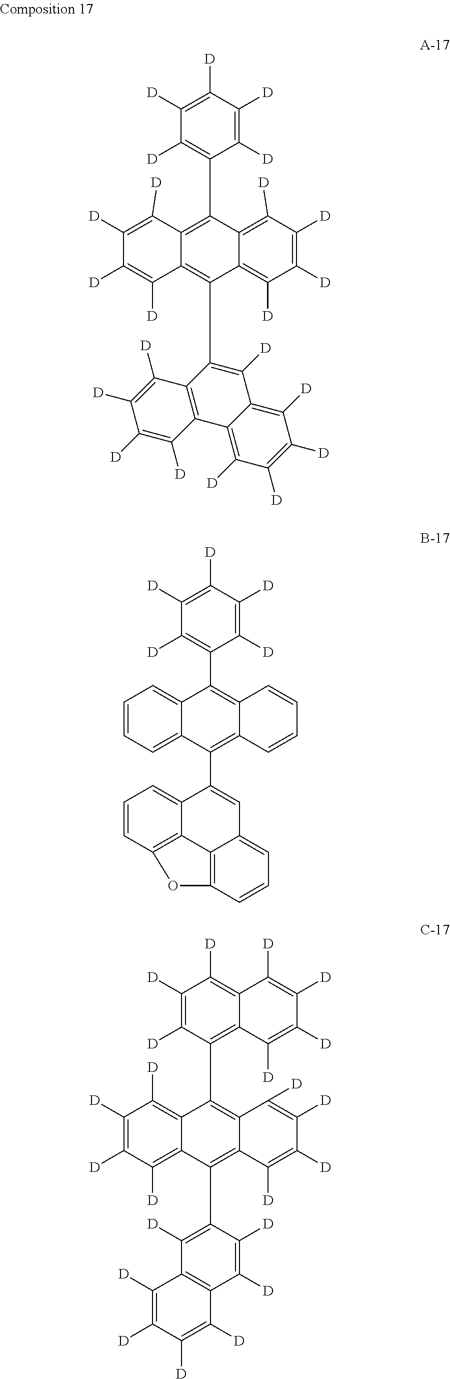 [SMILES: [2H]c1c([2H])c([2H])c(-c2c3c([2H])c([2H])c([2H])c([2H])c3c(-c3c([2H])c4c([2H])c([2H])c([2H])c([2H])c4c4c([2H])c([2H])c([2H])c([2H])c34)c3c([2H])c([2H])c([2H])c([2H])c23)c([2H])c1[2H] ; [2H]c1c([2H])c([2H])c(-c2c3ccccc3c(-c3cc4cccc5oc6cccc3c6c45)c3ccccc23)c([2H])c1[2H] ; [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H]]

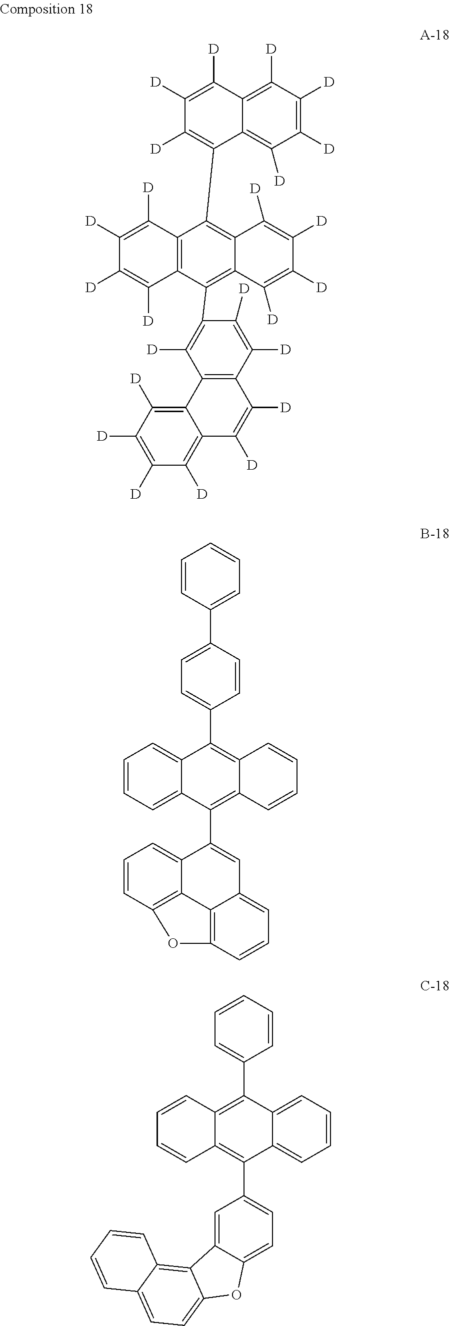

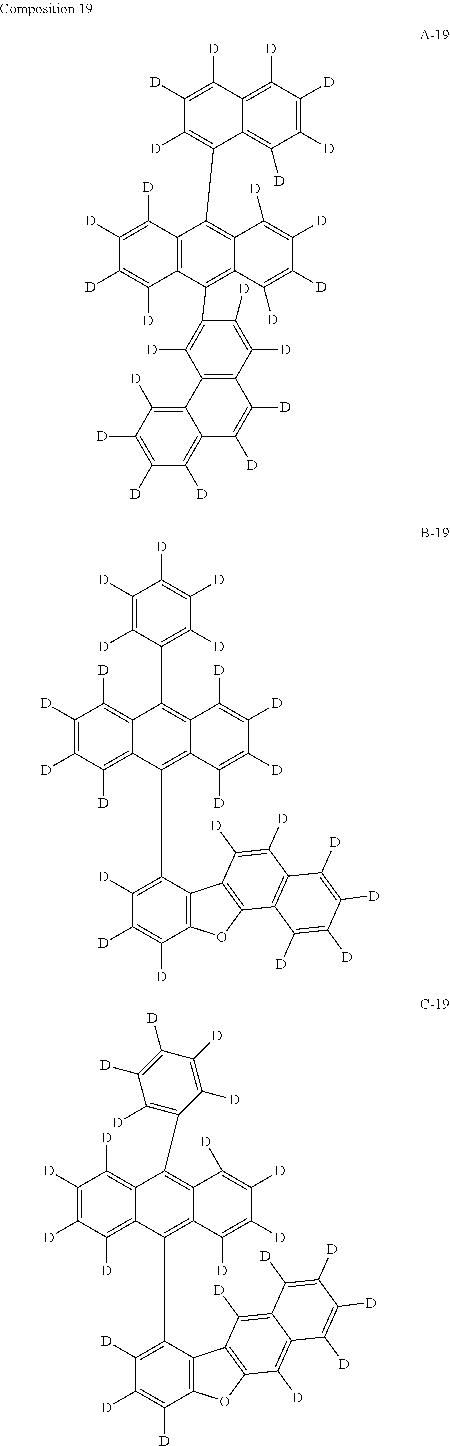

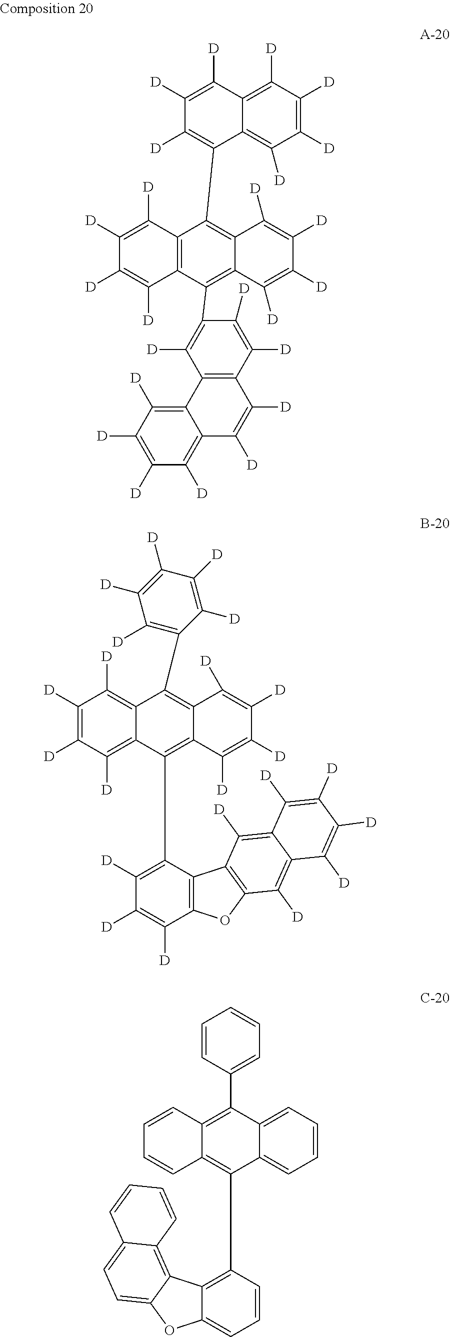 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; c1ccc(-c2c3ccccc3c(-c3cccc4oc5ccc6ccccc6c5c34)c3ccccc23)cc1]

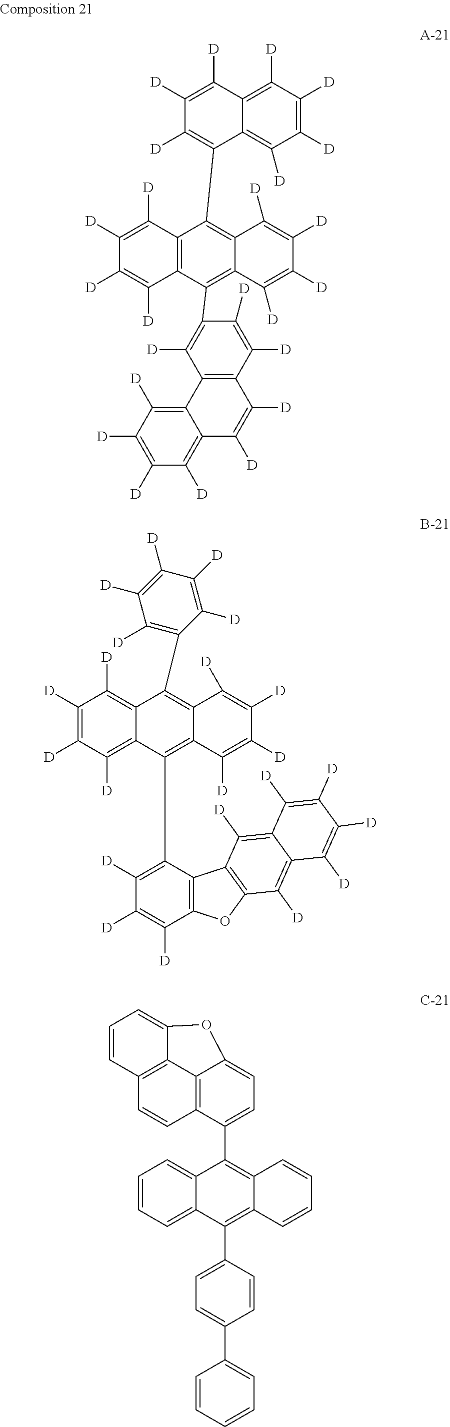 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; c1ccc(-c2ccc(-c3c4ccccc4c(-c4ccc5oc6cccc7ccc4c5c76)c4ccccc34)cc2)cc1]

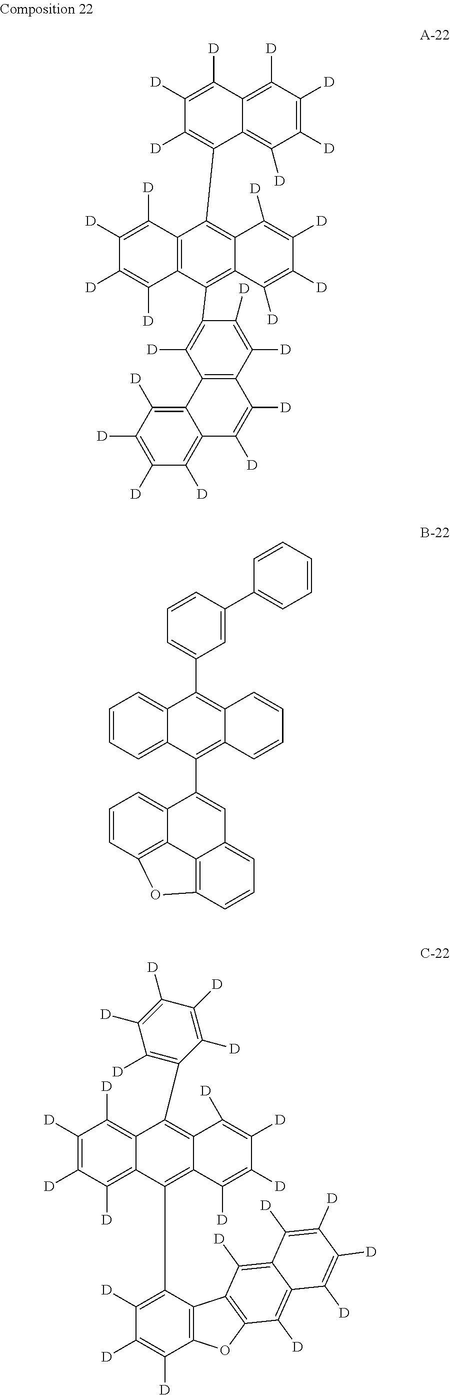 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; c1ccc(-c2cccc(-c3c4ccccc4c(-c4cc5cccc6oc7cccc4c7c56)c4ccccc34)c2)cc1 ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H]]

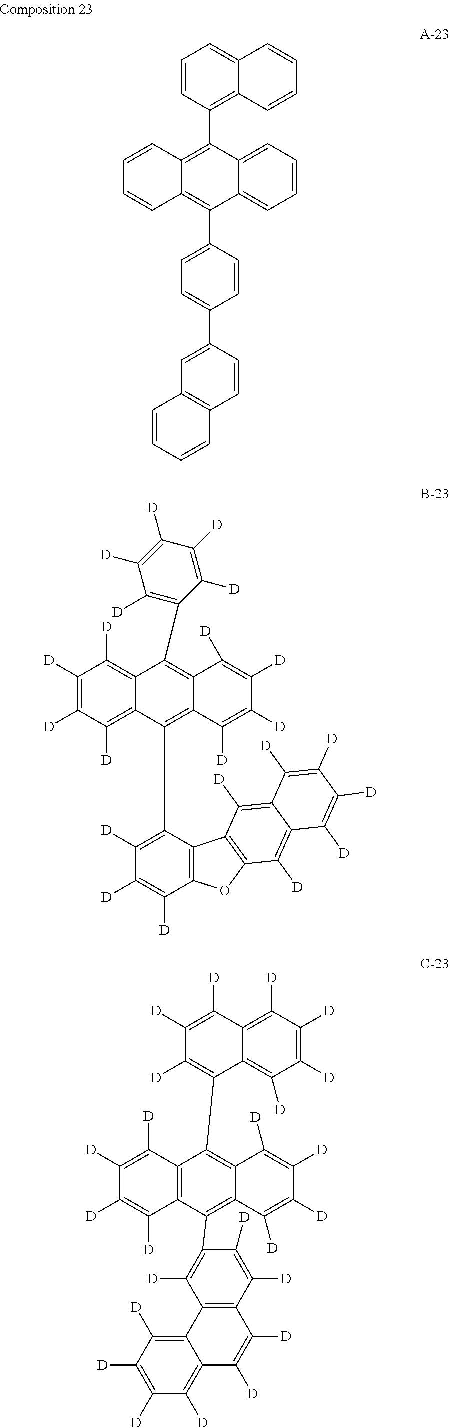

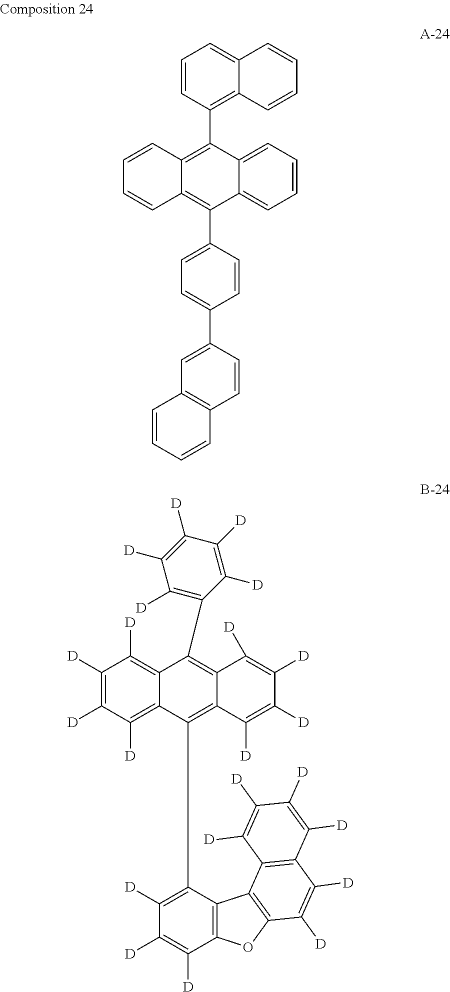

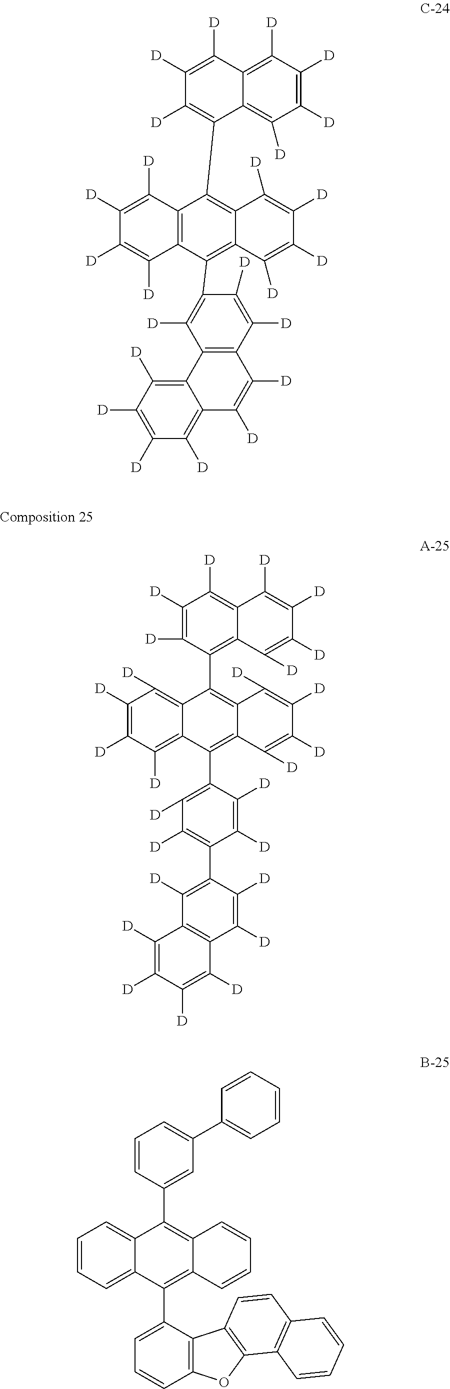 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H] ; c1ccc(-c2cccc(-c3c4ccccc4c(-c4cccc5oc6c7ccccc7ccc6c45)c4ccccc34)c2)cc1]

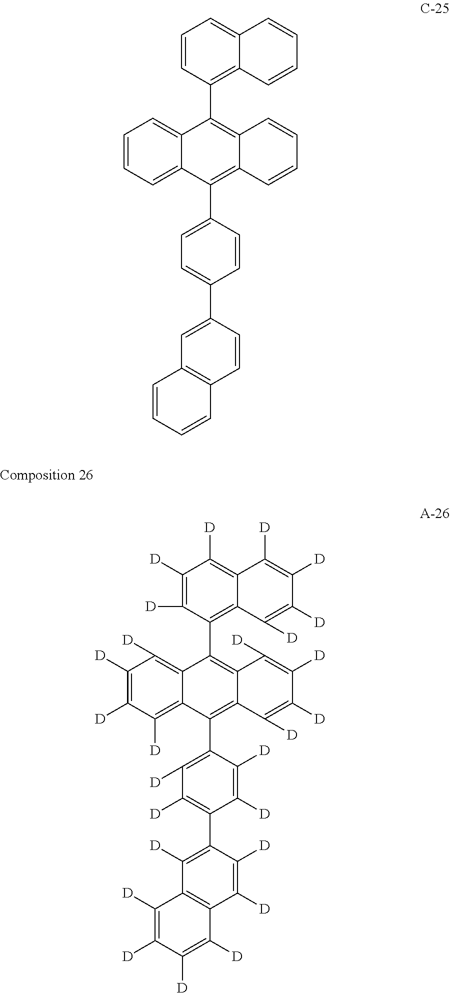

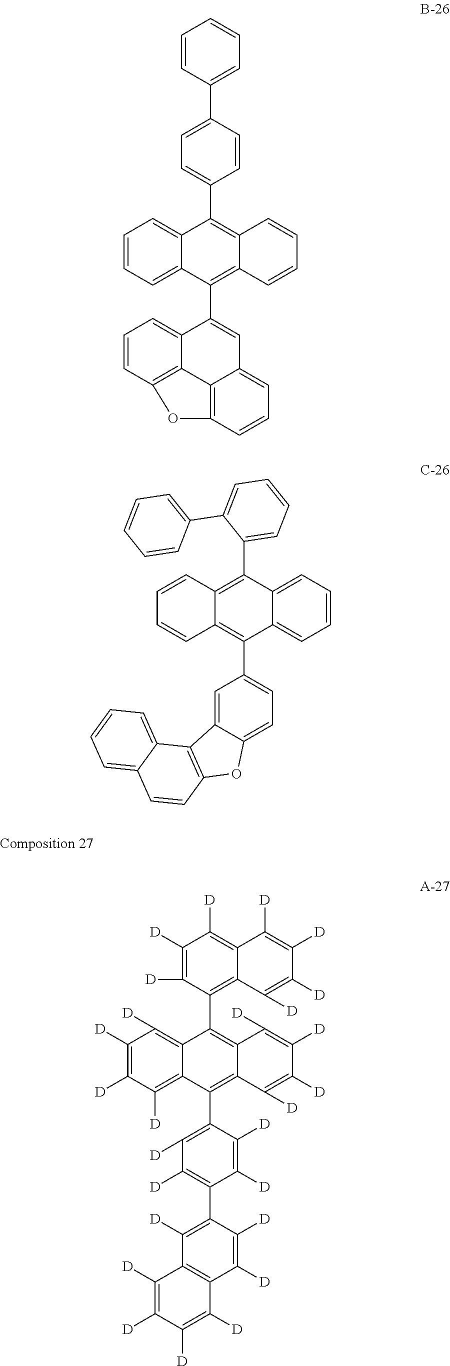 [SMILES: c1ccc(-c2ccc(-c3c4ccccc4c(-c4cc5cccc6oc7cccc4c7c56)c4ccccc34)cc2)cc1 ; c1ccc(-c2ccccc2-c2c3ccccc3c(-c3ccc4oc5ccc6ccccc6c5c4c3)c3ccccc23)cc1 ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H]]

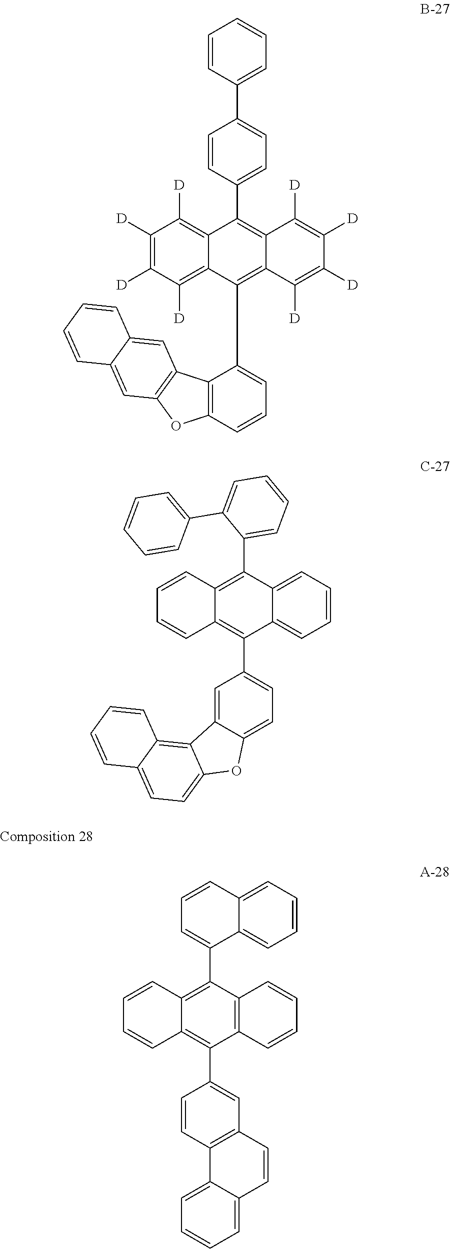

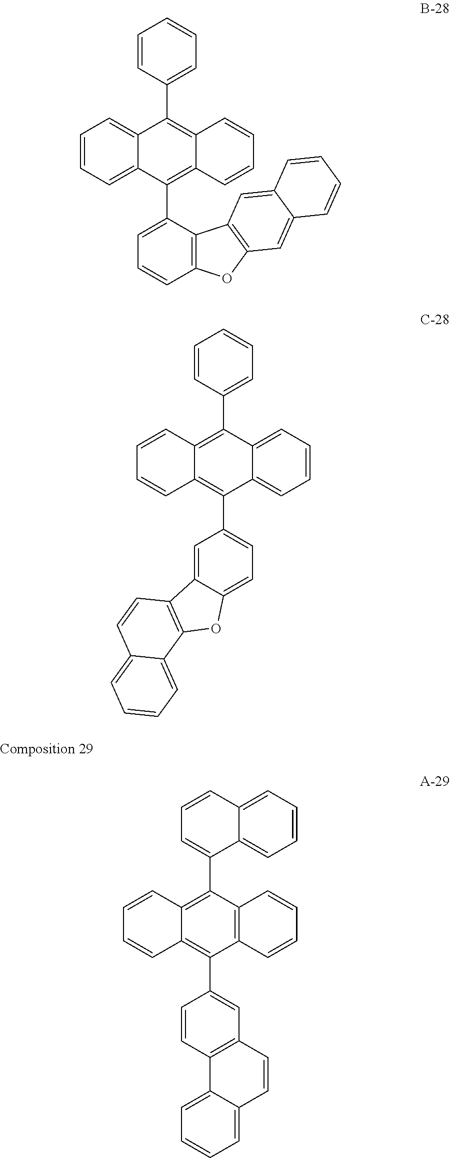

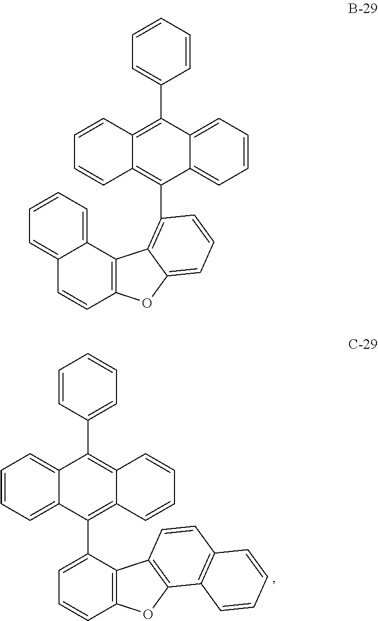

in these compositions, Compounds A-1 to A-29 are the first host compounds, Compounds B-1 to B-29 are the second host compounds, and Compounds C-1 to C-29 are the third host compounds.

A second aspect of the present invention provides an organic electroluminescent device. The organic electroluminescent device comprises an anode, a hole transport region, a luminescent layer, an electron transport region, and a cathode, which are sequentially arranged on a substrate plate, wherein the luminescent layer comprises the blue luminescent host composition as described above.

Furthermore, the luminescent layer comprises a host material and a guest material, wherein the host material comprises the blue luminescent host composition as described above.

A third aspect of the present invention provides a display device comprising the organic electroluminescent device as described above.

### Beneficial Effects of the Invention

The blue luminescent host composition disclosed in the present invention comprises at least three different compounds, i.e., a first host compound, a second host compound, and a third host compound. The compounds defined in the present invention are combined within a mass ratio range defined in the present invention to form a blue luminescent host composition. The composition has a melting point lower than that of each individual compound. The blue luminescent host compounds provided by the present invention are evaporated to form a host composition thin film under continuous working conditions and at different evaporation rates. The blue luminescent host composition provided by the present invention exhibits a relatively constant mass ratio in the final evaporated thin film and a relatively small difference from the initial pre-mixing ratio. The blue luminescent host composition provided by the present invention is applied, as a host material in the luminescent layer, to a blue organic electroluminescent device. The blue luminescent host composition provided by the present invention can not only significantly reduce the driving voltage of the device but can also significantly prolong the lifetime of the device. In addition, under continuous working conditions, the voltage efficiency and lifetime of the organic electroluminescent device prepared using the blue luminescent host composition provided by the present invention are relatively stable, indicating that it is easier to obtain a stable organic electroluminescent device having excellent performance from the blue luminescent host composition provided by the present invention.

### BRIEF DESCRIPTION OF THE DRAWINGS

FIG. 1 is a schematic structural diagram of an organic electroluminescent device of the present invention, wherein 1—substrate, 2—anode, 3—hole injection layer, 4—hole transport layer, 5—luminescent auxiliary layer, 6—luminescent layer, 7—hole barrier layer, 8—electron transport layer, 9—electron injection layer, 10—cathode, and 11—cover layer.

FIG. 2 is a DSC curve of Compound A-1.

FIG. 3 is a DSC curve of Compound B-1.

FIG. 4 is a DSC curve of Compound C-1.

FIG. 5 is a DSC curve of a composition of Compounds A-1, B-1, and C-1 mixed at a mass ratio of 2:5:3.

FIG. 6 is a DSC curve of a composition of Compounds A-1 and B-1 mixed at a mass ratio of 5:5.

### DETAILED DESCRIPTION OF EMBODIMENTS

In order to understand the content of the present invention more clearly, the present invention will be described in detail in conjunction with the accompanying drawings and examples.

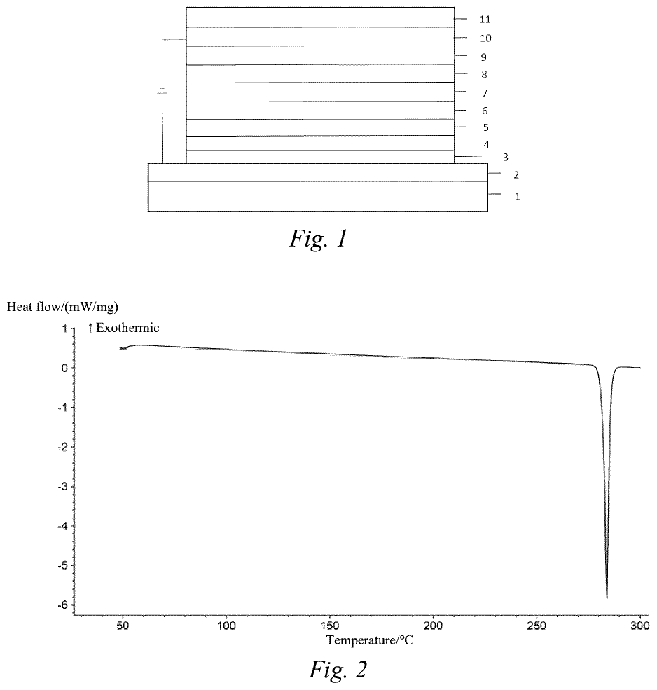

The compound of the present invention is suitable for light-emitting elements, display panels, and electronic devices, especially for organic electroluminescent devices. The electronic device of the present invention is a device comprising a layer of at least one organic compound, and the device may also comprise an inorganic material or a layer formed entirely of an inorganic material. The electronic device is preferably an organic electroluminescent device (OLED), an organic integrated circuit (O-IC), an organic field effect transistor (O-FET), an organic thin film transistor (O-TFT), an organic light-emitting transistor (O-LET), an organic solar cell (O-SC), an organic dye-sensitized solar cell (O-DSSC), an organic optical detector, an organic photosensor, an organic field-quenching device (O-FQD), a luminescent electrochemical cell (LEC), an organic laser diode (O-laser), and an organic plasma emitting device. The electronic device is preferably an organic electroluminescent device (OLED). The schematic structural diagram of an exemplary organic electroluminescent device is as shown in FIG. 1.

### Experimental Part

In order to understand the content of the present invention more clearly, the polycyclic compound, the preparation method for the compound, and the luminescent characteristics of the device will be explained in detail in conjunction with examples. Various chemical reactions can be applied to the synthesis method for a compound according to one embodiment of the present invention. However, it should be noted that the synthesis method for the compound according to one embodiment of the present invention is not limited to the synthesis method described below. Unless otherwise specified, the subsequent synthesis is carried out in an anhydrous solvent in a protective gas atmosphere. Solvents and reagents can be purchased from conventional reagent suppliers.

The compounds used in the following compositions can be purchased from external sources and synthesized in-house.

### Composition Example 1

This example provided a blue luminescent host composition. The blue luminescent host composition was composed of Compounds A-1, B-1, and C-1. The mass proportion of each of the compounds is as shown in Table 1:

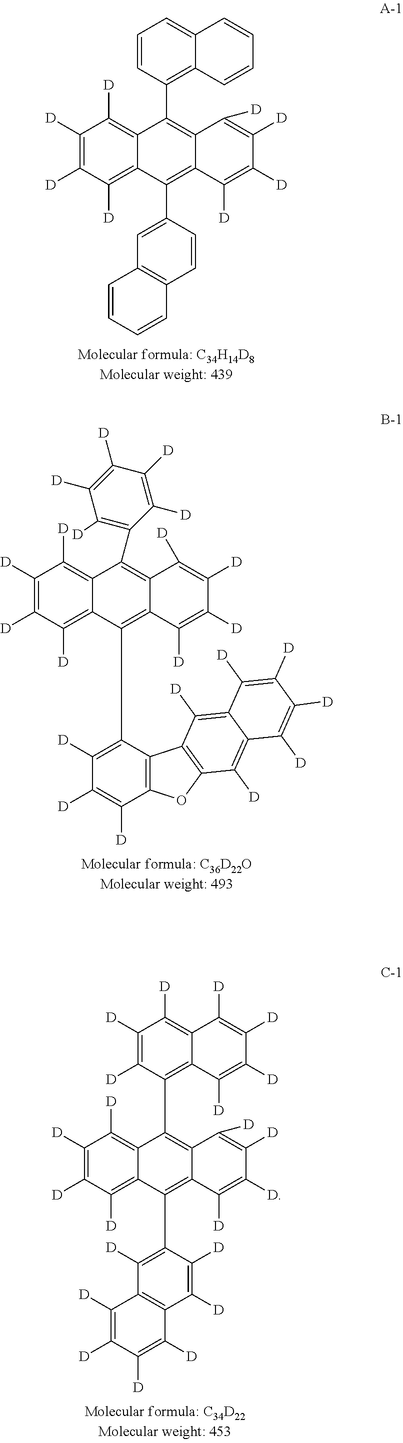

### Composition Example 2

This example provided a blue luminescent host composition. The blue luminescent host composition was composed of Compounds A-2, B-2, and C-2. The mass proportion of each of the compounds is as shown in Table 1:

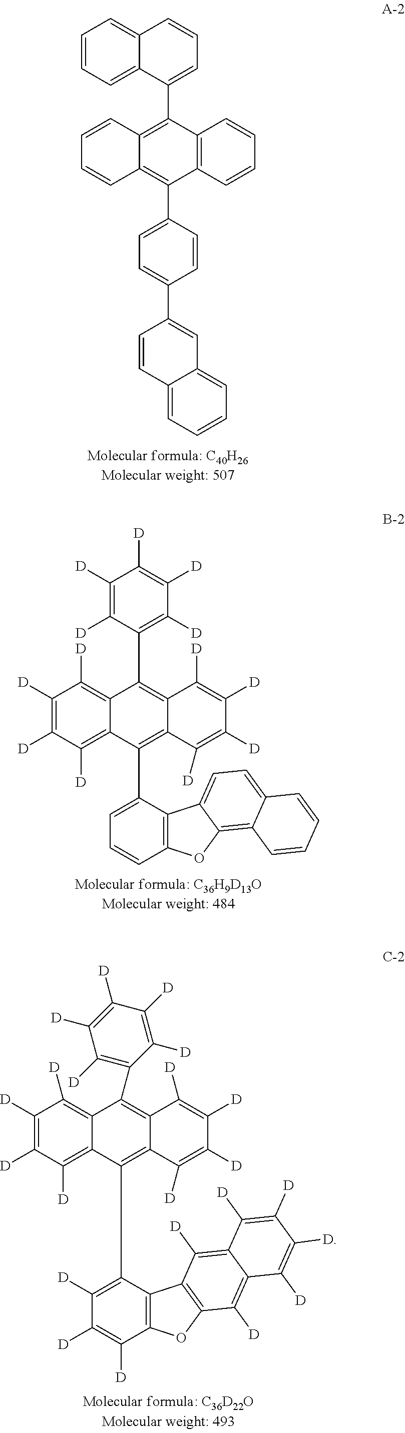

### Composition Example 3

This example provided a blue luminescent host composition. The blue luminescent host composition was composed of Compounds A-3, B-3, and C-3. The mass proportion of each of the compounds is as shown in Table 1:

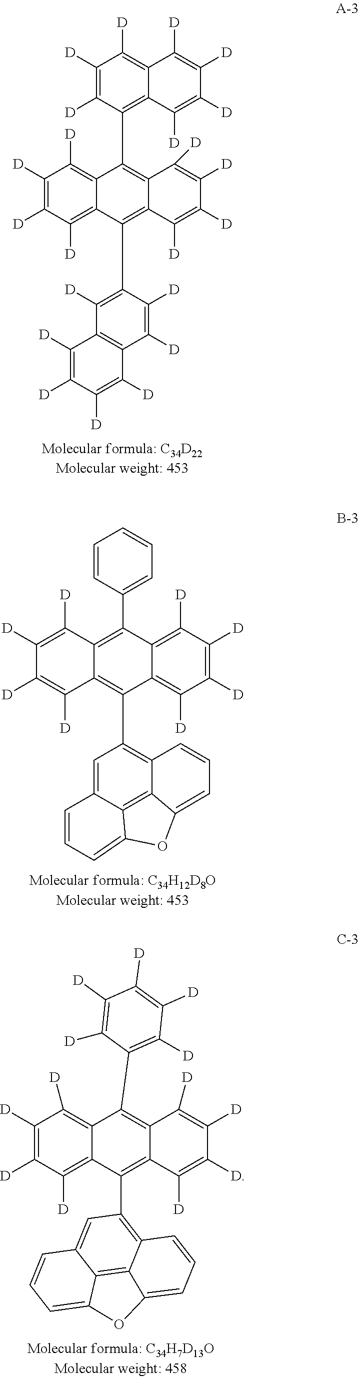

### Composition Example 4

This example provided a blue luminescent host composition. The blue luminescent host composition was composed of Compounds A-4, B-4, and C-4. The mass proportion of each of the compounds is as shown in Table 1:

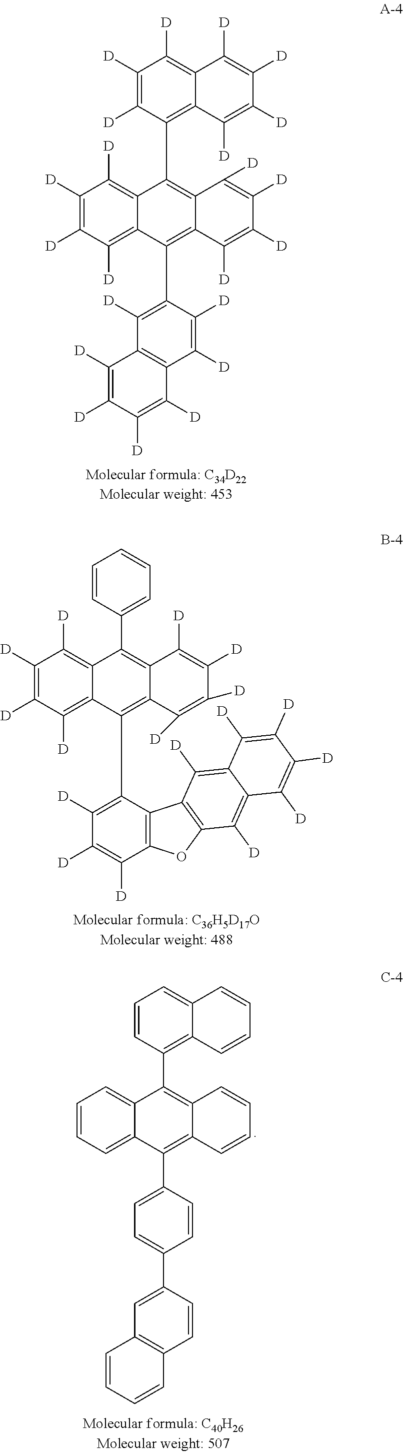

### Composition Example 5

This example provided a blue luminescent host composition. The blue luminescent host composition was composed of Compounds A-5, B-5, and C-5. The mass proportion of each of the compounds is as shown in Table 1:

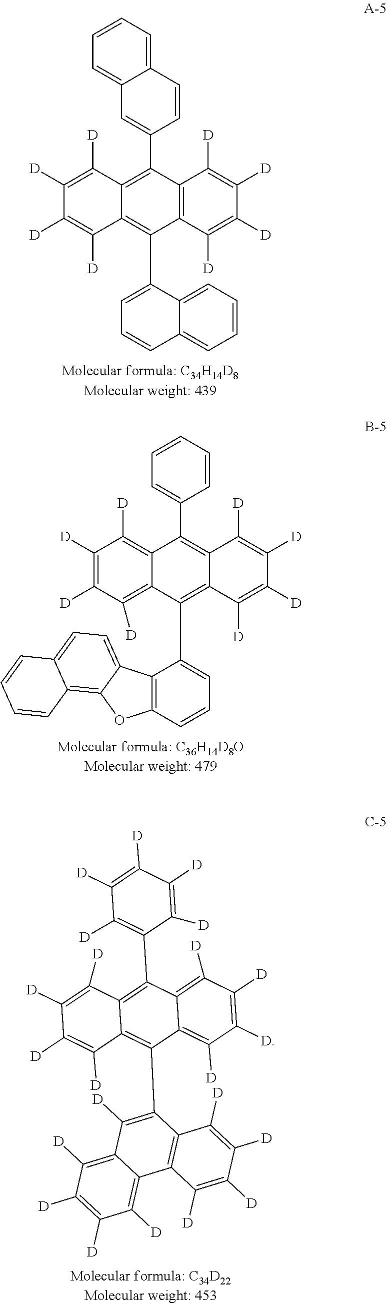

### Composition Example 6

This example provided a blue luminescent host composition. The blue luminescent host composition was composed of Compounds A-6, B-6, and C-6. The mass proportion of each of the compounds is as shown in Table 1:

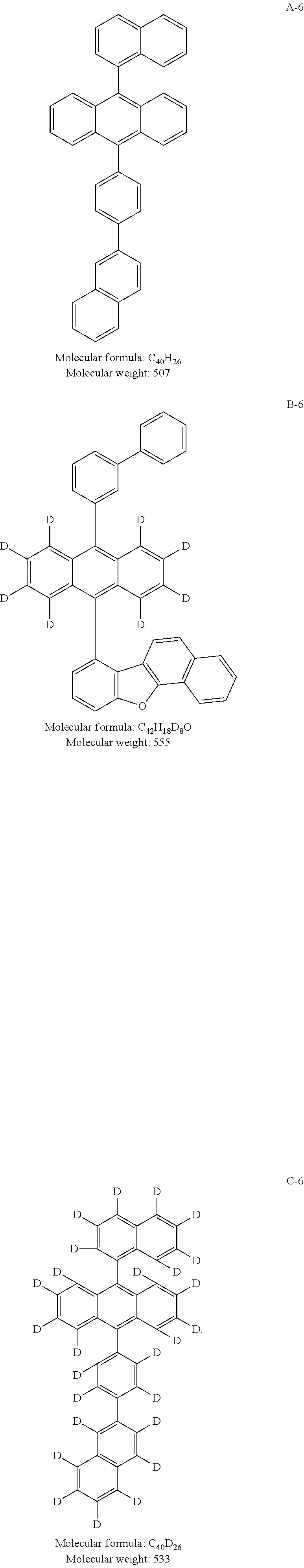

### Composition Example 7

This example provided a blue luminescent host composition. The blue luminescent host composition was composed of Compounds A-7, B-7, and C-7. The mass proportion of each of the compounds is as shown in Table 1:

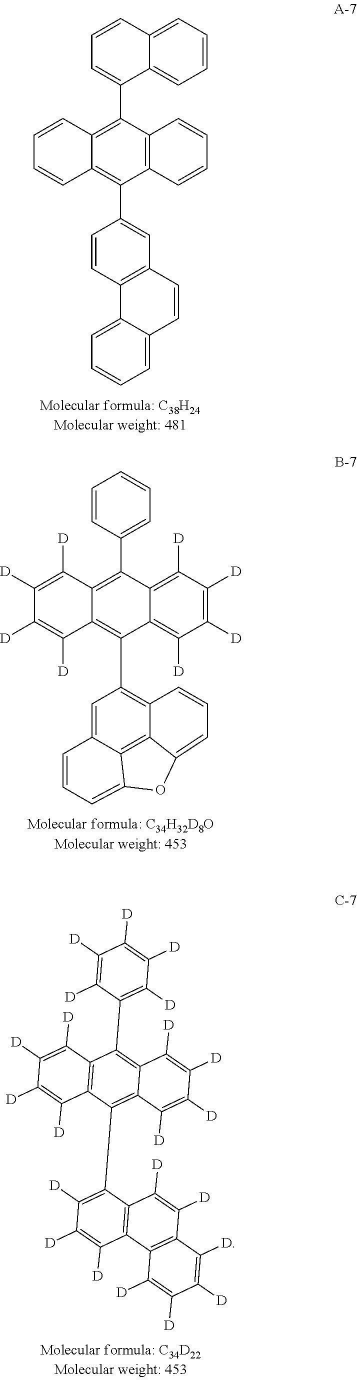

### Composition Example 8

This example provided a blue luminescent host composition. The blue luminescent host composition was composed of Compounds A-8, B-8, and C-8. The mass proportion of each of the compounds is as shown in Table 1:

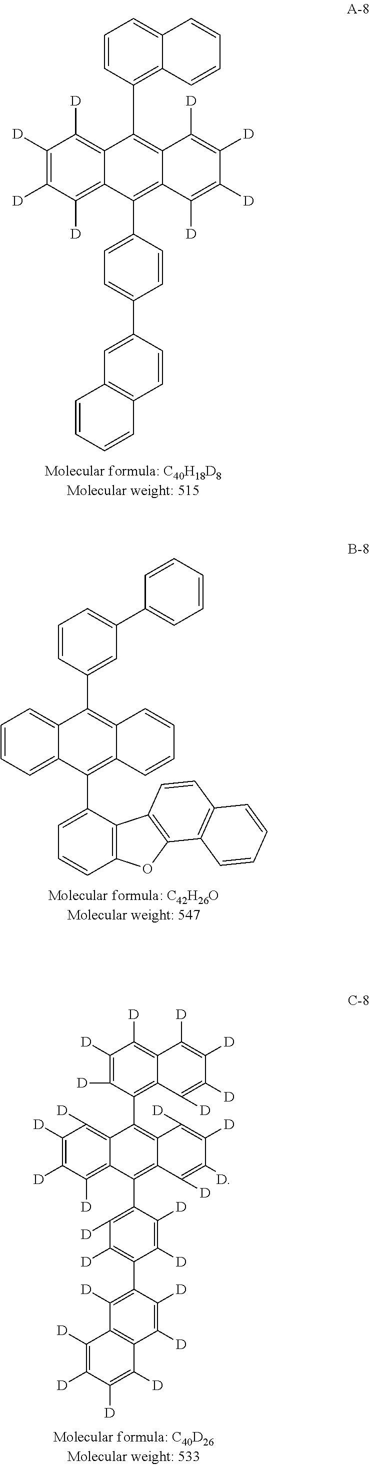

### Composition Example 9

This example provided a blue luminescent host composition. The blue luminescent host composition was composed of Compounds A-9, B-9, and C-9. The mass proportion of each of the compounds is as shown in Table 1:

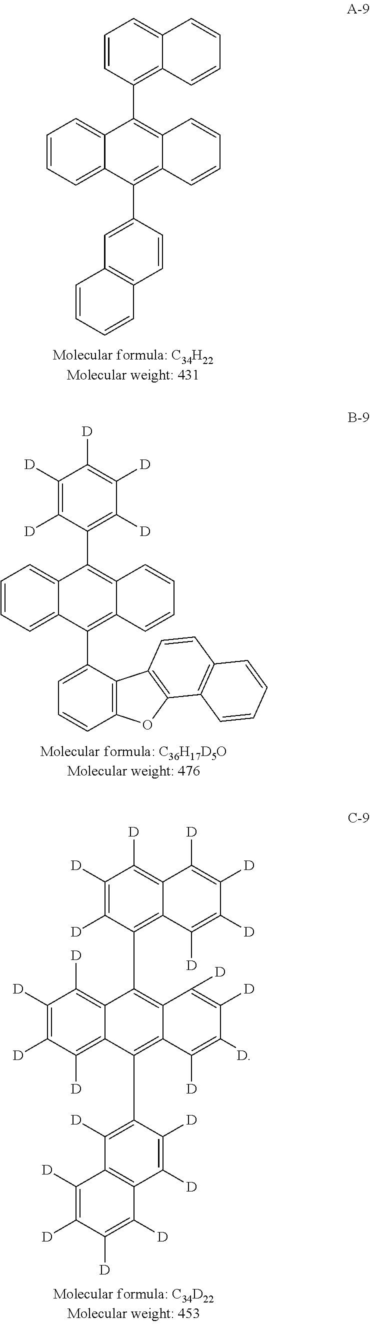

### Composition Example 10

This example provided a blue luminescent host composition. The blue luminescent host composition was composed of Compounds A-10, B-10, and C-10. The mass proportion of each of the compounds is as shown in Table 1:

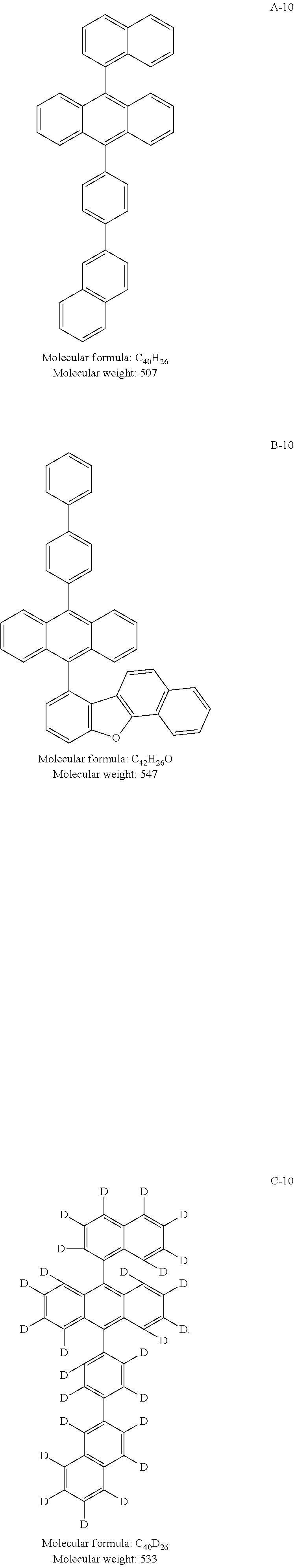

### Composition Example 11

This example provided a blue luminescent host composition. The blue luminescent host composition was composed of Compounds A-11, B-11, and C-11. The mass proportion of each of the compounds is as shown in Table 1:

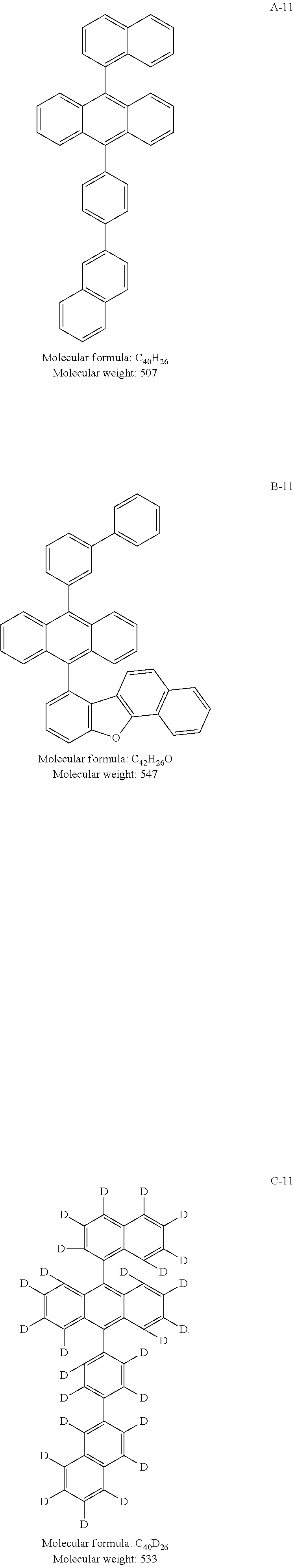

### Composition Example 12

This example provided a blue luminescent host composition. The blue luminescent host composition was composed of Compounds A-12, B-12, and C-12. The mass proportion of each of the compounds is as shown in Table 1:

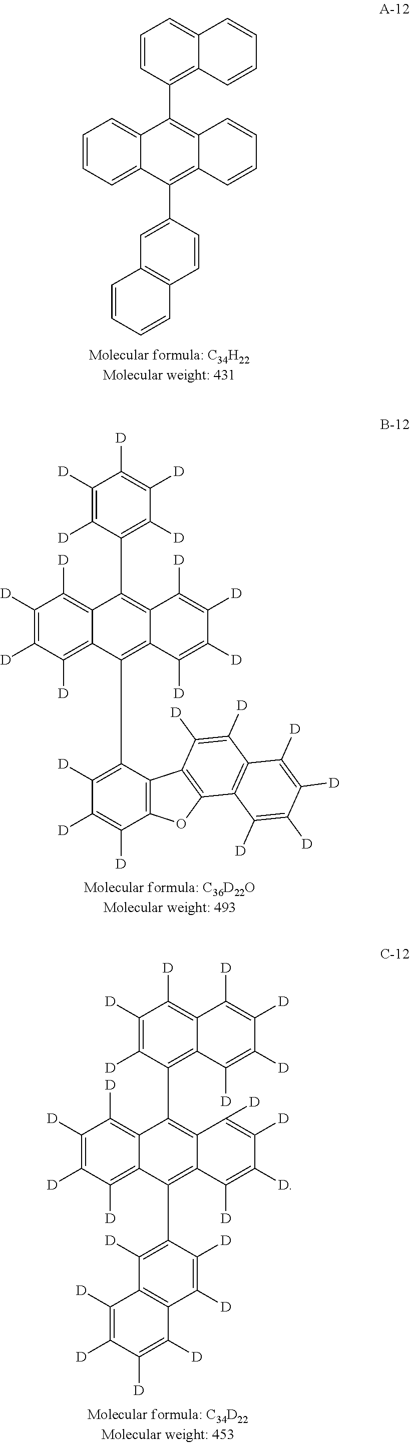

### Composition Example 13

This example provided a blue luminescent host composition. The blue luminescent host composition was composed of Compounds A-13, B-13, and C-13. The mass proportion of each of the compounds is as shown in Table 1:

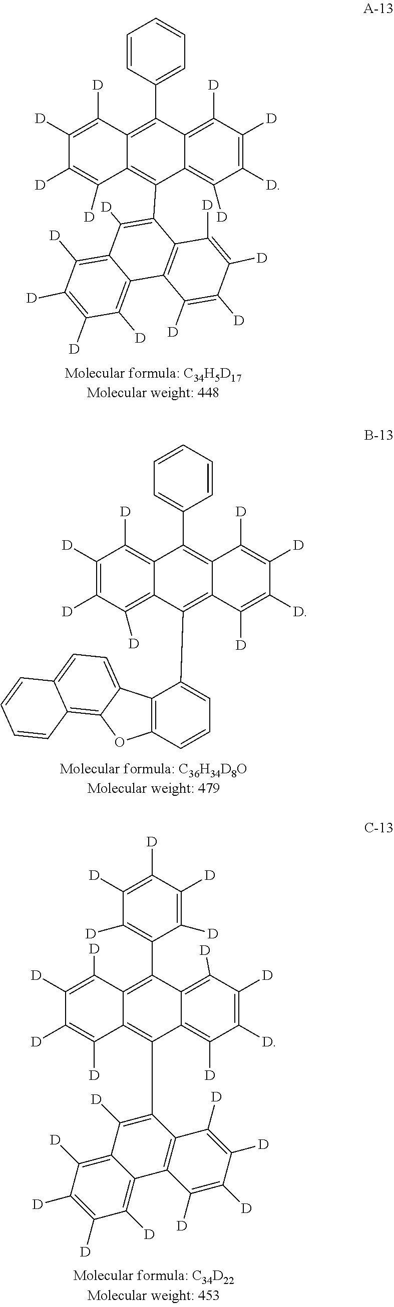

### Composition Example 14

This example provided a blue luminescent host composition. The blue luminescent host composition was composed of Compounds A-14, B-14, and C-14. The mass proportion of each of the compounds is as shown in Table 1:

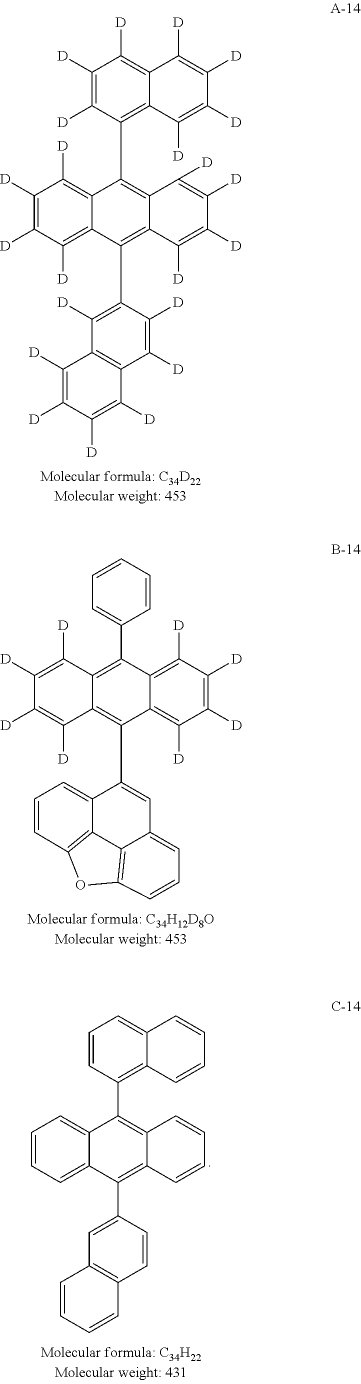

### Composition Example 15

This example provided a blue luminescent host composition. The blue luminescent host composition was composed of Compounds A-15, B-15, and C-15.

The mass proportion of each of the compounds is as shown in Table 1:

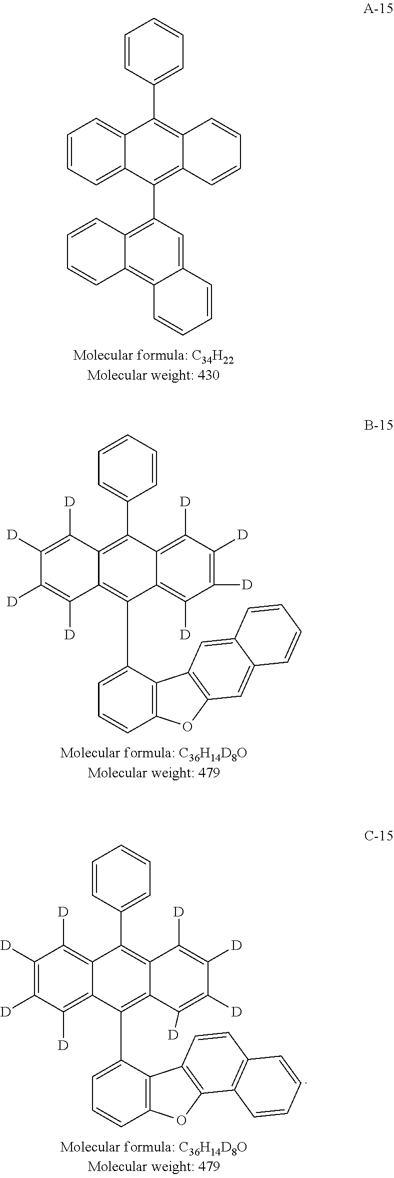

### Composition Example 16

This example provided a blue luminescent host composition. The blue luminescent host composition was composed of Compounds A-16, B-16, and C-16. The mass proportion of each of the compounds is as shown in Table 1:

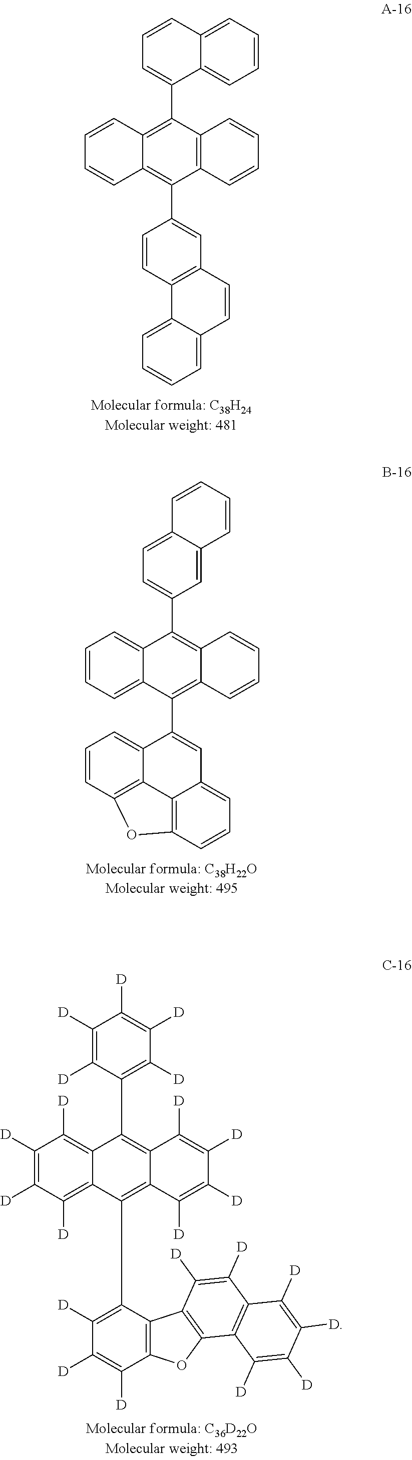

### Composition Example 17

This example provided a blue luminescent host composition. The blue luminescent host composition was composed of Compounds A-17, B-17, and C-17. The mass proportion of each of the compounds is as shown in Table 1:

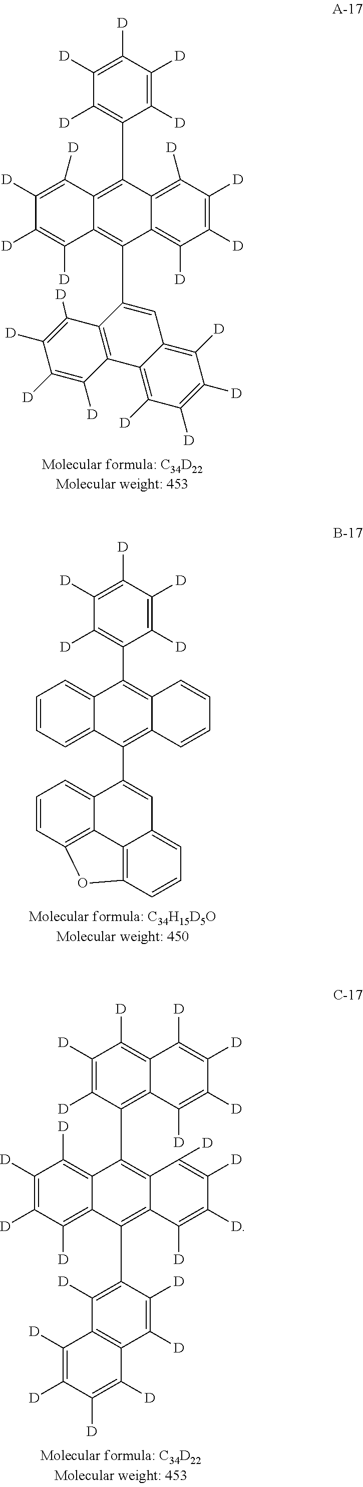

### Composition Example 18

This example provided a blue luminescent host composition. The blue luminescent host composition was composed of Compounds A-18, B-18, and C-18. The mass proportion of each of the compounds is as shown in Table 1:

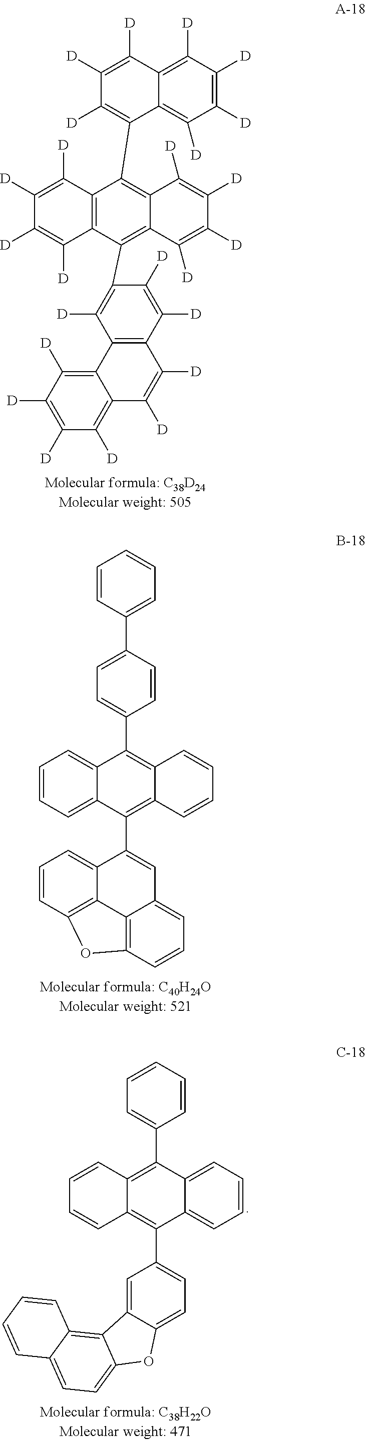 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; c1ccc(-c2ccc(-c3c4ccccc4c(-c4cc5cccc6oc7cccc4c7c56)c4ccccc34)cc2)cc1 ; c1ccc(-c2c3ccccc3c(-c3ccc4oc5ccc6ccccc6c5c4c3)c3ccccc23)cc1]

### Composition Example 19

This example provided a blue luminescent host composition. The blue luminescent host composition was composed of Compounds A-19, B-19, and C-19. The mass proportion of each of the compounds is as shown in Table 1:

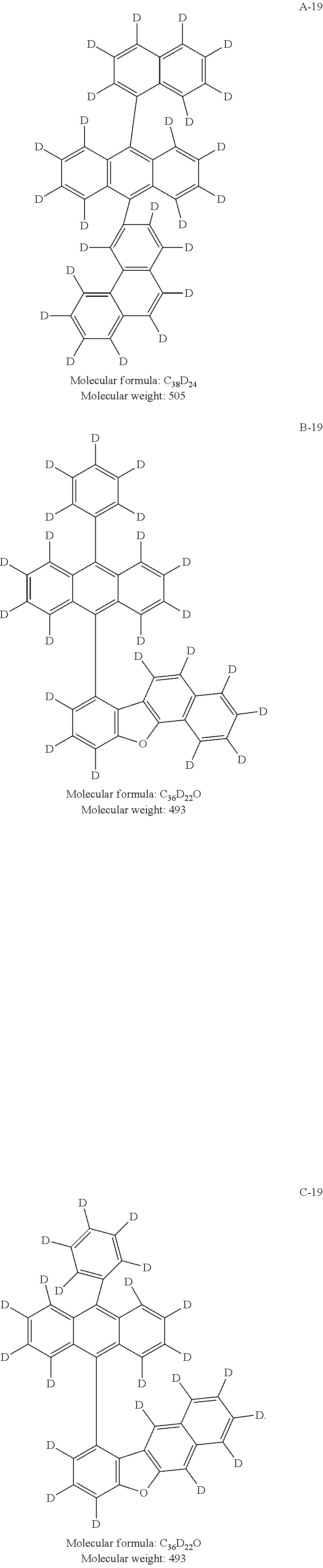

### Composition Example 20

This example provided a blue luminescent host composition. The blue luminescent host composition was composed of Compounds A-20, B-20, and C-20. The mass proportion of each of the compounds is as shown in Table 1:

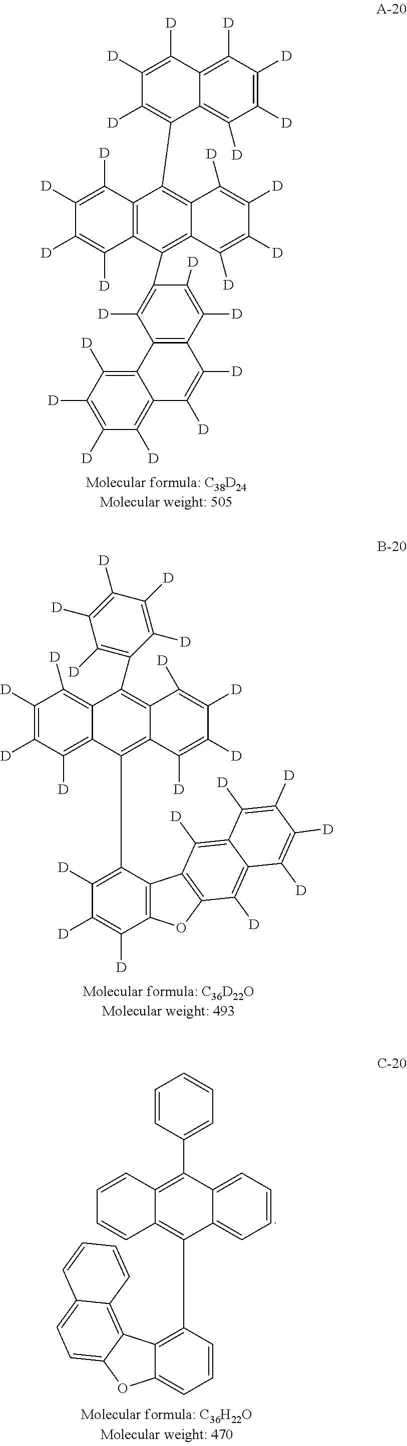 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; c1ccc(-c2c3ccccc3c(-c3cccc4oc5ccc6ccccc6c5c34)c3ccccc23)cc1]

### Composition Example 21

This example provided a blue luminescent host composition. The blue luminescent host composition was composed of Compounds A-21, B-21, and C-21. The mass proportion of each of the compounds is as shown in Table 1:

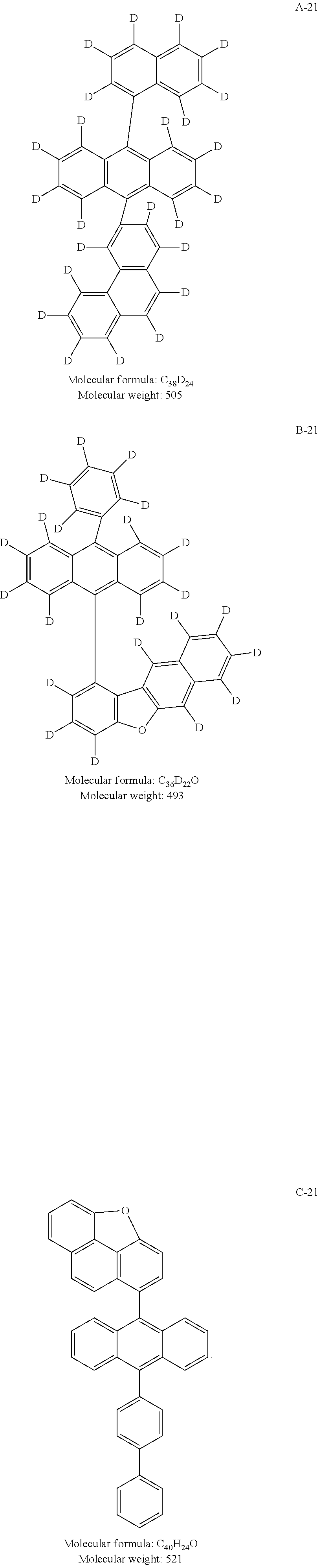 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; c1ccc(-c2ccc(-c3c4ccccc4c(-c4ccc5oc6cccc7ccc4c5c76)c4ccccc34)cc2)cc1]

### Composition Example 22

This example provided a blue luminescent host composition. The blue luminescent host composition was composed of Compounds A-22, B-22, and C-22. The mass proportion of each of the compounds is as shown in Table 1:

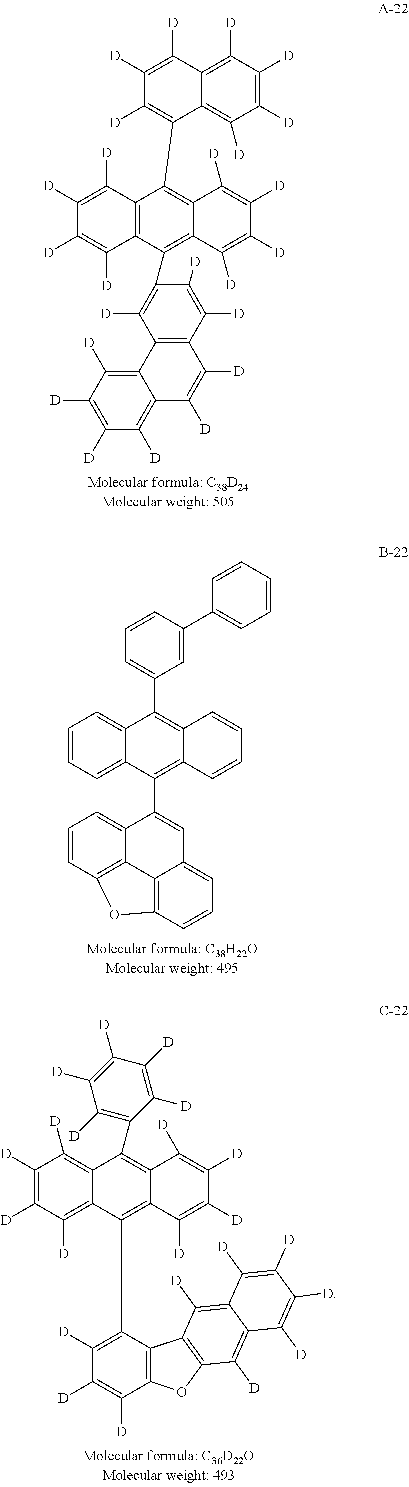

### Composition Example 23

This example provided a blue luminescent host composition. The blue luminescent host composition was composed of Compounds A-23, B-23, and C-23. The mass proportion of each of the compounds is as shown in Table 1:

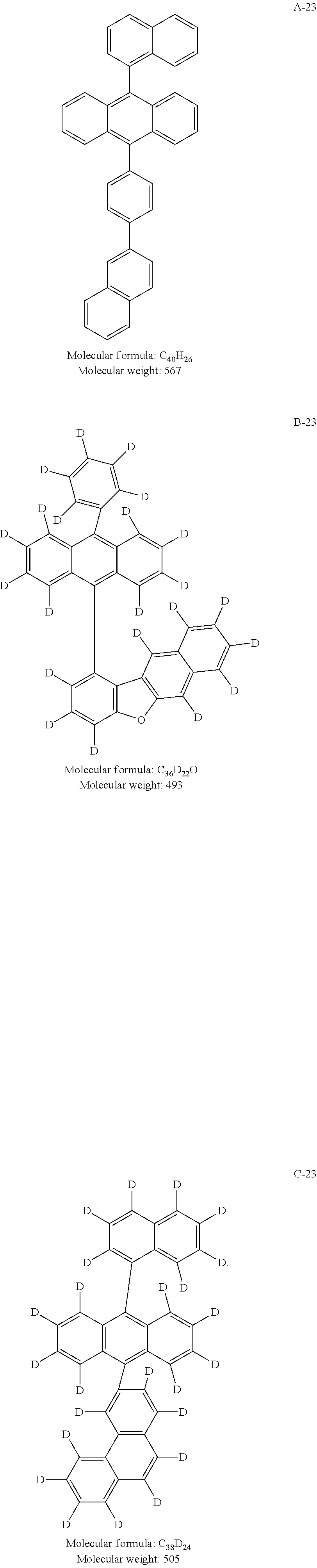

### Composition Example 24

This example provided a blue luminescent host composition. The blue luminescent host composition was composed of Compounds A-24, B-24, and C-24. The mass proportion of each of the compounds is as shown in Table 1:

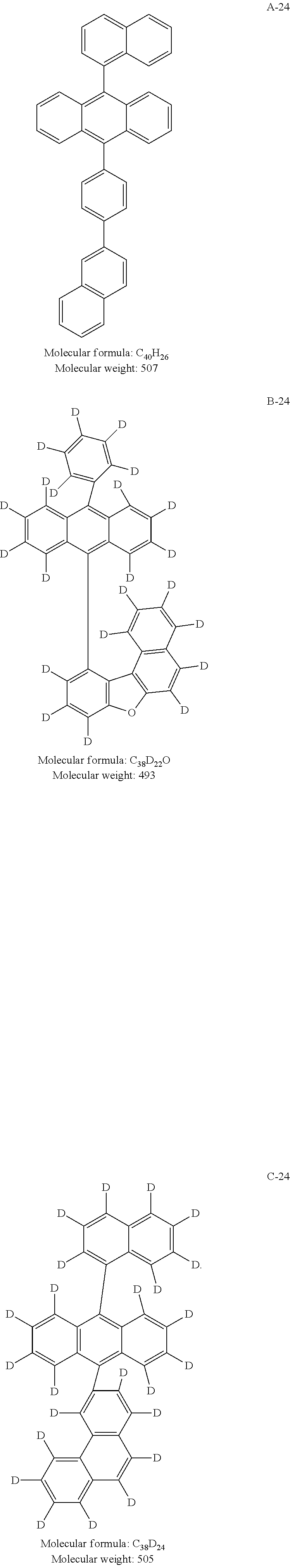

### Composition Example 25

This example provided a blue luminescent host composition. The blue luminescent host composition was composed of Compounds A-25, B-25, and C-25. The mass proportion of each of the compounds is as shown in Table 1:

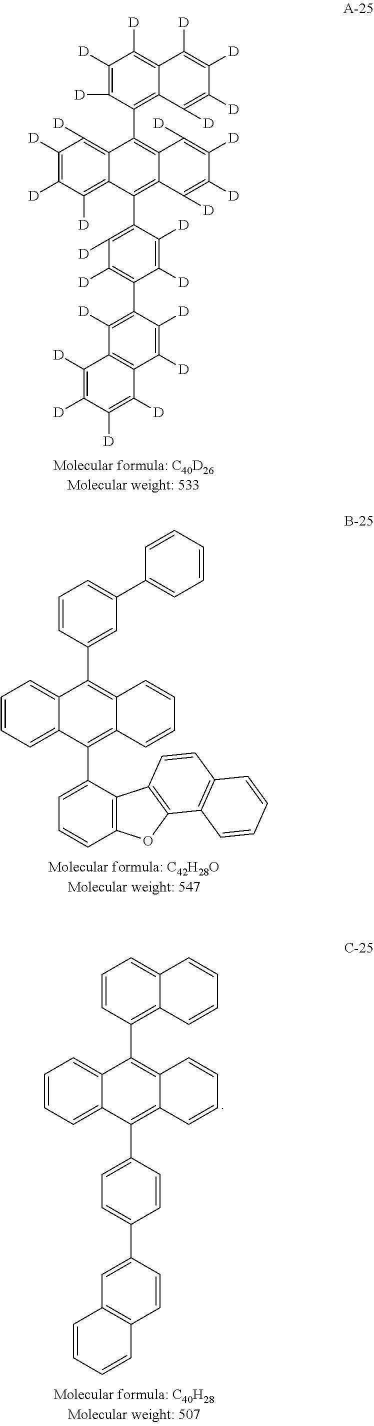

### Composition Example 26

This example provided a blue luminescent host composition. The blue luminescent host composition was composed of Compounds A-26, B-26, and C-26. The mass proportion of each of the compounds is as shown in Table 1:

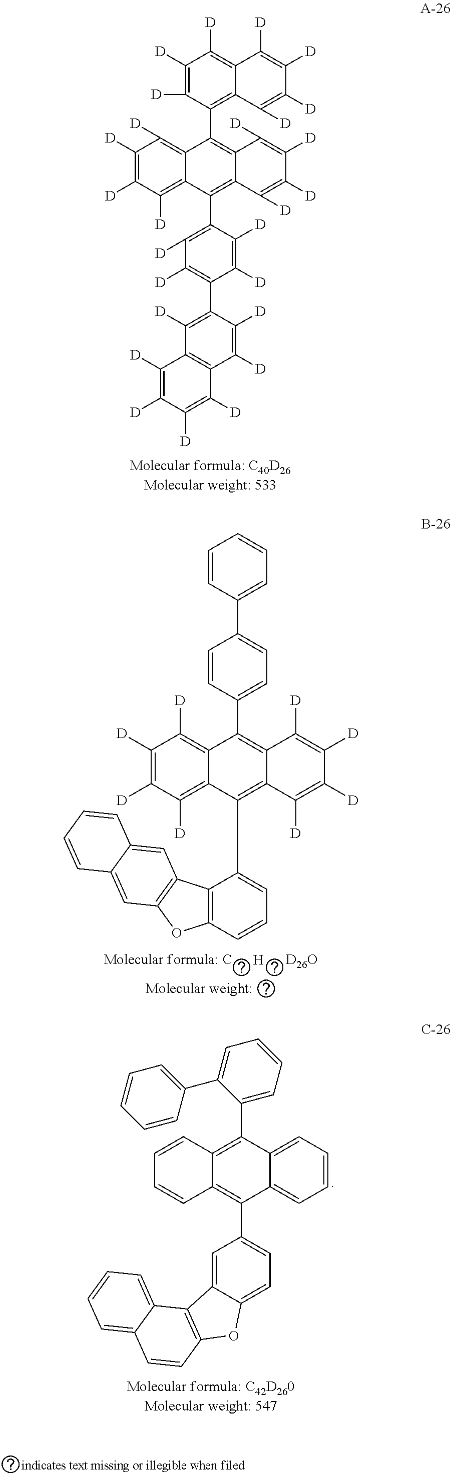

### Composition Example 27

This example provided a blue luminescent host composition. The blue luminescent host composition was composed of Compounds A-27, B-27, and C-27. The mass proportion of each of the compounds is as shown in Table 1:

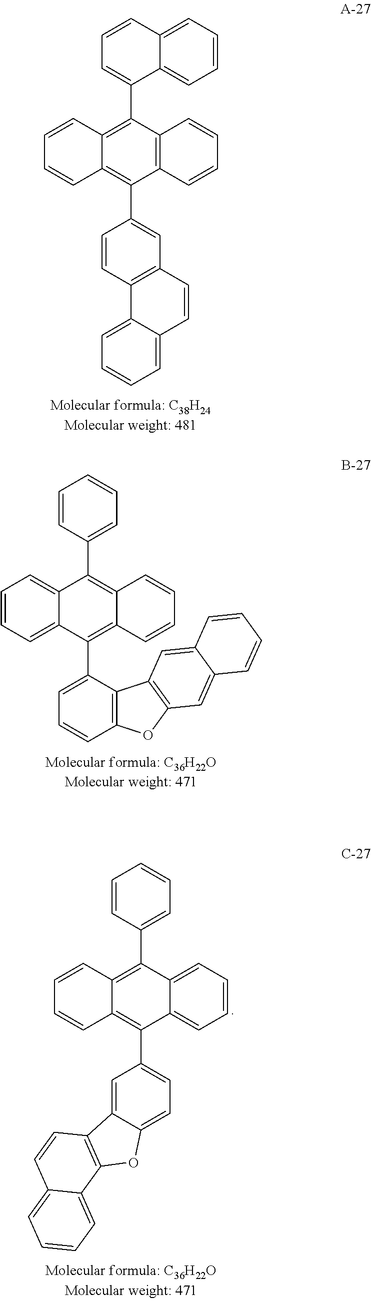

### Composition Example 28

This example provided a blue luminescent host composition. The blue luminescent host composition was composed of Compounds A-28, B-28, and C-28. The mass proportion of each of the compounds is as shown in Table 1:

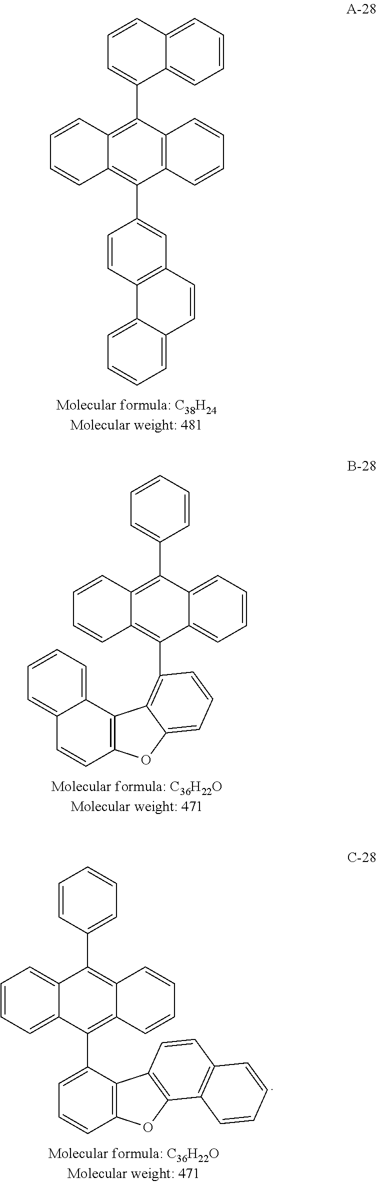

TABLE 1

| | | | | First | Second | Third |
|---|---|---|---|---|---|---|
| | | | | host | host | host |
| | | | | com- | com- | com- |
| | | | | pound | pound | pound |
| | First | Second | Third | Mass | Mass | Mass |
| | host | host | host | pro- | pro- | pro- |
| Composition | com- | com- | com- | portion | portion | portion |
| Example | pound | pound | pound | (%) | (%) | (%) |
| Example 1 | A-1 | B-1 | C-1 | 20 | 50 | 30 |
| Example 2 | A-2 | B-2 | C-2 | 30 | 30 | 40 |
| Example 3 | A-3 | B-3 | C-3 | 60 | 10 | 30 |
| Example 4 | A-4 | B-4 | C-4 | 40 | 40 | 20 |
| Example 5 | A-5 | B-5 | C-5 | 20 | 70 | 10 |
| Example 6 | A-6 | B-6 | C-6 | 60 | 30 | 10 |
| Example 7 | A-7 | B-7 | C-7 | 10 | 30 | 60 |
| Example 8 | A-8 | B-8 | C-8 | 20 | 70 | 10 |
| Example 9 | A-9 | B-9 | C-9 | 10 | 70 | 20 |
| Example 10 | A-10 | B-10 | C-10 | 50 | 40 | 10 |
| Example 11 | A-11 | B-11 | C-11 | 10 | 50 | 40 |
| Example 12 | A-12 | B-12 | C-12 | 30 | 40 | 30 |
| Example 13 | A-13 | B-13 | C-13 | 35 | 30 | 35 |
| Example 14 | A-14 | B-14 | C-14 | 30 | 30 | 40 |
| Example 15 | A-15 | B-15 | C-15 | 70 | 15 | 15 |
| Example 16 | A-16 | B-16 | C-16 | 70 | 10 | 20 |
| Example 17 | A-17 | B-17 | C-17 | 30 | 35 | 35 |
| Example 18 | A-18 | B-18 | C-18 | 30 | 60 | 10 |
| Example 19 | A-19 | B-19 | C-19 | 30 | 10 | 60 |
| Example 20 | A-20 | B-20 | C-20 | 40 | 30 | 30 |
| Example 21 | A-21 | B-21 | C-21 | 50 | 20 | 30 |
| Example 22 | A-22 | B-22 | C-22 | 30 | 35 | 35 |
| Example 23 | A-23 | B-23 | C-23 | 70 | 10 | 20 |
| Example 24 | A-24 | B-24 | C-24 | 40 | 30 | 30 |
| Example 25 | A-25 | B-25 | C-25 | 35 | 30 | 35 |
| Example 26 | A-26 | B-26 | C-26 | 50 | 20 | 30 |
| Example 27 | A-27 | B-27 | C-27 | 30 | 10 | 60 |
| Example 28 | A-28 | B-28 | C-28 | 40 | 15 | 45 |

Note:
The mass proportion of each compound in Table 1 refers to the mass proportion of each host compound in the corresponding blue luminescent host composition.

### Manufacturing and Characterization of OLEDs

### DEVICE EXAMPLES

The organic electroluminescent device provided by the present invention comprised an anode, a hole transport region, a luminescent layer, an electron transport region, and a cathode, which were sequentially arranged on a substrate plate.

Furthermore, the hole transport region comprised a hole injection layer, a hole transport layer, and a luminescent auxiliary layer; and the electron transport region comprised an electron transport layer and an electron injection layer.

Furthermore, the luminescent layer was composed of a host material and a guest material, wherein the host material of the luminescent layer can be composed of one molecular material or a plurality of molecular materials.

The composition of the present invention can be used for the luminescent layer of the above organic electroluminescent device.

The anode in the example was an anode material commonly used in the art, such as ITO, Ag or a multilayer structure thereof. The hole injection layer was made of a hole injection material commonly used in the art and was doped with F4TCNQ, HATCN, NDP-9, etc. The hole transport layer was made of a hole transport material commonly used in the art. For the luminescent layer, the host and guest material composition provide by the present invention was used. The electron transport layer was made of an electron transport material commonly used in the art. For the electron injection layer, electron injection materials commonly used in the art, such as LiQ, LiF, and Yb, were used. For the cathode, commonly used materials in the art, such as the metals Al and Ag or metal mixtures (Ag-doped Mg, Ag-doped Ca, etc.), were used.

The electrode preparation method and the deposition method for each functional layer in this example were both conventional methods in the art, such as vacuum thermal evaporation or ink-jet printing. No more detailed repetition will be given here. Only some process details and test methods in the preparation process are supplemented as follows:

### Device Example 1

The substrates used in the present invention were all subjected to the following operations: patterning an ITO substrate such that the luminescent area thereof had a size of 3 mm×3 mm, then carrying out an ultrasonic treatment with water/isopropanol, respectively, followed by UV/ozone irradiation and then drying at 100° C., then mounting the ITO substrate on a substrate support in a vacuum deposition device, and adjusting the pressure such that the vacuum level became 1×10⁻⁷ torr. Subsequently, the following operations were carried out. Firstly, on an ITO layer (anode) formed on the substrate, Compound HTO1 and Compound PDO1 (at a mass ratio of Compound HTO1 to Compound PDO1 of 97:3) were deposited in vacuo to a thickness of 10 nm to form a hole injection layer; secondly, on the above hole injection layer, Compound HTO1 was deposited in vacuo to a thickness of 100 nm to form a hole transport layer; thirdly, on the above hole transport layer, Compound BP01 was deposited in vacuo to a thickness of 5 nm to form a luminescent auxiliary layer; fourthly, on the above luminescent auxiliary layer, a mixture of Composition Example 1 provided by the present invention and Compound BD01 was deposited in vacuo to a thickness of 20 nm to form a luminescent layer, wherein Composition Example 1 was used as a host material and Compound BD01 as a guest material, and the mass ratio of Composition Example 1 to the guest material was 98:2; next, on the above luminescent layer, Compound HB01 was deposited in vacuo to a thickness of 5 nm to form a hole barrier layer; then, on the above hole barrier layer, Compound ET01 and Compound LiQ (at a mass ratio of Compound ET01 to Compound LiQ of 1:1) was deposited in vacuo to a thickness of 30 nm to form an electron transport layer; then, on the above electron transport layer, Yb was deposited in vacuo to a thickness of 1 nm to form an electron injection layer; then, on the above electron injection layer, Mg and Ag (a mass ratio of Mg to Ag of 1:9) were deposited to a thickness of 15 nm to form a cathode; then, on the above cathode, Compound CP01 was deposited to a thickness of 50 nm to form a cover layer; and finally, the evaporated substrate was packaged and the cleaned cover plate was subjected to a coating process using a UV adhesive by a coating apparatus. The coated cover plate was then moved to a pressure bonding work stage. The evaporated substrate was placed on top of the cover plate. Finally, the substrate and the cover plate were laminated under the action of a lamination apparatus while the UV adhesive was simultaneously photocured, thereby manufacturing a top-emitting organic electroluminescent device. The structure of the device is shown in FIG. 1.

The molecular structural formulas of the materials in the remaining layers other than the host and guest materials in the luminescent layer were as follows:

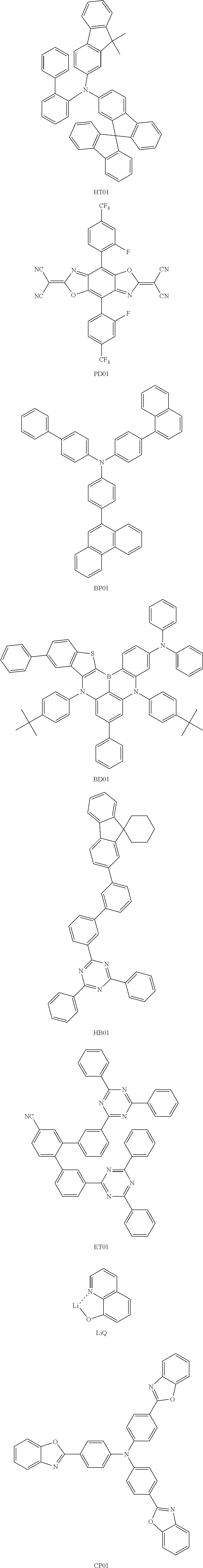

### Device Examples 2-5

By means of the above method, the Composition Examples 2 to 5 provided by the present invention, which were used as host materials, were respectively manufactured into organic electroluminescent devices, thereby obtaining Device Examples 2-5.

### Comparative Device Examples 1-3

By means of the above method, the host compositions in Table 2 were manufactured into organic electroluminescent devices, thereby obtaining Comparative Device Examples 1-3. The specific component combinations are shown in Table 2.

The OLED devices described above were tested by means of a standard method. To this end, the driving voltage and luminous efficiency of the organic electroluminescent devices were determined at a current density of J=10 mA/cm². LT97 means that when the prepared blue-light device operates at J=20 mA/cm², the luminous brightness decreases to 97% of its initial value L₀ after the time LT97.

The test instruments and methods for testing the performance of the OLED devices of the above examples and comparative examples were as follows:
the luminous efficiency C.E (cd/A) and color coordinates (CIEy) were tested by spectrum scanner PhotoResearch PR-635;
the current density and turn-on voltage were tested by digital SourceMeter Keithley 2400;
the luminous efficiency of the blue-light device was greatly influenced by chromaticity, and for blue-light devices, the BI value was generally used in the industry as a basis for the efficiency of blue-light devices, wherein BI (Blue index) was obtained by dividing the luminous efficiency C.E (cd/A) by the color coordinates (CIEy); and
the lifetime test was carried out by using a silicon photoelectric OLED device lifetime test system.

The performance test results of the above devices were listed in Table 2.

TABLE 2
Performance test results of blue-light devices

| | | Mass | | Mass | | Mass | | | |
|---|---|---|---|---|---|---|---|---|---|
| | First | pro- | Second | pro- | Third | pro- | | BI | |
| | host | por- | host | por- | host | por- | | (cd/ | |
| | com- | tion | com- | tion | com- | tion | Volt | A/ | LT97 |
| Device | pound | (%) | pound | (%) | pound | (%) | (V) | CIEy) | (h) |
| Device | A-1 | 20 | B-1 | 50 | C-1 | 30 | 3.31 | 261 | 205 |
| Example | | | | | | | | | |
| 1 | | | | | | | | | |
| Device | A-2 | 30 | B-2 | 30 | C-2 | 40 | 3.35 | 258 | 216 |
| Example | | | | | | | | | |
| 2 | | | | | | | | | |
| Device | A-3 | 60 | B-3 | 10 | C-3 | 30 | 3.33 | 263 | 234 |
| Example | | | | | | | | | |
| 3 | | | | | | | | | |
| Device | A-4 | 40 | B-4 | 40 | C-4 | 20 | 3.32 | 257 | 216 |
| Example | | | | | | | | | |
| 4 | | | | | | | | | |
| Device | A-5 | 20 | B-5 | 70 | C-5 | 10 | 3.34 | 263 | 209 |
| Example | | | | | | | | | |
| 5 | | | | | | | | | |
| Com- | A-1 | 50 | B-1 | 50 | / | / | 3.50 | 255 | 164 |
| parative | | | | | | | | | |
| Device | | | | | | | | | |
| Example | | | | | | | | | |
| 1 | | | | | | | | | |
| Com- | A-1 | 50 | / | / | C-1 | 50 | 3.85 | 259 | 204 |
| parative | | | | | | | | | |
| Device | | | | | | | | | |
| Example | | | | | | | | | |
| 2 | | | | | | | | | |
| Com- | A-1 | 100 | / | / | / | / | 3.85 | 260 | 184 |
| parative | | | | | | | | | |
| Device | | | | | | | | | |
| Example | | | | | | | | | |
| 3 | | | | | | | | | |

Note:
The mass proportion in Table 2 refers to the mass proportion of each host compound in the corresponding host composition.

As can be seen from the data in the above table, the single-host material of Comparative Device Example 3 exhibited a higher device driving voltage and a shorter lifetime; compared with the single host device, although the dual-host device of Comparative Device Example 1 reduced the driving voltage of the device, the efficiency and lifetime of the device were reduced, and although the lifetime of the dual-host device of Comparative Device Example 2 was slightly prolonged, neither of the driving voltage and efficiency was improved; whereas, Device Examples 1 to 5 provided by the present invention can achieve not only a significant decrease in driving voltage but also a significantly prolonged device lifetime.

### Performance Test for Composition Examples

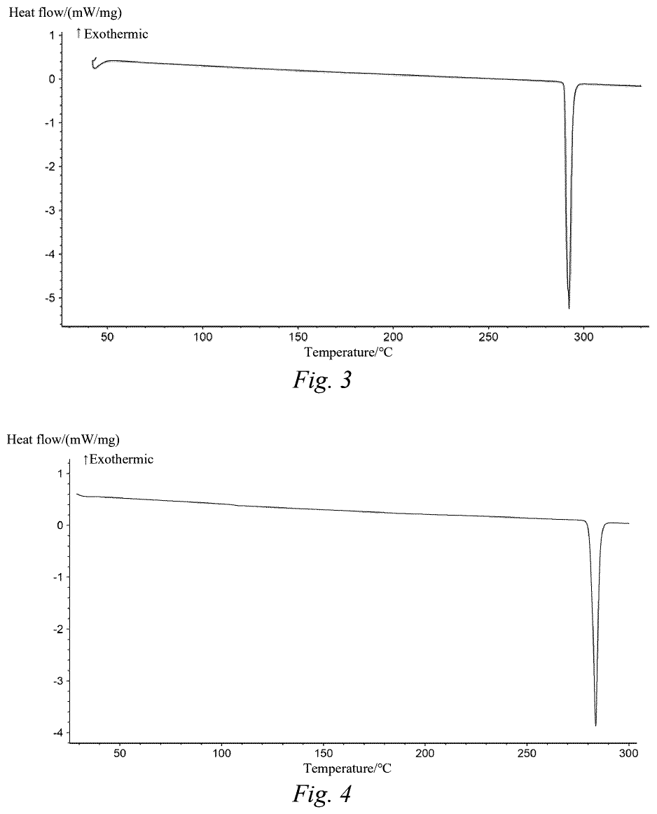

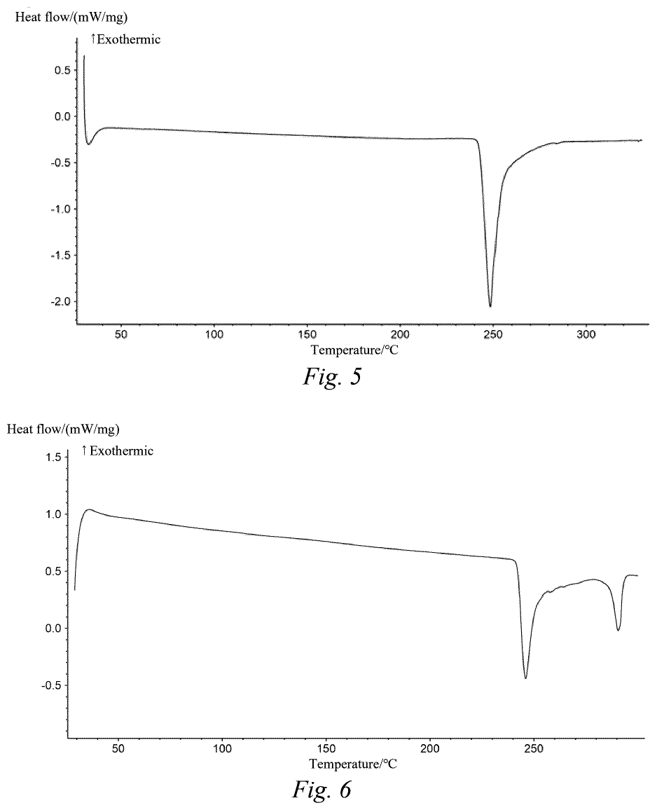

In order to demonstrate that the blue luminescent host composition provided by the present invention has good melting point advantages during the evaporation process, the melting points of the composition examples provided by the present invention were measured. The DSC curves of some host compounds and compositions are shown in FIGS. 2 to 5, and the measurement results are as shown in Table 3.

TABLE 3

| | | Melting | | Melting | | | |
|---|---|---|---|---|---|---|---|
| | | point of | | point of | | Melting | |
| | | in- | | in- | | point of | Melting |
| | First | dividual | Second | dividual | Third | in- | point of |
| | host | com- | host | com- | host | dividual | com- |
| | com- | ponent / | com- | ponent / | com- | compon | position / |
| | pound | ° C. | pound | ° C. | pound | ent / ° C. | ° C. |
| Com- | A-1 | 282 | B-1 | 290 | C-1 | 282 | 243 |
| position | | | | | | | |
| Example | | | | | | | |
| 1 | | | | | | | |
| Com- | A-2 | 275 | B-2 | 248 | C-2 | 290 | 268 |
| position | | | | | | | |
| Example | | | | | | | |
| 2 | | | | | | | |
| Com- | A-3 | 282 | B-3 | 250 | C-3 | 250 | 228 |
| position | | | | | | | |
| Example | | | | | | | |
| 3 | | | | | | | |
| Com- | A-4 | 282 | B-4 | 290 | C-4 | 275 | 252 |
| position | | | | | | | |
| Example | | | | | | | |
| 4 | | | | | | | |
| Com- | A-5 | 282 | B-5 | 248 | C-5 | 239 | 209 |
| position | | | | | | | |
| Example | | | | | | | |
| 5 | | | | | | | |
| Com- | A-1 | 282 | B-1 | 290 | / | / | No fixed |
| parative | | | | | | | single |
| Com- | | | | | | | melting |
| position | | | | | | | point |
| Example | | | | | | | |
| 1 | | | | | | | |
| Com- | A-1 | 282 | / | / | C-1 | 282 | No fixed |
| parative | | | | | | | single |
| Com- | | | | | | | melting |
| position | | | | | | | point |
| Example | | | | | | | |
| 2 | | | | | | | |
| Com- | A-1 | 282 | / | / | / | / | 282 |
| parative | | | | | | | |
| Com- | | | | | | | |
| position | | | | | | | |
| Example | | | | | | | |
| 3 | | | | | | | |

Note:
NETZSCH DSC 3500 was used as a melting point testing instrument, and
the mass proportion of each of the host compounds in Examples 1 to 5 in the
corresponding blue luminescent host composition is as shown in Table 1.

As can be read successively from FIGS. 2 to 5, the melting point of Compound A-1 is 282° C., the melting point of Compound B-1 is 290° C., and the melting point of Compound C-1 is 282° C.; and the melting point of the composition of Compounds A-1, B-1, and C-1 mixed at the ratio in Table 1 is 243° C. It can be seen therefrom that the melting point of the blue luminescent host composition provided by the present invention is lower than that of each individual component, and a lower melting point is advantageous for the composition provided by the present invention to form an organic thin film by evaporation according to a constant component ratio.

FIG. 6 is the composition used in Comparative Device Example 1. As can be seen from the figure, the composition of the comparative example did not form a single phase transition peak and had no fixed single melting point. The absence of a fixed single melting point may cause the composition to shown poor compositional constancy during the evaporation process.

### Test of Compositional Constancy in Host Composition Thin Film

In order to further illustrate the advantages of the blue luminescent host composition provided by the present invention, a composition example was formed into a host composition thin film, and the compositional constancy in the thin film was tested. The host composition was obtained by pre-mixing according to the pre-mixing ratio in Tables 4-1 to 4-3 (denoting the mass proportion of each host compound within the corresponding host composition). The pre-mixed host composition was then subjected to a different evaporation rate to form a thin film having a thickness of 2000 Å. The above operation was continuously repeated three times (that is, the same composition having the same pre-mixing ratio was continuously evaporated three times to form thin films). The formed three thin films were subjected to high-performance liquid chromatography analysis method to measure the mass proportion of each compound in the thin film. The evaluation results are as follows:

TABLE 4-1

| | | | | At an evaporation rate of 0.5 | | |
|---|---|---|---|---|---|---|
| | | | | Å/s, mass proportion of each | | |
| Effect | Pre-mixing ratio / wt % | | | compound in thin film / % | | |
| Example | A-1 | B-1 | C-1 | A-1 | B-1 | C-1 |
| Effect | 20 | 50 | 30 | 19.51 | 50.44 | 30.05 |
| Example 1-1 | | | | | | |
| Effect | 20 | 50 | 30 | 19.42 | 50.42 | 30.16 |
| Example 1-2 | | | | | | |
| Effect | 20 | 50 | 30 | 19.19 | 50.37 | 30.44 |
| Example 1-3 | | | | | | |
| Effect | 30 | 30 | 40 | 29.48 | 29.32 | 41.2 |
| Example 2-1 | | | | | | |
| Effect | 30 | 30 | 40 | 29.45 | 29.28 | 41.27 |
| Example 2-2 | | | | | | |
| Effect | 30 | 30 | 40 | 29.35 | 29.43 | 41.22 |
| Example 2-3 | | | | | | |
| Effect | 60 | 10 | 30 | 60.45 | 10.48 | 29.07 |
| Example 3-1 | | | | | | |
| Effect | 60 | 10 | 30 | 60.57 | 10.21 | 29.22 |
| Example 3-2 | | | | | | |
| Effect | 60 | 10 | 30 | 60.41 | 10.32 | 29.27 |
| Example 3-3 | | | | | | |
| Comparative | 50 | 50 | / | 86.54 | 13.46 | / |
| Effect | | | | | | |
| Example 1-1 | | | | | | |
| Comparative | 50 | 50 | / | 65.16 | 34.84 | / |
| Effect | | | | | | |
| Example 1-2 | | | | | | |
| Comparative | 50 | 50 | / | 71.63 | 28.37 | / |
| Effect | | | | | | |
| Example 1-3 | | | | | | |

TABLE 4-2

| | | | | At an evaporation rate of 1 | | |
|---|---|---|---|---|---|---|
| | | | | Å/s, mass proportion of each | | |
| Effect | Pre-mixing ratio / wt % | | | compound in thin film / % | | |
| Example | A-1 | B-1 | C-1 | A-1 | B-1 | C-1 |
| Effect | 20 | 50 | 30 | 50.38 | 19.75 | 29.87 |
| Example 1-4 | | | | | | |
| Effect | 20 | 50 | 30 | 50.28 | 19.81 | 29.91 |
| Example 1-5 | | | | | | |
| Effect | 20 | 50 | 30 | 50.34 | 19.69 | 29.97 |
| Example 1-6 | | | | | | |
| Effect | 30 | 30 | 40 | 29.65 | 29.58 | 40.77 |
| Example 2-4 | | | | | | |
| Effect | 30 | 30 | 40 | 29.76 | 29.76 | 40.48 |
| Example 2-5 | | | | | | |
| Effect | 30 | 30 | 40 | 29.68 | 29.67 | 40.65 |
| Example 2-6 | | | | | | |
| Effect | 60 | 10 | 30 | 60.34 | 10.29 | 29.37 |
| Example 3-4 | | | | | | |
| Effect | 60 | 10 | 30 | 60.38 | 10.19 | 29.43 |
| Example 3-5 | | | | | | |
| Effect | 60 | 10 | 30 | 60.29 | 10.25 | 29.46 |
| Example 3-6 | | | | | | |
| Comparative | 50 | 50 | / | 58.93 | 41.07 | / |
| Effect | | | | | | |
| Example 1-4 | | | | | | |
| Comparative | 50 | 50 | / | 76.51 | 23.49 | / |
| Effect | | | | | | |
| Example 1-5 | | | | | | |
| Comparative | 50 | 50 | / | 69.54 | 30.46 | / |
| Effect | | | | | | |
| Example 1-6 | | | | | | |

TABLE 4-3

| | | | | At an evaporation rate of 3 | | |
|---|---|---|---|---|---|---|
| | | | | Å/s, mass proportion of each | | |
| Effect | Pre-mixing ratio / wt % | | | compound in thin film / % | | |
| Example | A-1 | B-1 | C-1 | A-1 | B-1 | C-1 |
| Effect | 20 | 50 | 30 | 50.08 | 19.94 | 29.98 |
| Example 1-7 | | | | | | |
| Effect | 20 | 50 | 30 | 50.01 | 19.96 | 30.03 |
| Example 1-8 | | | | | | |
| Effect | 20 | 50 | 30 | 50.03 | 19.98 | 29.99 |
| Example 1-9 | | | | | | |
| Effect | 30 | 30 | 40 | 29.94 | 29.92 | 40.14 |
| Example 2-7 | | | | | | |
| Effect | 30 | 30 | 40 | 29.89 | 29.84 | 40.27 |
| Example 2-8 | | | | | | |
| Effect | 30 | 30 | 40 | 29.96 | 29.94 | 40.1 |
| Example 2-9 | | | | | | |
| Effect | 60 | 10 | 30 | 60.08 | 10.08 | 29.84 |
| Example 3-7 | | | | | | |
| Effect | 60 | 10 | 30 | 60.09 | 10.11 | 29.8 |
| Example 3-8 | | | | | | |
| Effect | 60 | 10 | 30 | 60.07 | 10.04 | 29.89 |
| Example 3-9 | | | | | | |
| Comparative | 50 | 50 | / | 62.14 | 37.86 | / |
| Effect | | | | | | |
| Example 1-7 | | | | | | |
| Comparative | 50 | 50 | / | 64.75 | 35.25 | / |
| Effect | | | | | | |
| Example 1-8 | | | | | | |
| Comparative | 50 | 50 | / | 54.52 | 45.48 | / |
| Effect | | | | | | |
| Example 1-9 | | | | | | |

As can be seen from the above tables, separately at the evaporation rates of 0.5 Å/s, 1 Å/s, and 3 Å/s, compared with Comparative Effect Examples 1-1 to 1-9 composed of the two-component mixed host materials, each compound in the Effect Examples 1-1 to 2-9 composed of the blue luminescent host compositions provided by the present invention showed a relatively constant mass ratio in the final evaporated thin film under continuous working conditions and had a relatively small difference from the initial pre-mixing ratio.

At the low evaporation rate of 0.5 Å/s, the mass proportion of each compound in the final evaporated thin film in Comparative Effect Examples 1-1 to 1-3 under continuous working conditions showed a relatively significant difference from the initial pre-mixing ratio. The proportions of the evaporated components were not in line with the pre-mixing ratio, resulting in adverse effects on device performance.

With the increase of the evaporation rate, although the mass proportion of each compound of the comparative effect example composed of the two-component mixed host material in the final evaporated thin film was closer to the initial pre-mixing ratio, the mass proportion of each compound of the two-component mixed host material in the final evaporated thin film showed a relatively significant fluctuation under continuous working conditions. As can be seen at the evaporation rate of 3 Å/s, the two-component mixed host materials of Comparative Effect Examples 1-7 to 1-9 showed significantly increased fluctuations; whereas, the blue luminescent host compositions of Effect Examples 1-7 to 2-9 provided by the present invention all maintained better process stability and compositional ratio constancy at different evaporation rates, indicating that using the blue luminescent host compositions provided by the present invention can maintain better compositional ratio constancy both in different production processes and under continuous operating working conditions. However, for the comparative effect examples composed of the two-component mixed host materials, the mass proportion of each compound in the final evaporated thin film showed a relatively significant difference from the initial pre-mixing ratio at different evaporation rates and under continuous operating working conditions. This probably results in the components of the evaporated organic film layer not in line with the pre-mixing ratio in terms of composition, leading to the inability to stably exert the pre-mixing advantages.

### Device Performance Constancy Test

According to the above process, the composition used in Comparative Effect Example 1-1 was continuously prepared into Comparative Device Examples 1-1 to 1-3 under the same working conditions, and the blue luminescent host composition in Effect Example 1-1 of the present invention was continuously prepared into Device Examples 1-1 to 1-3 under the same working conditions. According to Table 2, the device performance was tested under the same testing conditions, and the results are shown in Table 5.

TABLE 5

| | First | Mass | Second | Mass | Third | Mass | | | |
|---|---|---|---|---|---|---|---|---|---|
| | host | pro- | host | pro- | host | pro- | | BI | |
| | com- | portion | com- | portion | com | portion | Volt | (cd /A/ | LT97 |
| Device | pound | (%) | pound | (%) | pound | (%) | (V) | CIEy) | (h) |
| Device | A-1 | 20 | B-1 | 50 | C-1 | 30 | 3.29 | 259 | 203 |
| Examples | | | | | | | | | |
| 1-1 | | | | | | | | | |
| Device | A-1 | 20 | B-1 | 50 | C-1 | 30 | 3.31 | 261 | 205 |
| Examples | | | | | | | | | |
| 1-2 | | | | | | | | | |
| Device | A-1 | 20 | B-1 | 50 | C-1 | 30 | 3.33 | 260 | 210 |
| Examples | | | | | | | | | |
| 1-3 | | | | | | | | | |
| Comparative | A-1 | 50 | B-1 | 50 | / | / | 3.43 | 238 | 184 |
| Device | | | | | | | | | |
| Examples | | | | | | | | | |
| 1-1 | | | | | | | | | |
| Comparative | A-1 | 50 | B-1 | 50 | / | / | 3.50 | 255 | 164 |
| Device | | | | | | | | | |
| Examples | | | | | | | | | |
| 1-2 | | | | | | | | | |
| Comparative | A-1 | 50 | B-1 | 50 | / | / | 3.91 | 207 | 124 |
| Device | | | | | | | | | |
| Examples | | | | | | | | | |
| 1-3 | | | | | | | | | |

Note:
The mass proportion in Table 5 refers to the mass proportion of each host
compound in the corresponding host composition.

As can be seen from the above table, the voltage efficiencies and lifetimes of the Device Examples 1-1 to 1-3 provided by the present invention were relatively stable and all superior to the comparative device examples. As can also be seen from Table 5, Comparative Device Examples 1-1 to 1-3 showed significant fluctuation in device performance, possibly due to the fact that the compositions of Comparative Examples 1-1 to 1-3 had no fixed melting points, causing the composition to show poor compositional constancy during the evaporation process, and the mass proportion of each compound in the final evaporated thin film showed a relatively significant difference from the initial pre-mixing ratio, causing the device performance of the comparative device example to significantly fluctuate; whereas, the melting point of the blue luminescent host compositions provided by the present invention was lower than that of each individual component. A lower melting point is advantageous for the composition provided by the present invention to form an organic thin film by evaporation according to a constant component ratio. Therefore, the performance of the devices prepared using the device examples provided by the present invention under continuous working conditions is more stable, indicating that the present invention is more suitable for commercial mass production.

Apparently, the above examples of the present invention are only examples provided to clearly illustrate the present invention, rather than limitations on the embodiments of the present invention. For those of ordinary skill in the art, other variations or changes in various forms can also be made on the basis of the above description. It is impossible to enumerate all embodiments here. Any obvious variations or changes arising from the technical solutions of the present invention still fall within the scope of protection of the present invention.

1. A blue luminescent host composition, characterized by comprising at least a first host compound, a second host compound, and a third host compound, wherein the structure of the first host compound is as represented by formula I, the structure of the second host compound is as represented by formula II, and the structure of the third host compound is as represented by formula I or II; and the first host compound, the second host compound, and the third host compound are different from each other; 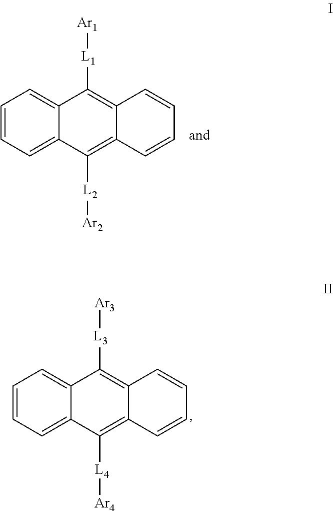
characterized in that Ar₁ and Ar₂ are each independently selected from any one of or a combination of any two of a deuterated or non-deuterated phenyl group, a deuterated or non-deuterated biphenyl group, a deuterated or non-deuterated naphthyl group, and a deuterated or non-deuterated phenanthryl group;
Ar₃ is selected from any one of or a combination of any two of a deuterated or non-deuterated phenyl group, a deuterated or non-deuterated biphenyl group, and a deuterated or non-deuterated naphthyl group;
Ar₄ is selected from any one of 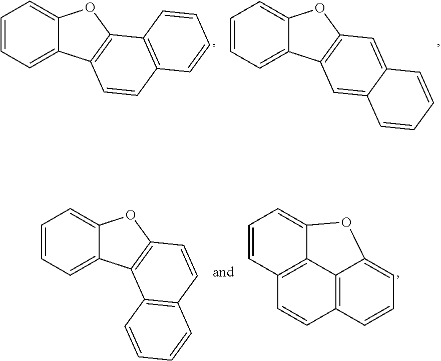
and any hydrogen in Ar₄ can be replaced by deuterium;
L₁, L₂, L₃, and L₄ are each independently selected from any one of a single bond, a deuterated or non-deuterated phenyl group, and a deuterated or non-deuterated biphenyl group;
when the third host compound is selected from structures as represented by formula I, the mass ratio of the first host compound to the second host compound to the third host compound in the blue luminescent host composition is 0.1-6:0.5-7:1; and
when the third host compound is selected from structures as represented by formula II, the mass ratio of the first host compound to the second host compound to the third host compound in the blue luminescent host composition is 0.5-7:0.1-6:1,
the mass proportion of any one of the host compounds in the blue luminescent host composition is between 10 wt % and 80 wt %;
characterized in that the difference in molecular weight between any two compounds of the first host compound, the second host compound, and the third host compound is within 100, and
characterized in that when the first host compound, the second host compound, and the third host compound are deuterated compounds, the degree of deuteration at each deuteration site in the structures of the compounds is greater than 5%.

2. (canceled)

3. (canceled)

4. (canceled)

5. The blue luminescent host composition according to claim 1, characterized in that Formula I is selected from one of the following structures: 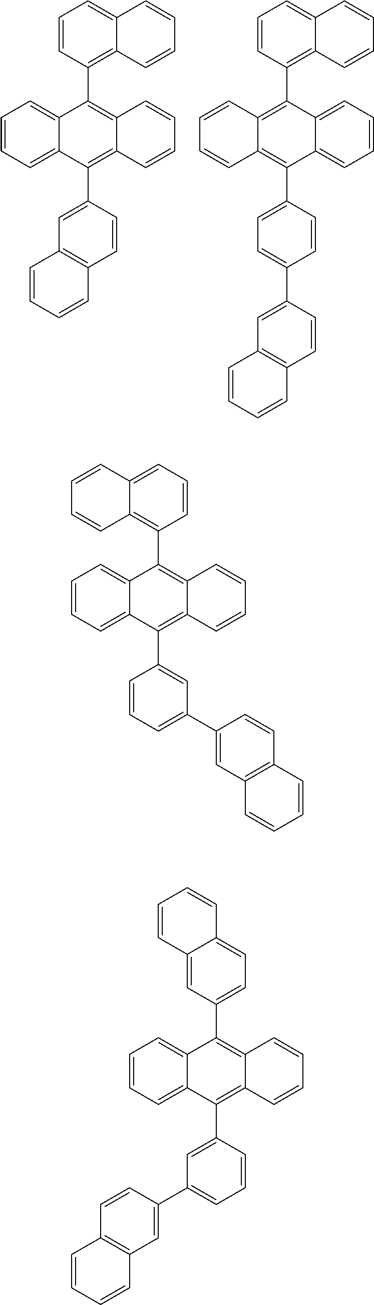 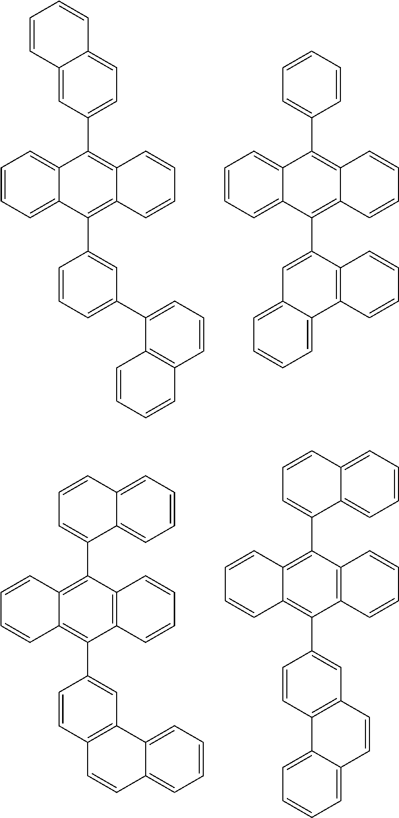 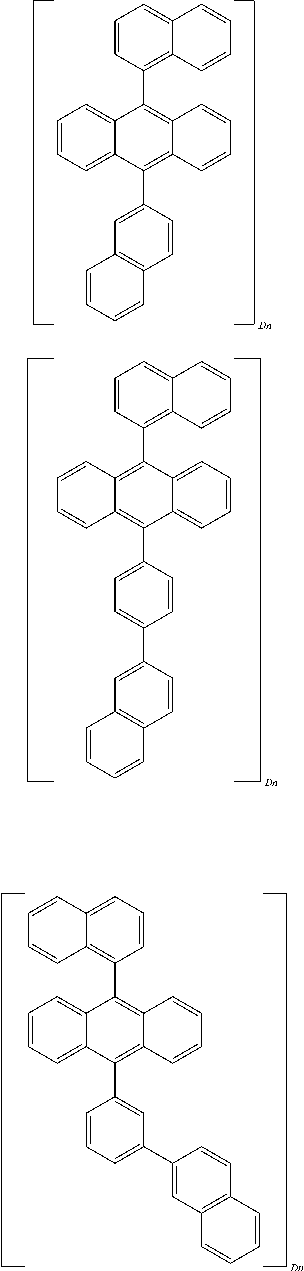 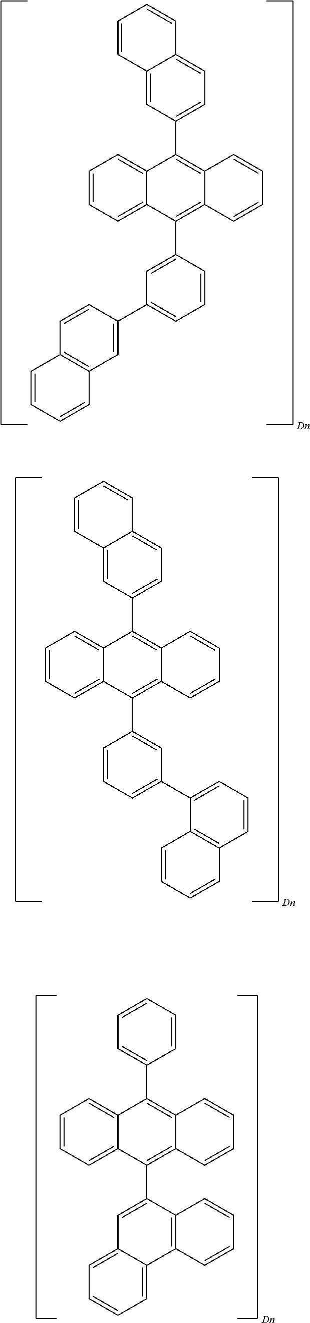 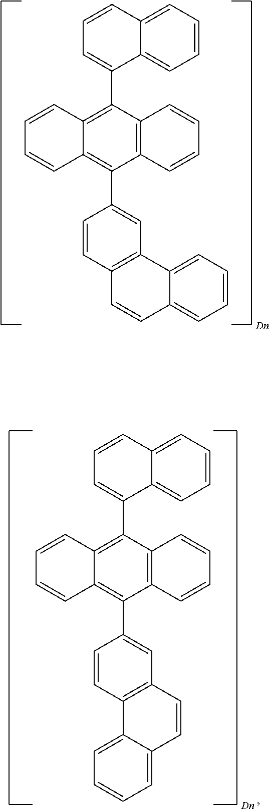
wherein Dn represents n hydrogen atoms being replaced by deuterium, n is a positive integer, and the value of n is from 1 to the maximum number of deuteration.

6. The blue luminescent host composition according to claim 1, characterized in that Formula II is selected from one of the following structures: 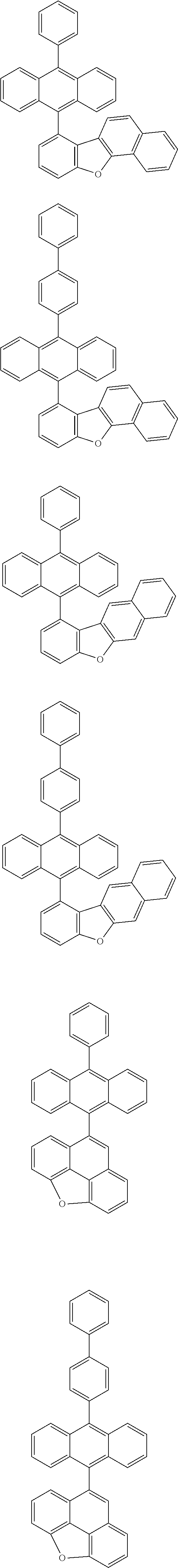 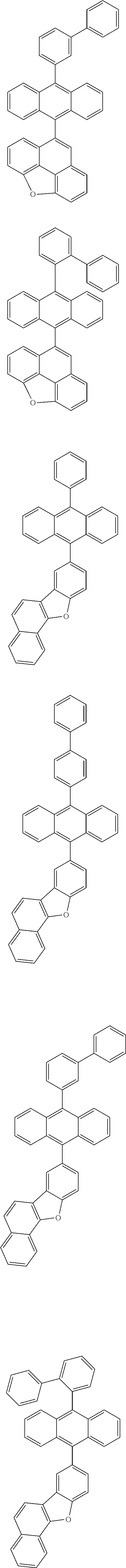 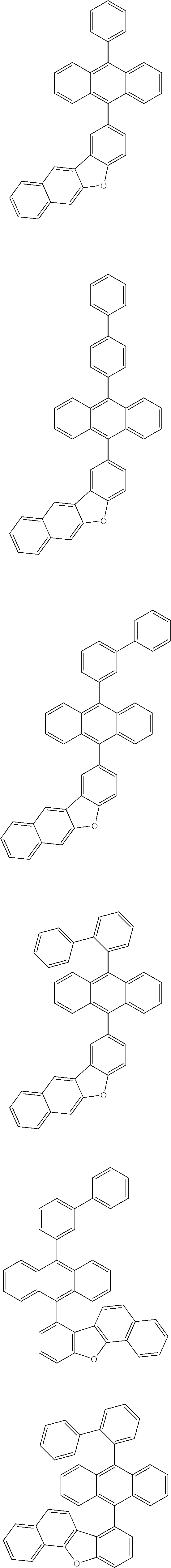 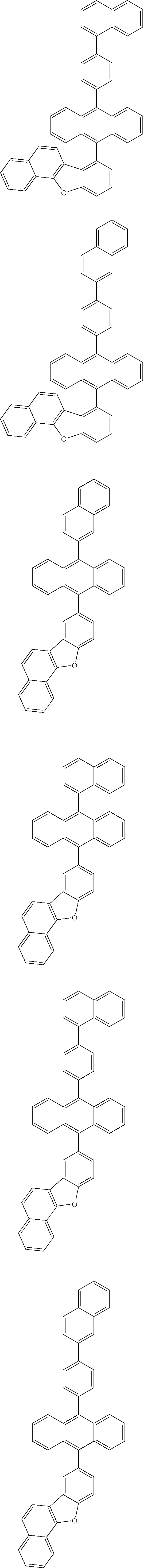 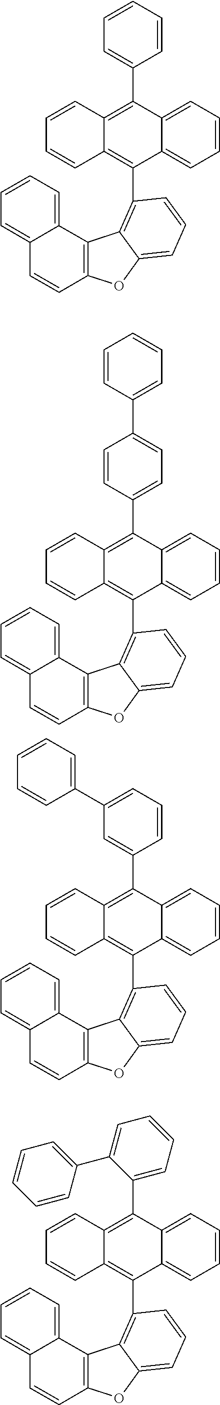 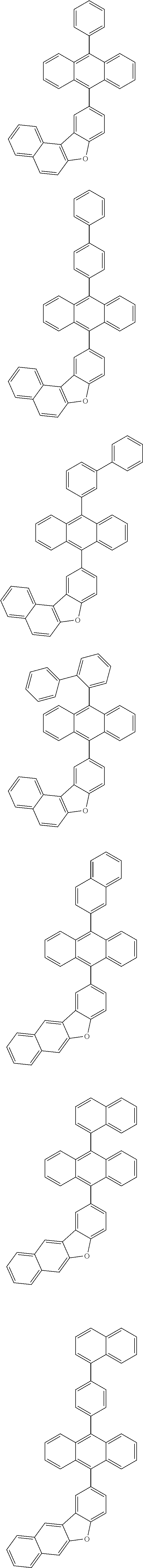 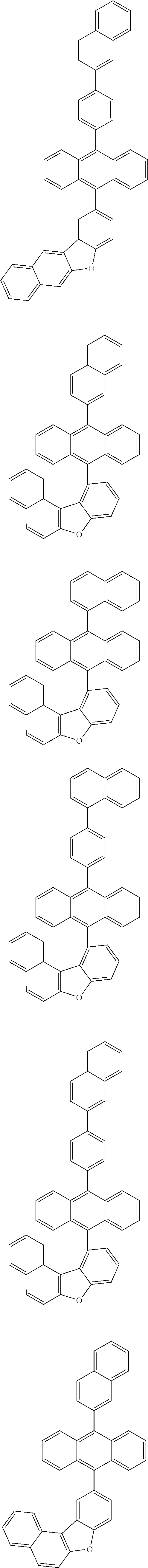 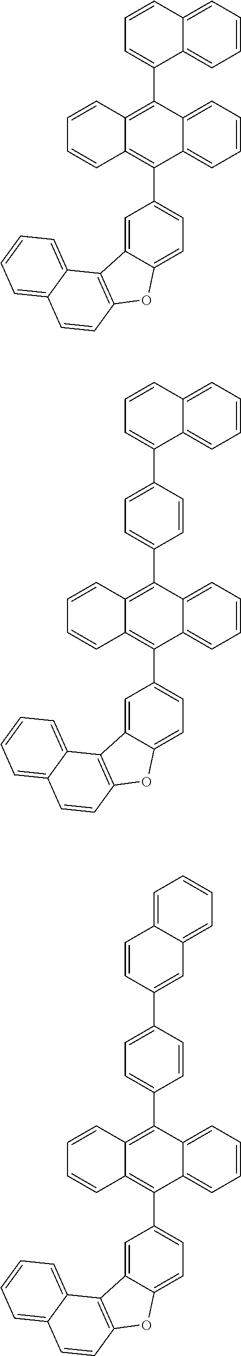 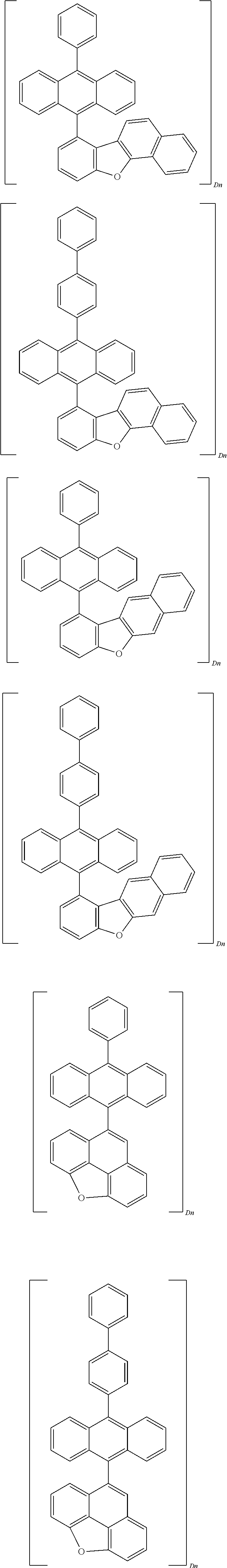 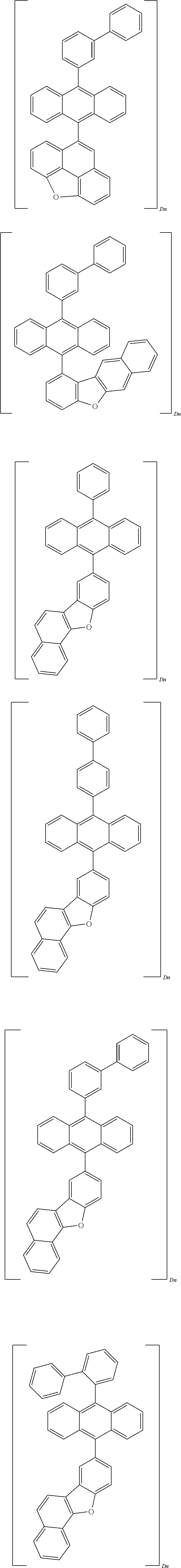 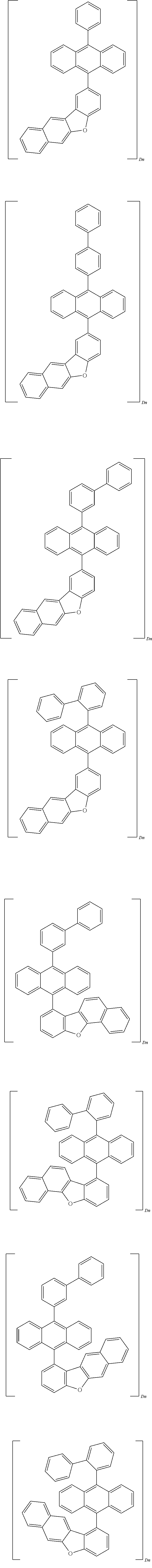 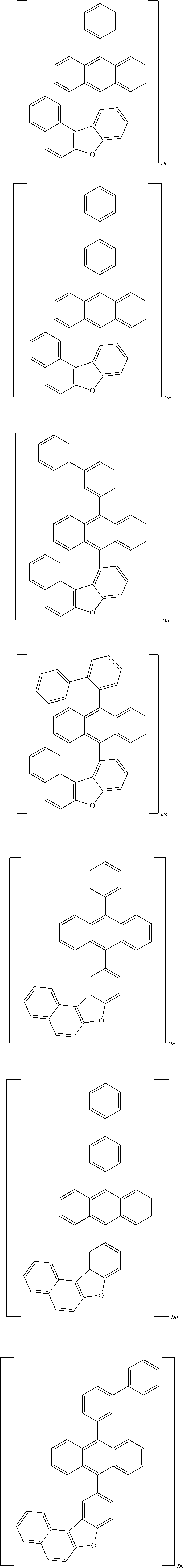 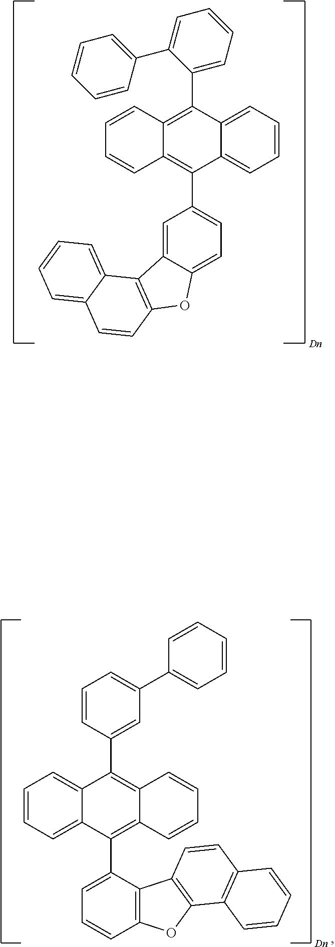
wherein Dn represents n hydrogen atoms being replaced by deuterium, n is a positive integer, and the value of n is from 1 to the maximum number of deuteration.

7. The blue luminescent host composition according to claim 1, characterized in that the blue luminescent host composition is selected from any one of: 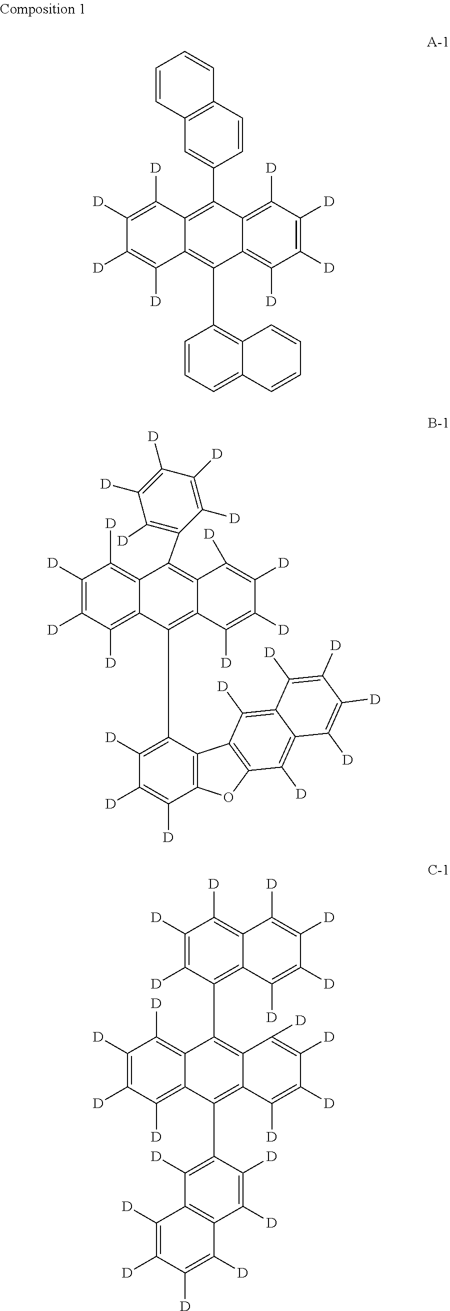 [SMILES: [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H]] 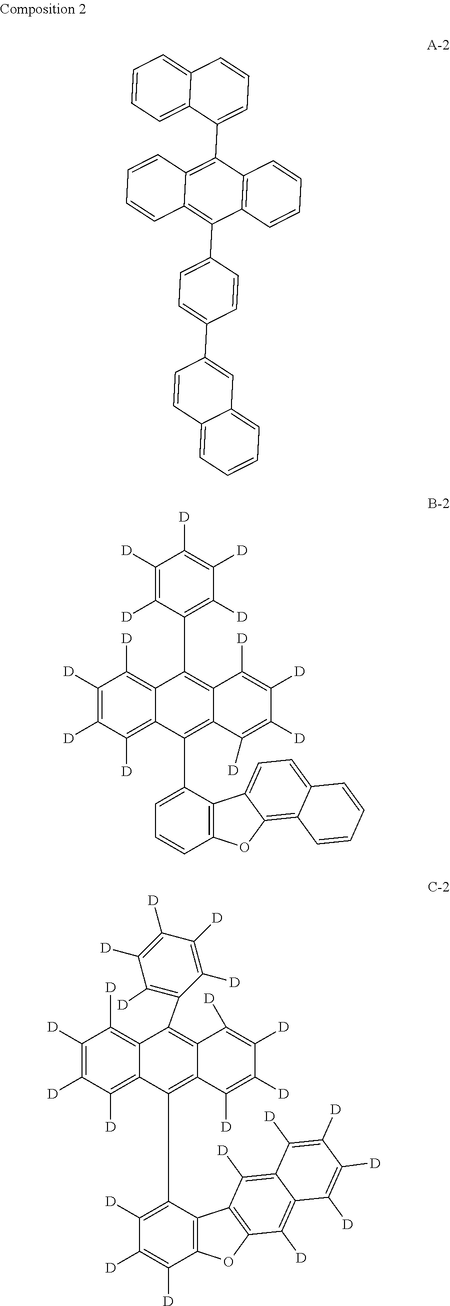 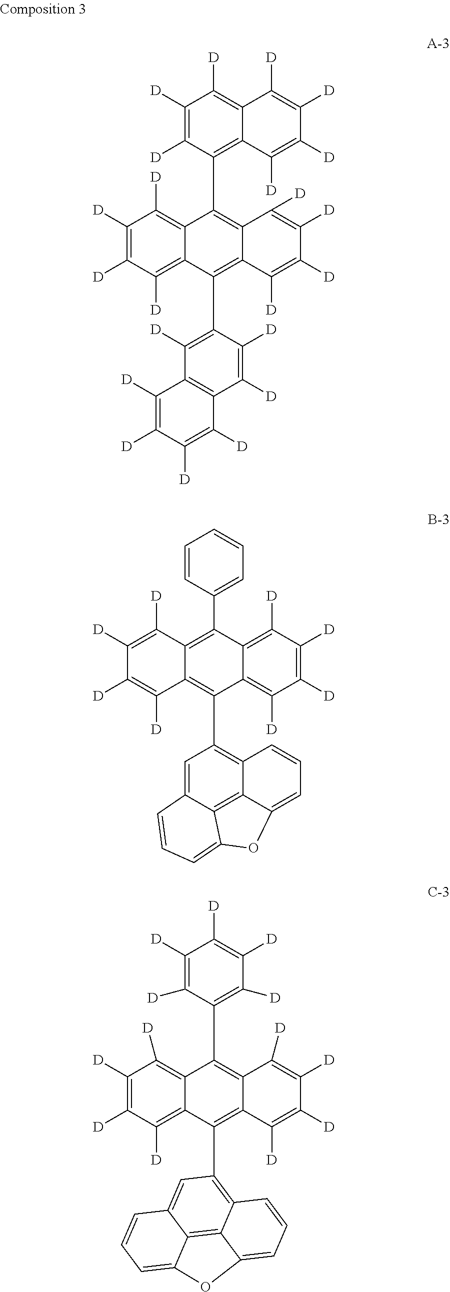 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c2c(-c3cc4cccc5oc6cccc3c6c45)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3cc4cccc5oc6cccc3c6c45)c3c([2H])c([2H])c([2H])c([2H])c23)c([2H])c1[2H]] 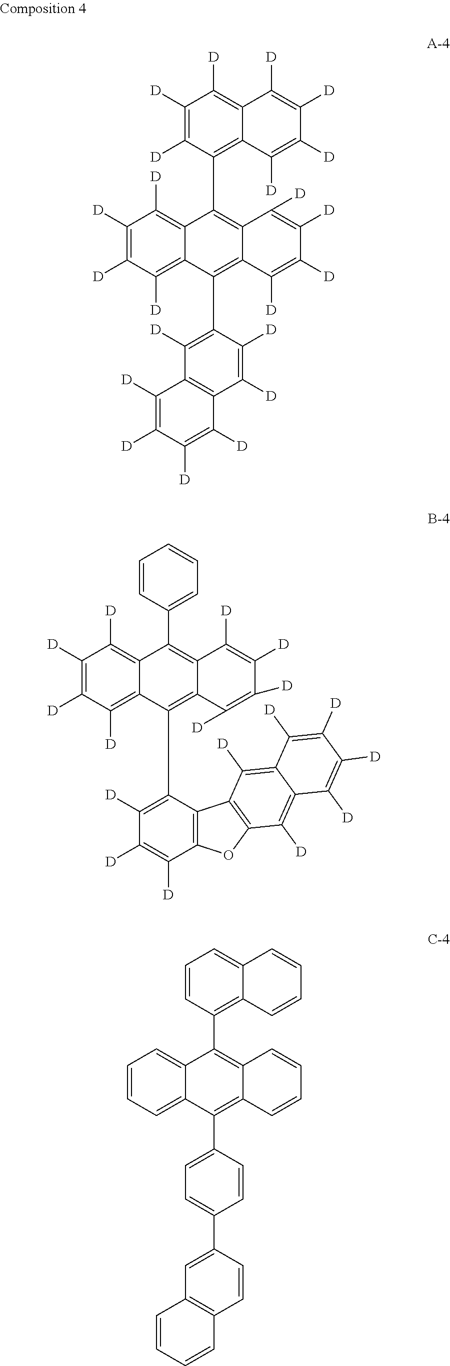 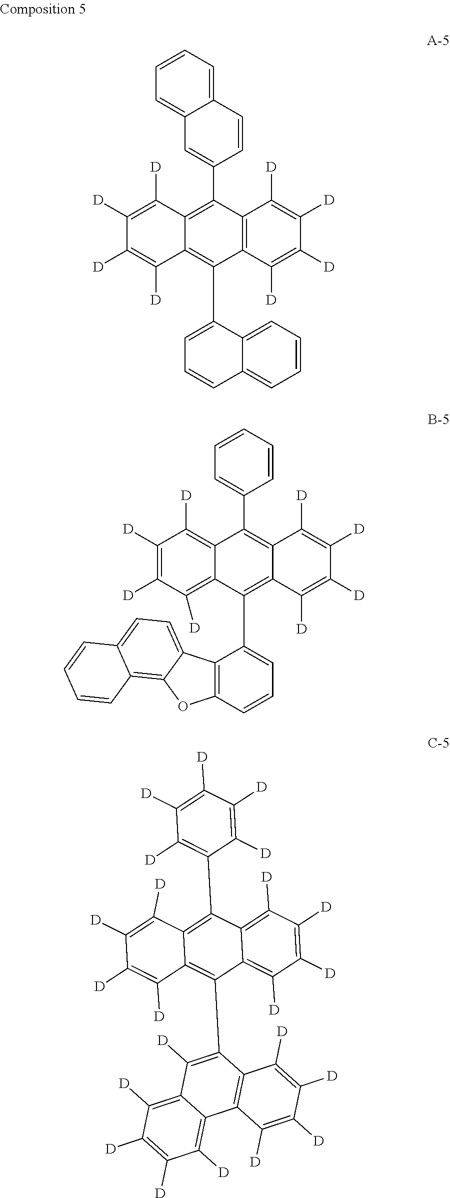 [SMILES: [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3c([2H])c4c([2H])c([2H])c([2H])c([2H])c4c4c([2H])c([2H])c([2H])c([2H])c34)c3c([2H])c([2H])c([2H])c([2H])c23)c([2H])c1[2H]] 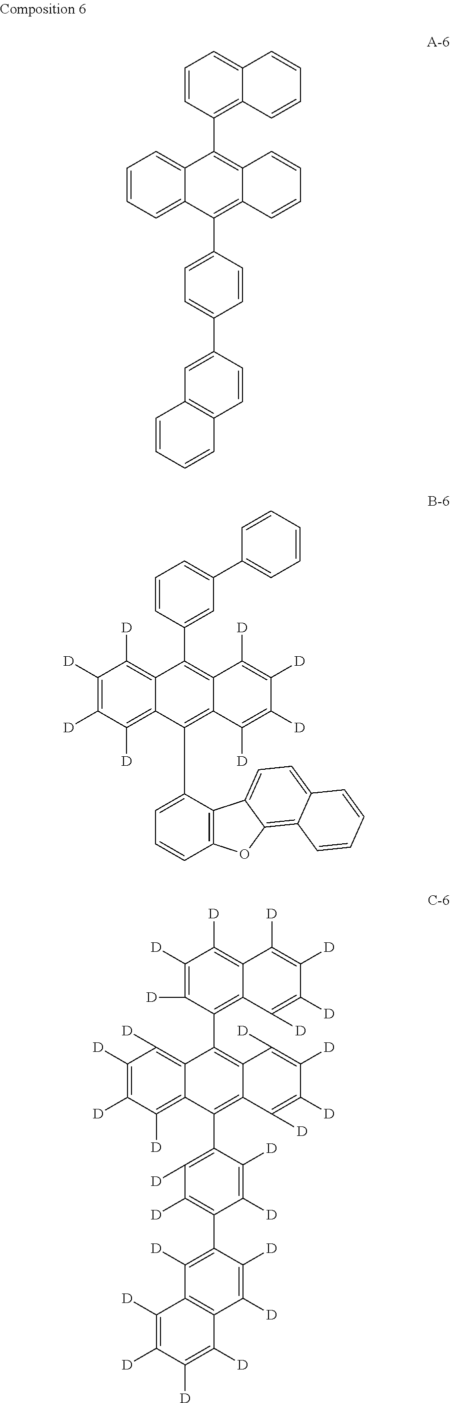 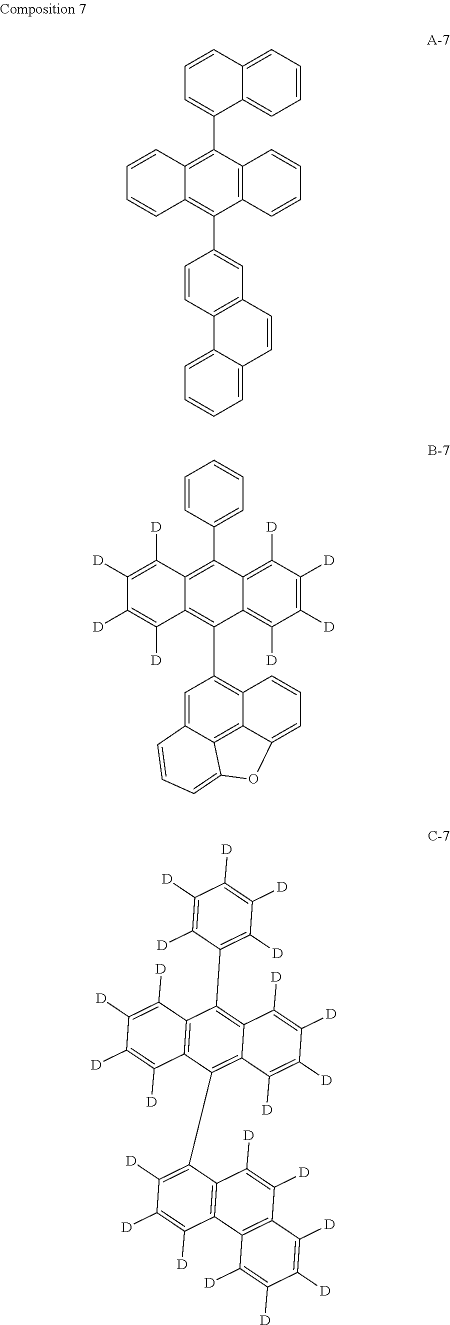 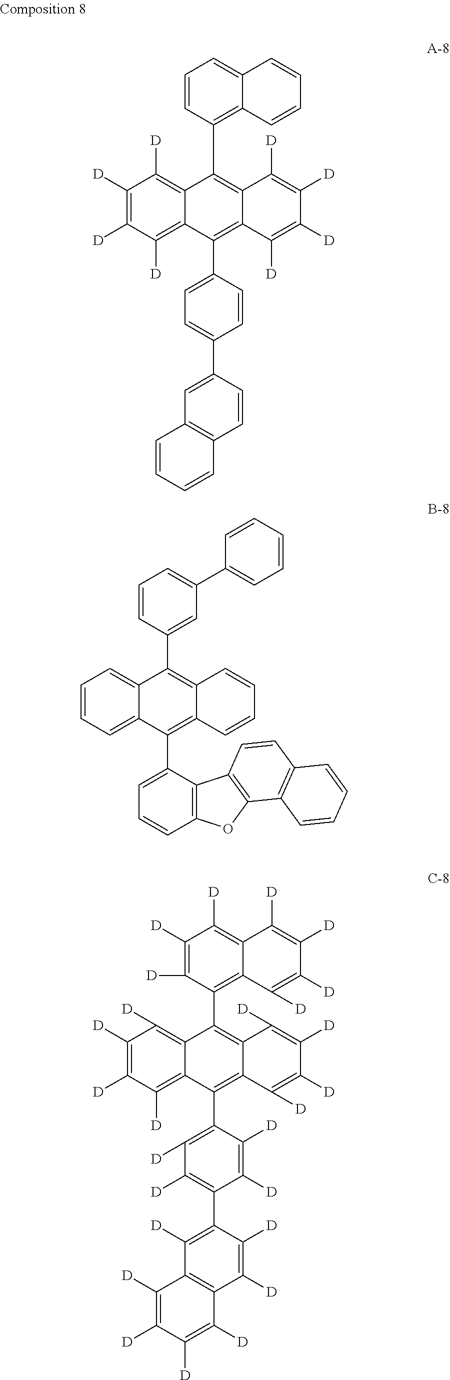 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; c1ccc(-c2cccc(-c3c4ccccc4c(-c4cccc5oc6c7ccccc7ccc6c45)c4ccccc34)c2)cc1 ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H]] 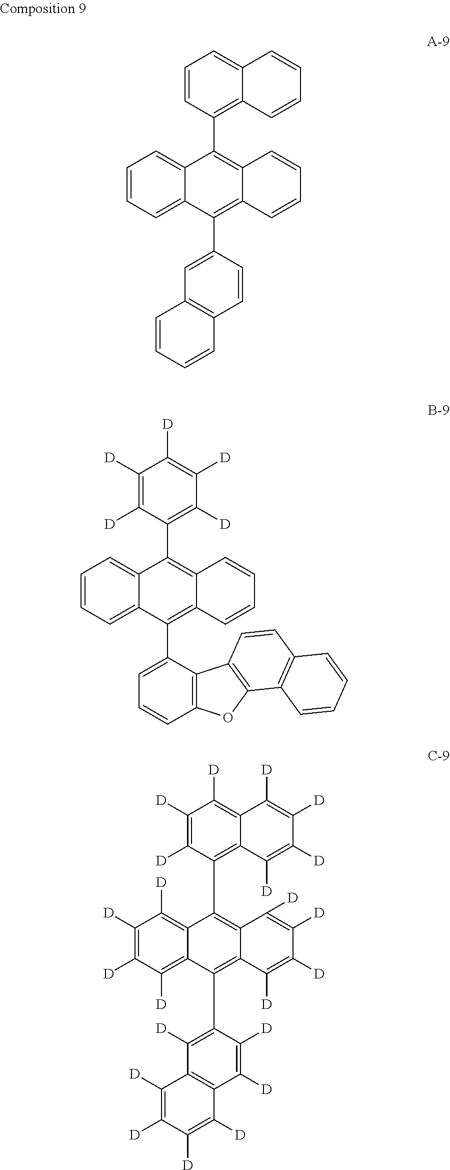 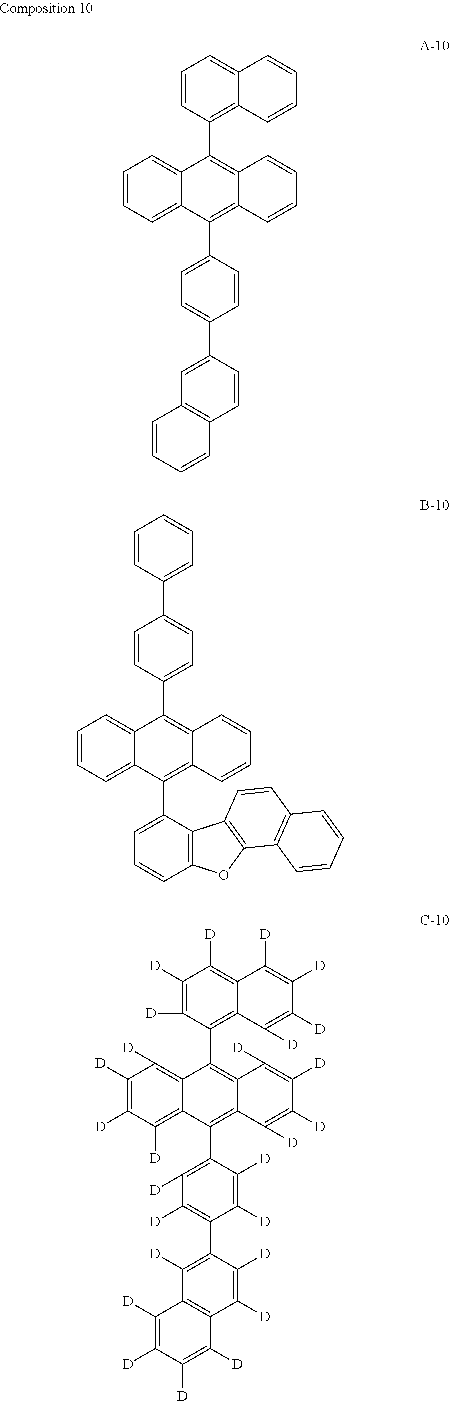 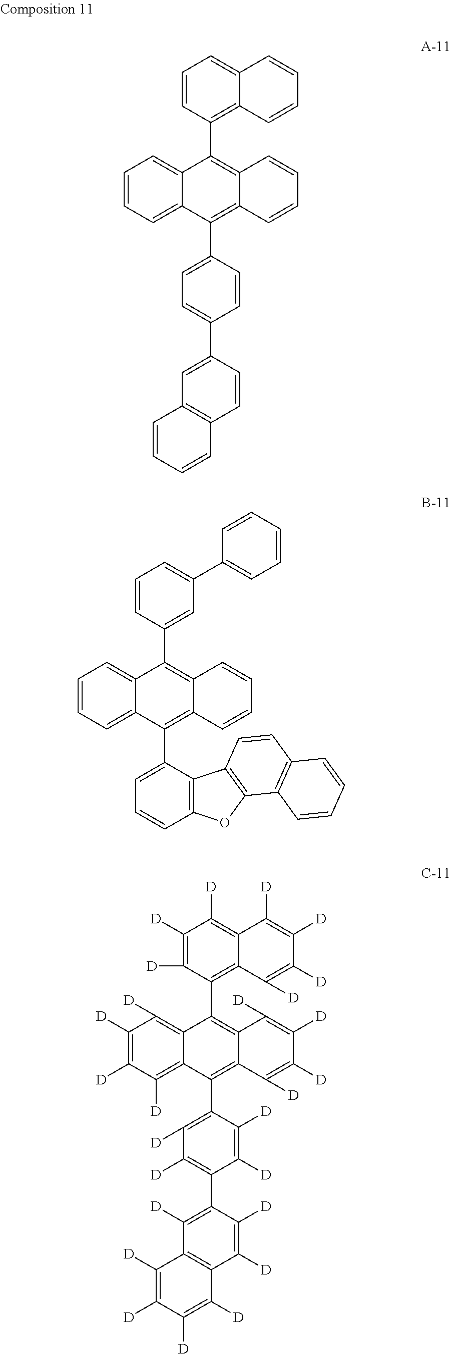 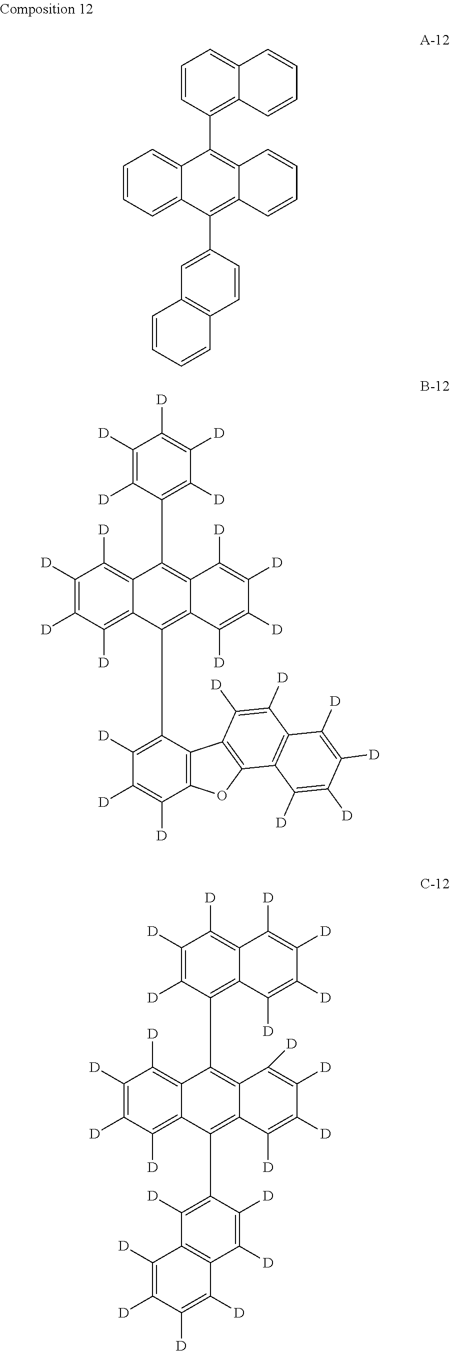 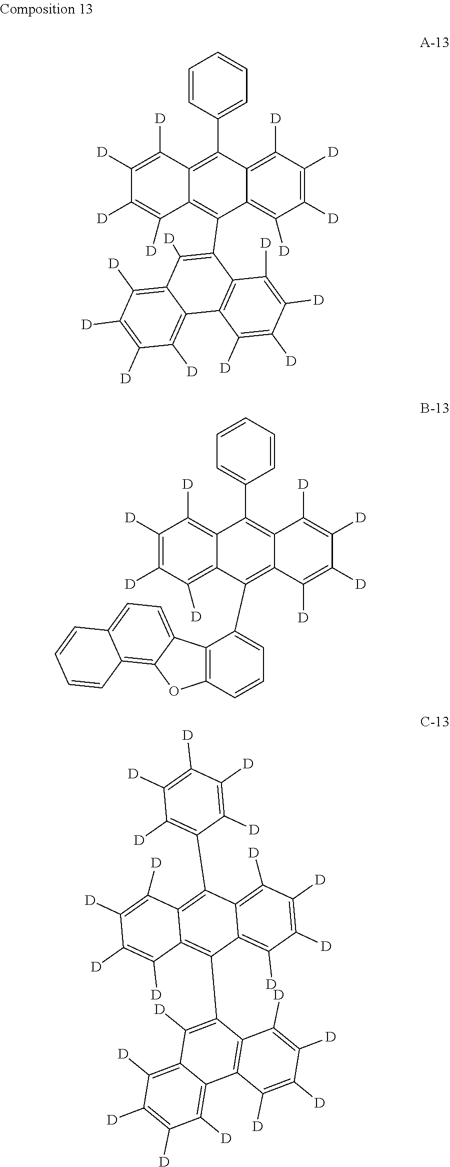 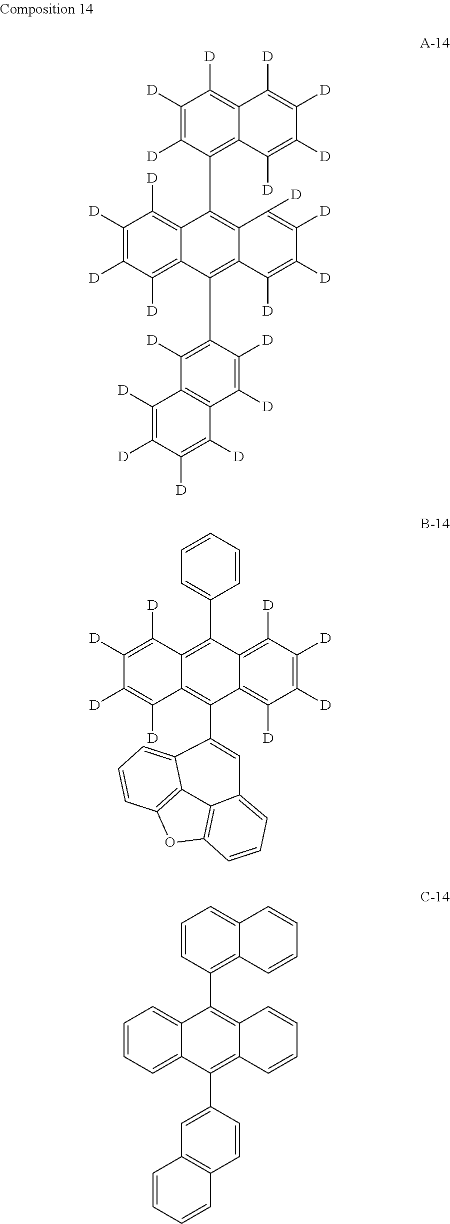 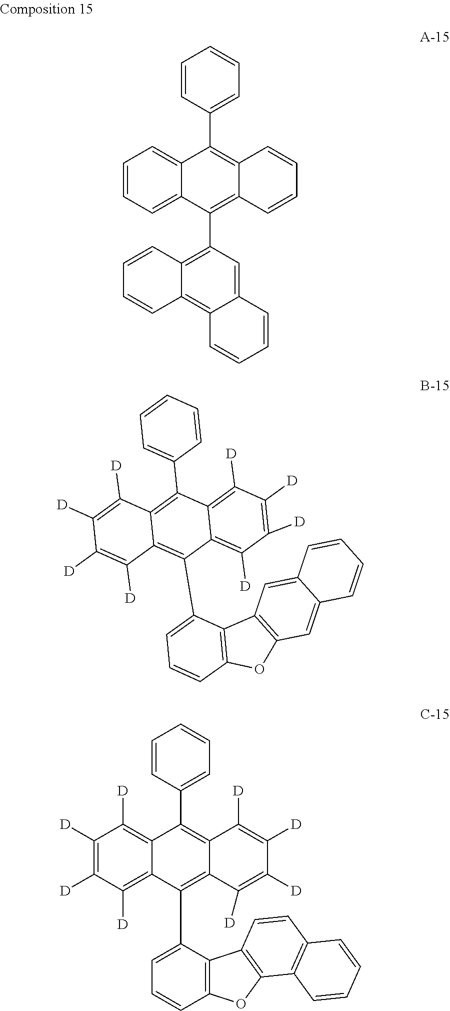 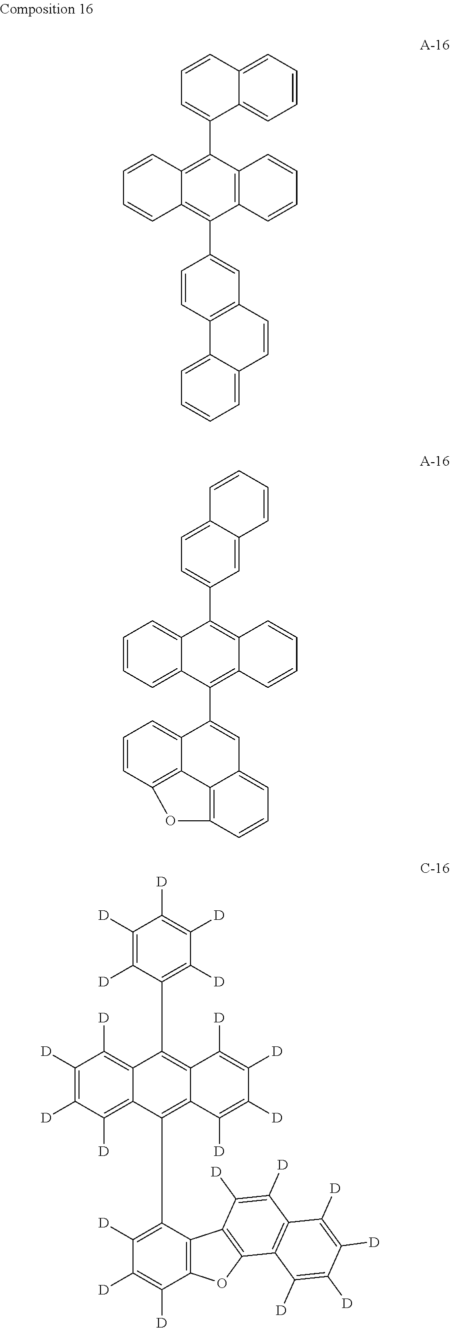 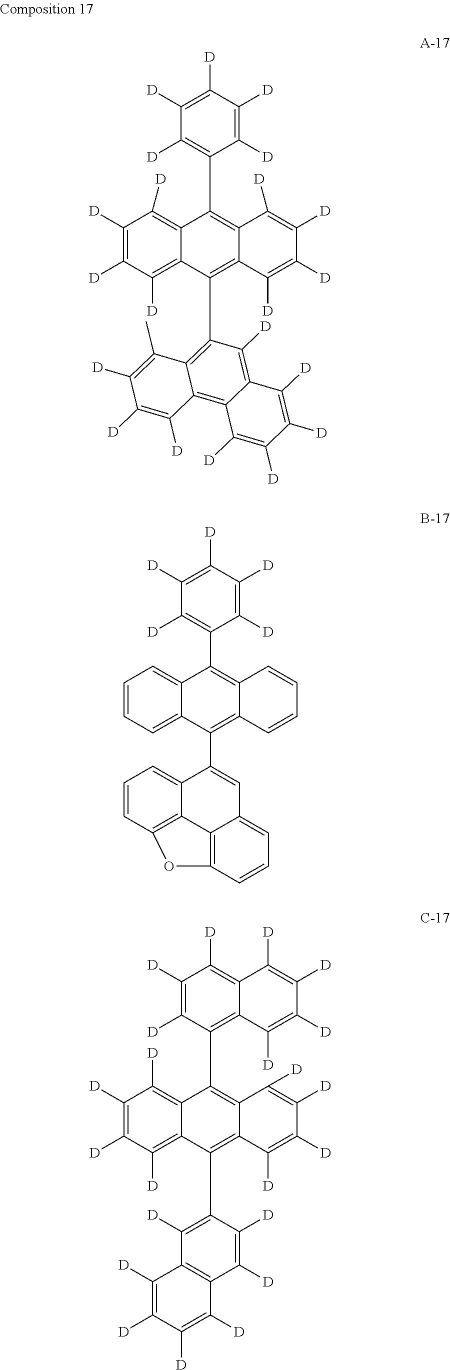 [SMILES: [2H]c1c([2H])c([2H])c(-c2c3c([2H])c([2H])c([2H])c([2H])c3c(-c3c([2H])c4c([2H])c([2H])c([2H])c([2H])c4c4c([2H])c([2H])c([2H])c(C)c34)c3c([2H])c([2H])c([2H])c([2H])c23)c([2H])c1[2H] ; [2H]c1c([2H])c([2H])c(-c2c3ccccc3c(-c3cc4cccc5oc6cccc3c6c45)c3ccccc23)c([2H])c1[2H] ; [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H]] 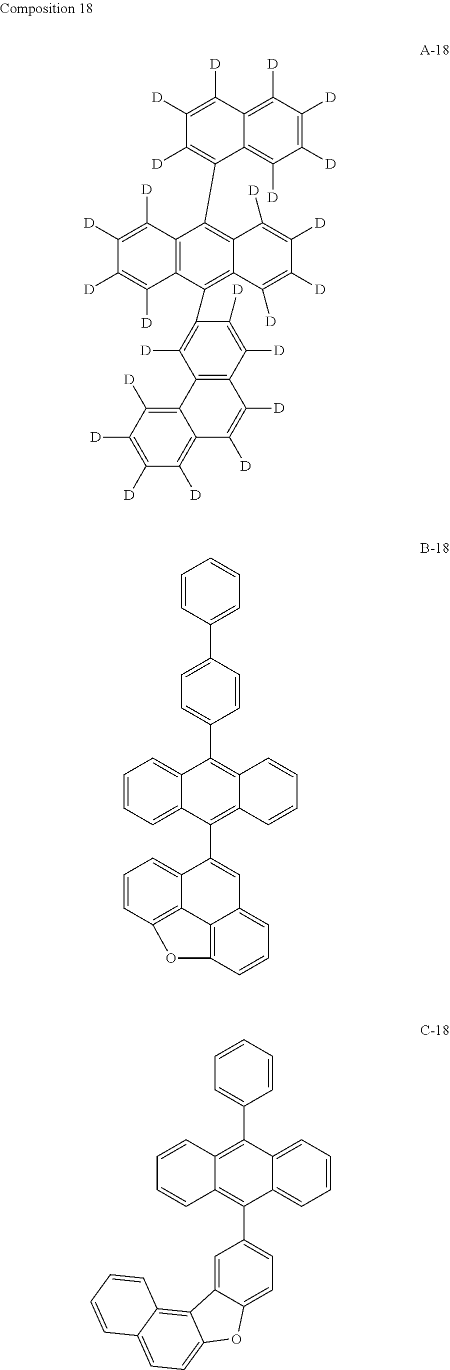 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; c1ccc(-c2ccc(-c3c4ccccc4c(-c4cc5cccc6oc7cccc4c7c56)c4ccccc34)cc2)cc1 ; c1ccc(-c2c3ccccc3c(-c3ccc4oc5ccc6ccccc6c5c4c3)c3ccccc23)cc1] 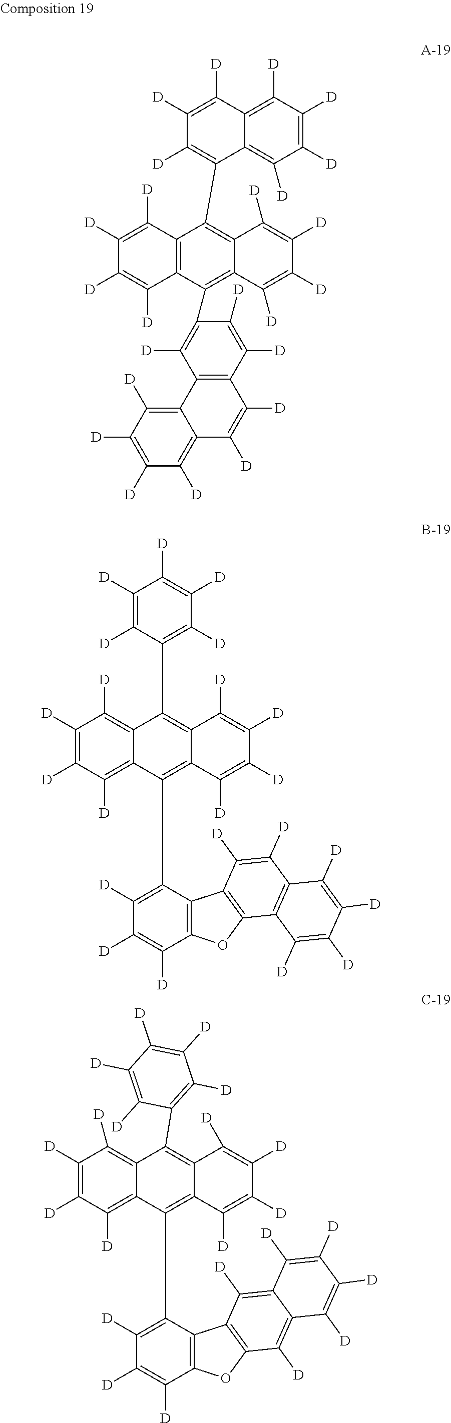 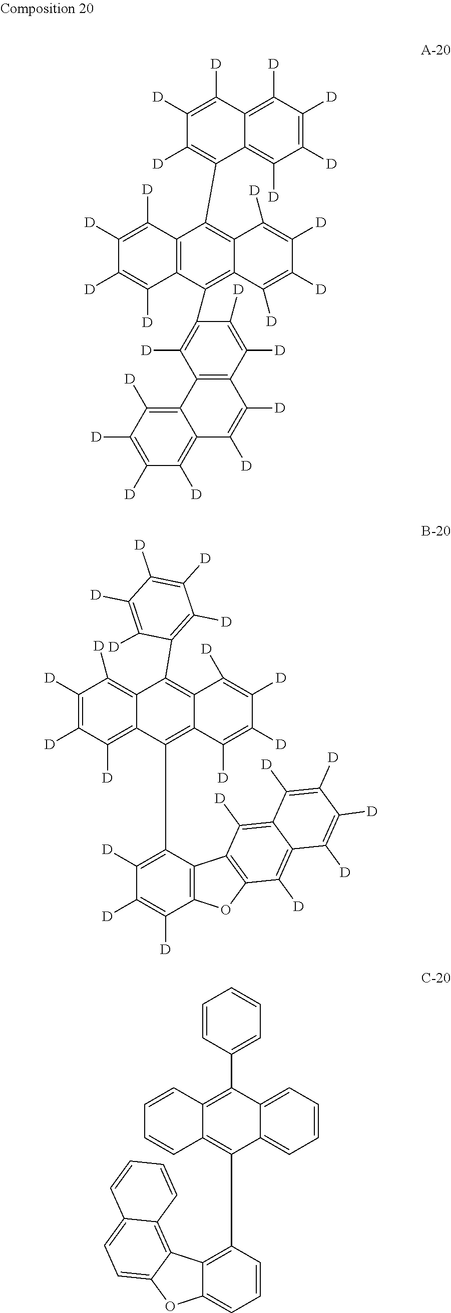 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H] ; c1ccc(-c2c3ccccc3c(-c3cccc4oc5ccc6ccccc6c5c34)c3ccccc23)cc1] 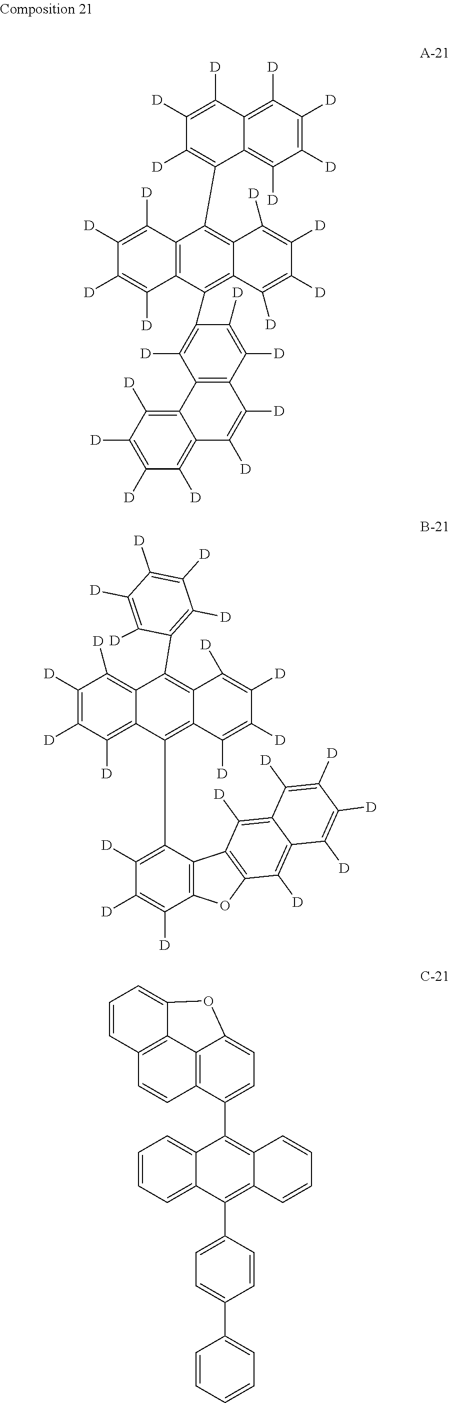 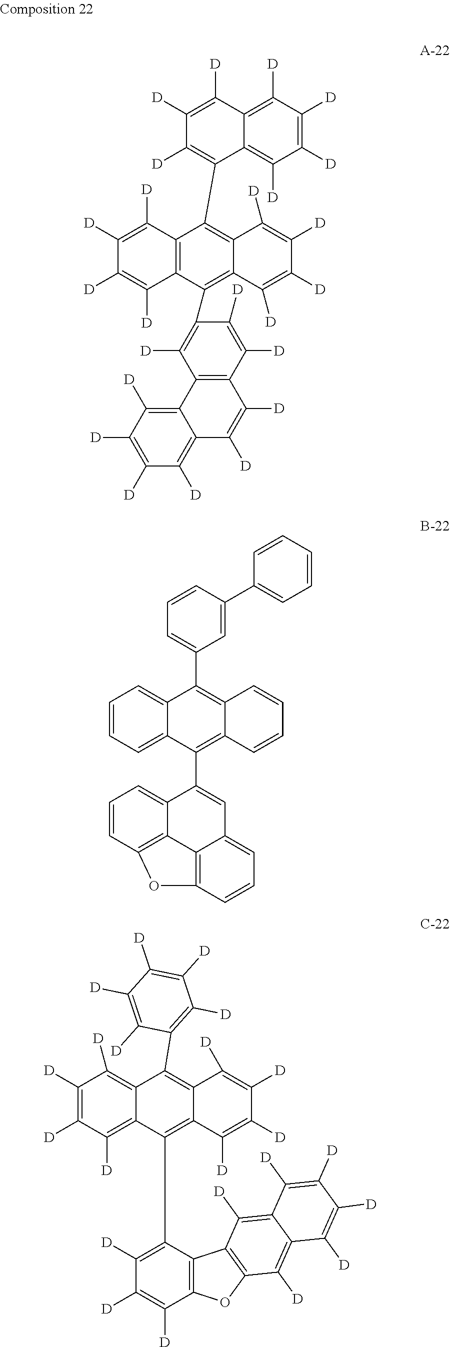 [SMILES: [2H]c1c([2H])c([2H])c2c(-c3c4c([2H])c([2H])c([2H])c([2H])c4c(-c4c([2H])c([2H])c5c([2H])c([2H])c6c([2H])c([2H])c([2H])c([2H])c6c5c4[2H])c4c([2H])c([2H])c([2H])c([2H])c34)c([2H])c([2H])c([2H])c2c1[2H] ; c1ccc(-c2cccc(-c3c4ccccc4c(-c4cc5cccc6oc7cccc4c7c56)c4ccccc34)c2)cc1 ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H]] 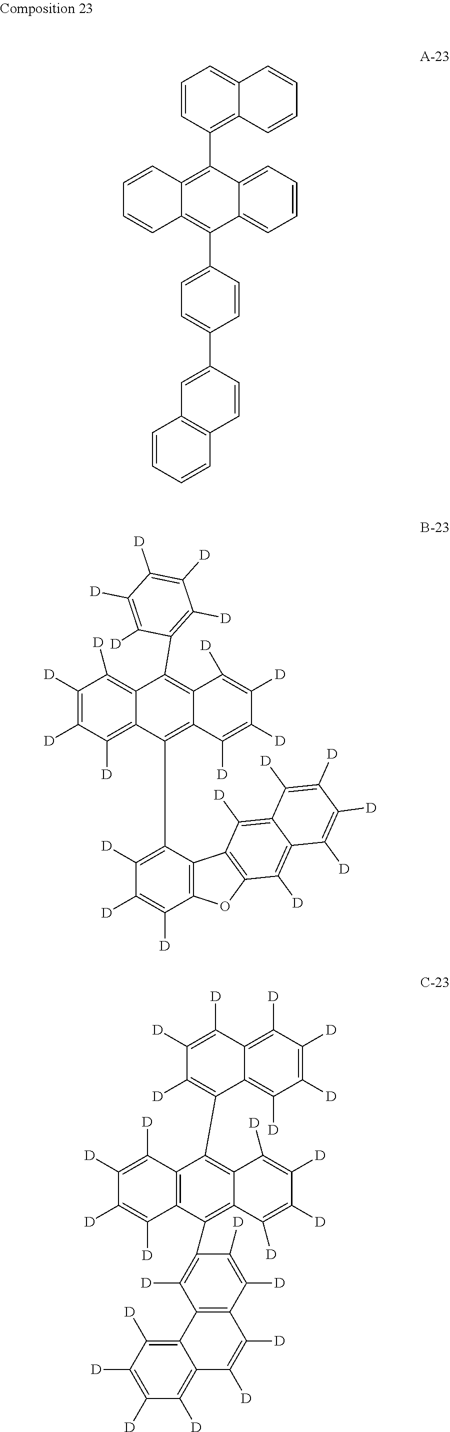 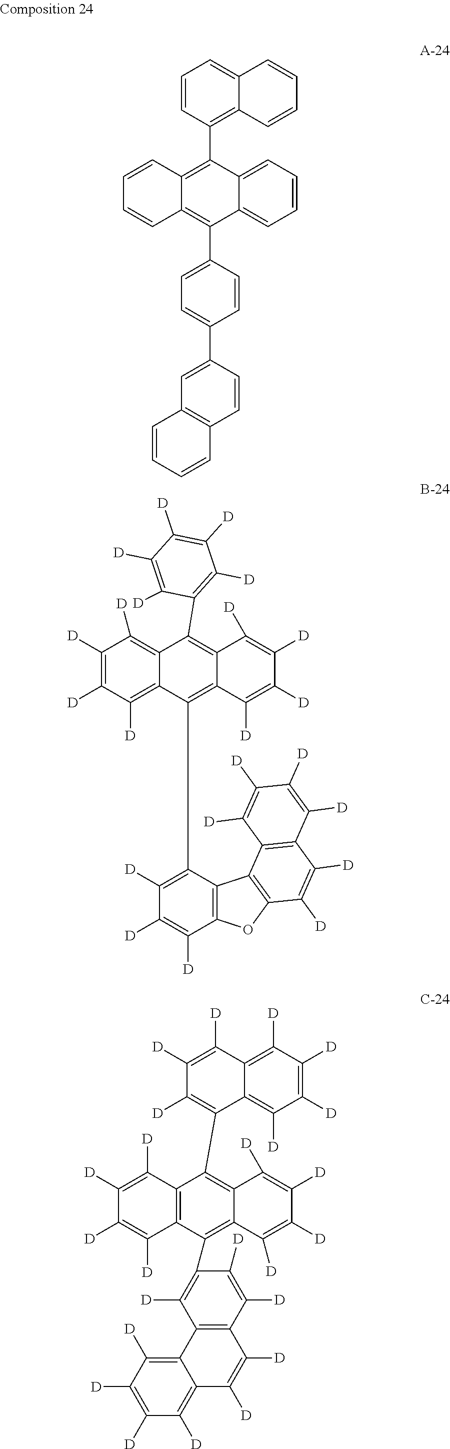 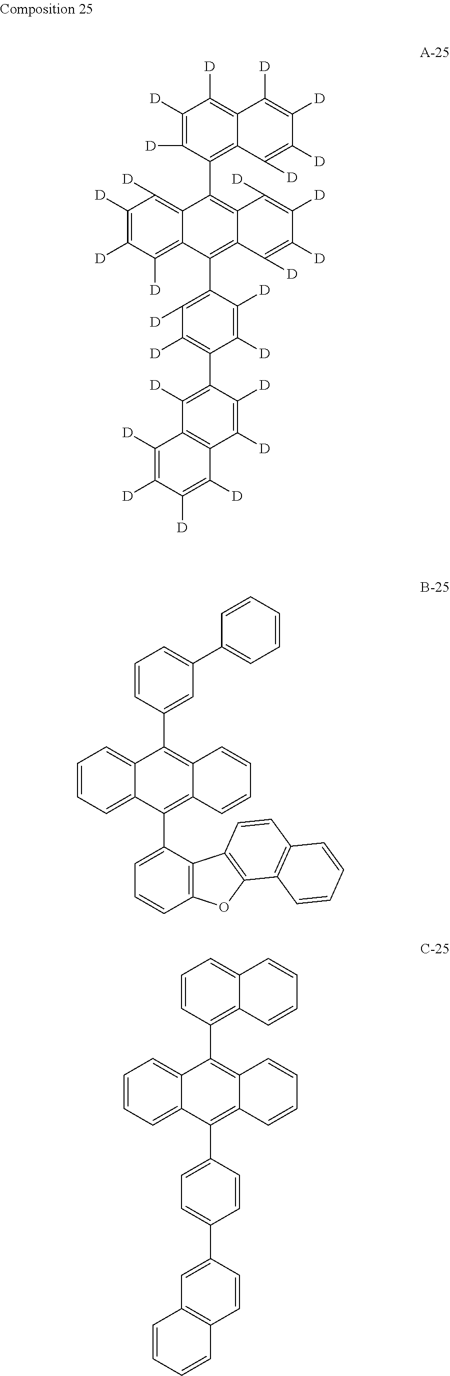 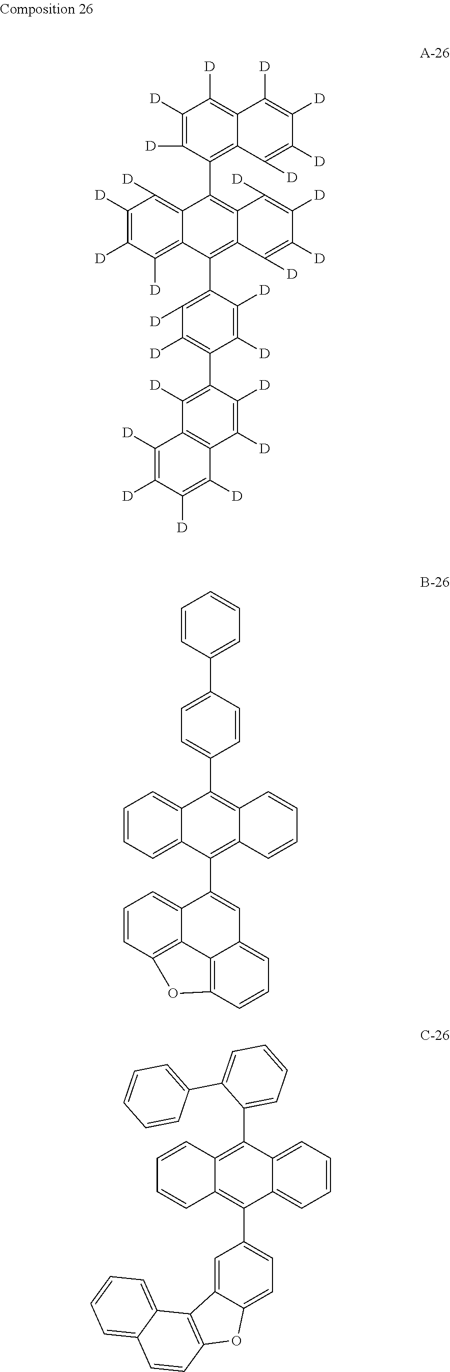 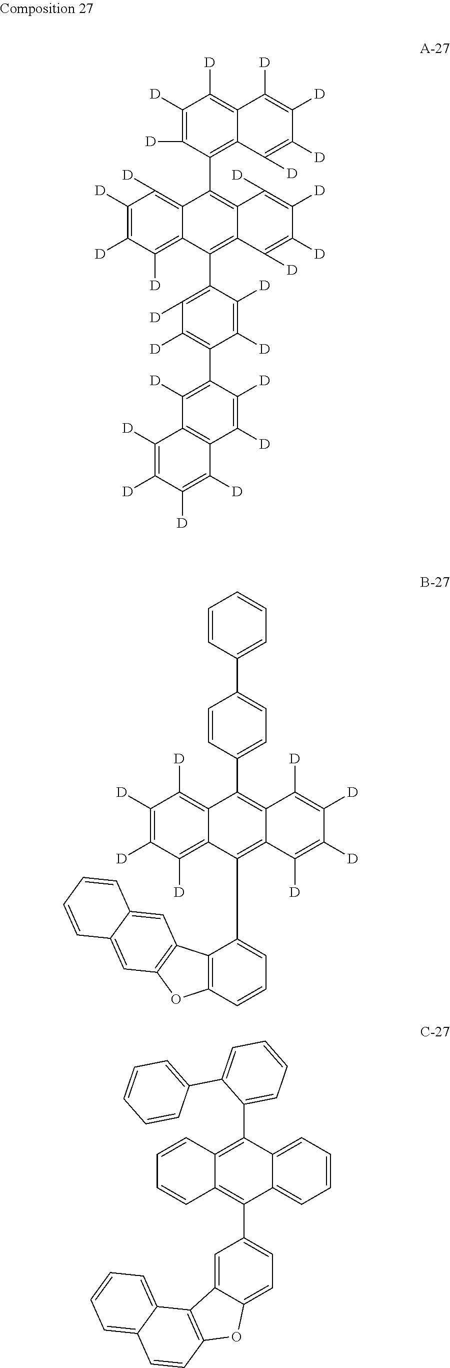 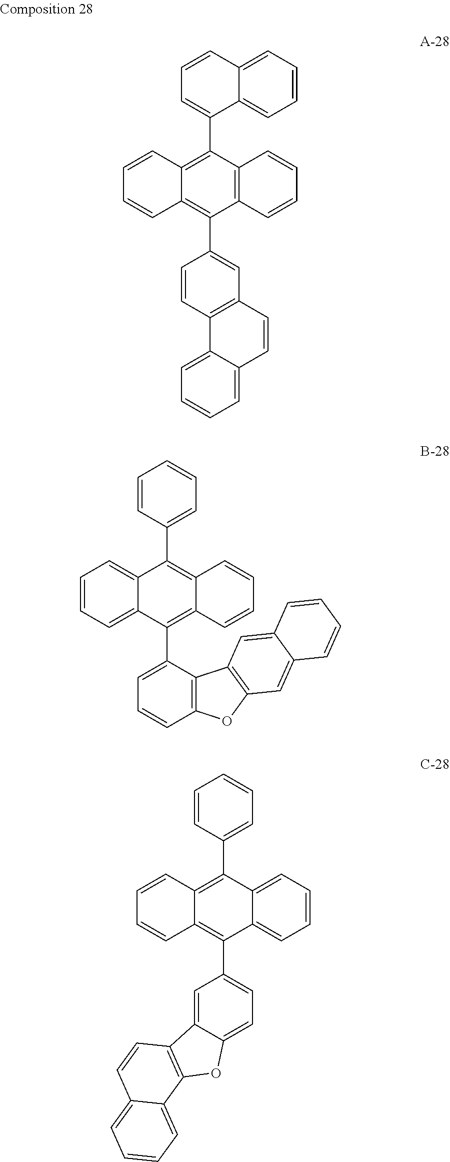 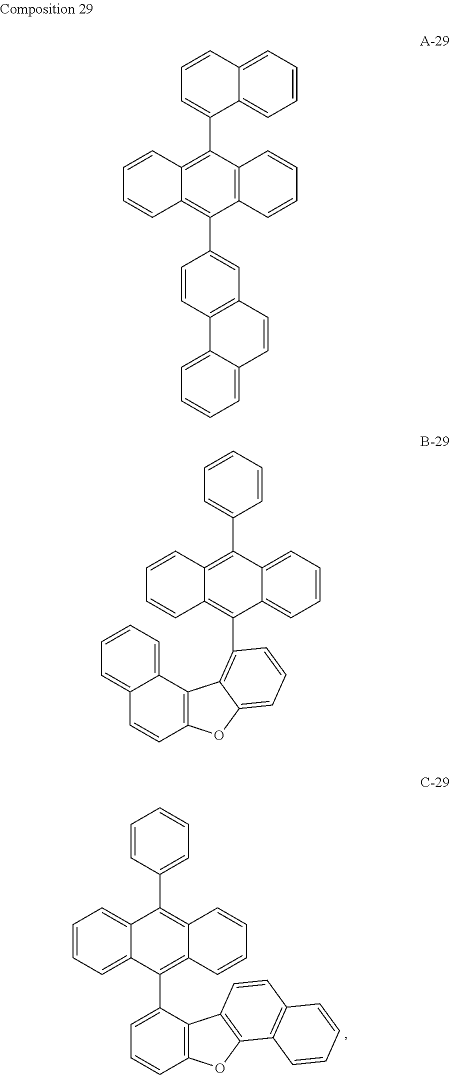
in these compositions, Compounds A-1 to A-29 are the first host compounds, Compounds B-1 to B-29 are the second host compounds, and Compounds C-1 to C-29 are the third host compounds.

8. An organic electroluminescent device, characterized by comprising an anode, a hole transport region, a luminescent layer, an electron transport region, and a cathode, which are sequentially arranged on a substrate plate, wherein the luminescent layer comprises the blue luminescent host composition according to claim 1.

9. The organic electroluminescent device according to claim 8, characterized in that the luminescent layer comprises a host material and a guest material, wherein the host material comprises the blue luminescent host composition.

10. A display device, characterized by comprising the organic electroluminescent device according to claim 8.

11. A display device, characterized by comprising the organic electroluminescent device according to claim 9.

12. An organic electroluminescent device, characterized by comprising an anode, a hole transport region, a luminescent layer, an electron transport region, and a cathode, which are sequentially arranged on a substrate plate, wherein the luminescent layer comprises the blue luminescent host composition according to claim 5.

13. The organic electroluminescent device according to claim 12, characterized in that the luminescent layer comprises a host material and a guest material, wherein the host material comprises the blue luminescent host composition.

14. A display device, characterized by comprising the organic electroluminescent device according to claim 12.

15. A display device, characterized by comprising the organic electroluminescent device according to claim 13.

16. An organic electroluminescent device, characterized by comprising an anode, a hole transport region, a luminescent layer, an electron transport region, and a cathode, which are sequentially arranged on a substrate plate, wherein the luminescent layer comprises the blue luminescent host composition according to claim 6.

17. The organic electroluminescent device according to claim 16, characterized in that the luminescent layer comprises a host material and a guest material, wherein the host material comprises the blue luminescent host composition.

18. A display device, characterized by comprising the organic electroluminescent device according to claim 16.

19. A display device, characterized by comprising the organic electroluminescent device according to claim 17.

20. An organic electroluminescent device, characterized by comprising an anode, a hole transport region, a luminescent layer, an electron transport region, and a cathode, which are sequentially arranged on a substrate plate, wherein the luminescent layer comprises the blue luminescent host composition according to claim 7.

21. The organic electroluminescent device according to claim 20, characterized in that the luminescent layer comprises a host material and a guest material, wherein the host material comprises the blue luminescent host composition.

22. A display device, characterized by comprising the organic electroluminescent device according to claim 20.

23. A display device, characterized by comprising the organic electroluminescent device according to claim 21.
